(19) United States
(12) Patent Application Publication
(10) Pub. No.: US 2026/0334287 A1
(43) Pub. Date: Oct. 22, 2026

(54) LIGHT DETECTION DEVICE

(71) Applicant: SONY SEMICONDUCTOR SOLUTIONS CORPORATION, KANAGAWA (JP)

(72) Inventors: TAKUMI ONODERA, KANAGAWA (JP); TAKAHIRO KAMEI, KANAGAWA (JP); AKIHISA SAKAMOTO, KANAGAWA (JP); KATSUYA AKIYAMA, KANAGAWA (JP); NAOKI OGAWA, KANAGAWA (JP); TORU OSAKO, KANAGAWA (JP); YOSHIYUKI ISHII, KANAGAWA (JP); HIROYASU MATSUGAI, KANAGAWA (JP)

(21) Appl. No.: 19/107,713

(22) PCT Filed: Sep. 7, 2023
(86) PCT No.: PCT/JP2023/032601

§ 371 Date: Feb. 28, 2025

(30) Foreign Application Priority Data
Sep. 8, 2022 (JP) 2022-142956

(51) Int. Cl. H10W 74/10; H10D 80/30; H10F 39/00; H10F 39/95; H10W 74/01; H10W 76/63; H10W 76/67; H10W 90/00; H10W 90/15; H10W 90/20; H10W 90/26

(52) U.S. Cl. CPC H10W 74/114; H10F 39/8053; H10F 39/8063; H10F 39/809; H10F 39/811; H10W 74/01; H10W 74/121; H10W 74/141; H10W 76/63; H10W 76/67; H10W 90/15; H10W 90/155; H10W 90/26; H10D 80/30; H10F 39/95; H10W 90/297; H10W 90/792

(57) ABSTRACT

A light detection device includes: a substrate including a light detection element; a chip provided for the substrate; a buried layer provided to cover the chip; a seam portion occurring in the buried layer and extending to a front surface of the buried layer; and a sealing layer provided to cover the buried layer and the seam portion.

### FIELD

The present disclosure relates to a light detection device.

### BACKGROUND

It is known that a step on a substrate causes occurrence of a seam portion in a layer provided so as to cover the substrate. For example, Patent Literature 1 discloses a technique of discontinuously forming seam portions of two stacked layers to suppress communication of the seam portion to the outside.

### CITATION LIST

### Patent Literature

Patent Literature 1: WO 2017/183390 A

### SUMMARY

### Technical Problem

There is a light detection device having a configuration in which a layer is provided so as to cover a chip provided on a substrate including a light detection element. A step formed by the chip can cause occurrence of a seam portion. There is still room for examining a method of suppressing communication of the seam portion to the outside.

One aspect of the present disclosure is to suppress communication of the seam portion to the outside.

### Solution to Problem

A light detection device according to one aspect of the present disclosure includes: a substrate including a light detection element; a chip provided for the substrate; a buried layer provided to cover the chip; a seam portion occurring in the buried layer and extending to a front surface of the buried layer; and a sealing layer provided to cover the buried layer and the seam portion.

### BRIEF DESCRIPTION OF DRAWINGS

FIG. 1 is a diagram illustrating an example of a schematic configuration of a light detection device according to a first embodiment.

FIG. 2 is a diagram illustrating an example of a schematic configuration of a light detection device according to a second embodiment.

FIG. 3 is a diagram illustrating an example of a schematic configuration of a light detection device according to a fourth embodiment.

FIG. 4 is a diagram illustrating an example of a schematic configuration of a light detection device according to a fifth embodiment.

FIG. 5 is a diagram illustrating an example of a schematic configuration of a light detection device according to a sixth embodiment.

FIG. 6 is a diagram illustrating an example of a schematic configuration of a light detection device according to the sixth embodiment.

FIG. 7 is a diagram illustrating an example of a schematic configuration of a light detection device according to a seventh embodiment.

FIG. 8 is a diagram illustrating an example of a schematic configuration of a light detection device according to an eighth embodiment.

FIG. 9 is a diagram illustrating an example of a method of manufacturing a light detection device.

FIG. 10 is a diagram illustrating an example of a method of manufacturing the light detection device.

FIG. 11 is a diagram illustrating an example of a method of manufacturing the light detection device.

FIG. 12 is a diagram illustrating an example of a method of manufacturing the light detection device.

FIG. 13 is a diagram illustrating an example of a method of manufacturing the light detection device.

FIG. 14 is a diagram illustrating an example of a method of manufacturing the light detection device.

FIG. 15 is a diagram illustrating an example of a method of manufacturing the light detection device.

FIG. 16 is a diagram illustrating an example of a method of manufacturing the light detection device.

FIG. 17 is a diagram illustrating an example of a method of manufacturing the light detection device.

FIG. 18 is a diagram illustrating an example of a method of manufacturing a light detection device.

FIG. 19 is a diagram illustrating an example of a method of manufacturing the light detection device.

FIG. 20 is a diagram illustrating an example of a schematic configuration of a light detection device according to an application example.

FIG. 21 is a diagram illustrating an example of a schematic configuration of a light detection device according to an application example.

FIG. 22 is a diagram illustrating an example of a schematic configuration of a light detection device according to an application example.

FIG. 23 is a diagram illustrating an example of a schematic configuration of a light detection device according to an application example.

FIG. 24 is a block diagram depicting an example of schematic configuration of a vehicle control system.

FIG. 25 is a diagram of assistance in explaining an example of installation positions of an outside-vehicle information detecting section and an imaging section.

FIG. 26 is a diagram illustrating an example of a schematic configuration of a light detection device according to a ninth embodiment.

FIG. 27 is a diagram illustrating an example of a schematic configuration of a light detection device according to the ninth embodiment.

FIG. 28 is a diagram illustrating an example of a method of manufacturing the light detection device.

FIG. 29 is a diagram illustrating an example of a method of manufacturing the light detection device.

FIG. 30 is a diagram illustrating an example of a method of manufacturing the light detection device.

FIG. 31 is a diagram illustrating an example of a method of manufacturing the light detection device.

FIG. 32 is a diagram illustrating an example of a method of manufacturing the light detection device.

FIG. 33 is a diagram illustrating a modification.

FIG. 34 is a diagram illustrating a modification.

FIG. 35 is a diagram illustrating an example of a schematic configuration of a light detection device according to a tenth embodiment.

FIG. 36 is a diagram illustrating an example of a schematic configuration of a light detection device according to the tenth embodiment.

FIG. 37 is a diagram illustrating an example of a method of manufacturing the light detection device.

FIG. 38 is a diagram illustrating an example of a method of manufacturing the light detection device.

FIG. 39 is a diagram illustrating an example of a method of manufacturing the light detection device.

FIG. 40 is a diagram illustrating an example of a method of manufacturing the light detection device.

FIG. 41 is a diagram illustrating an example of a method of manufacturing the light detection device.

FIG. 42 is a diagram illustrating an example of a method of manufacturing the light detection device.

FIG. 43 is a diagram illustrating an example of a method of manufacturing the light detection device.

FIG. 44 is a diagram illustrating a modification.

FIG. 45 is a diagram illustrating an example of a schematic configuration of a light detection device according to an eleventh embodiment.

FIG. 46 is a diagram illustrating an example of a schematic configuration of a light detection device according to the eleventh embodiment.

FIG. 47 is a diagram illustrating an example of a method of manufacturing the light detection device.

FIG. 48 is a diagram illustrating an example of a method of manufacturing the light detection device.

FIG. 49 is a diagram illustrating an example of a method of manufacturing the light detection device.

FIG. 50 is a diagram illustrating an example of a method of manufacturing the light detection device.

FIG. 51 is a diagram illustrating an example of a method of manufacturing the light detection device.

FIG. 52 is a diagram illustrating an example of a schematic configuration of a sealing layer.

FIG. 53 is a diagram illustrating an example of a schematic configuration of a light detection device according to a thirteenth embodiment.

FIG. 54 is a diagram illustrating an example of a method of manufacturing the light detection device.

FIG. 55 is a diagram illustrating an example of a method of manufacturing the light detection device.

FIG. 56 is a diagram illustrating an example of a method of manufacturing the light detection device.

FIG. 57 is a diagram illustrating an example of a method of manufacturing the light detection device.

FIG. 58 is a diagram illustrating an example of a method of manufacturing the light detection device.

FIG. 59 is a diagram illustrating an example of a schematic configuration of a light detection device according to a fourteenth embodiment.

FIG. 60 is a diagram illustrating an example of a method of manufacturing the light detection device.

FIG. 61 is a diagram illustrating an example of a method of manufacturing the light detection device.

FIG. 62 is a diagram illustrating an example of a method of manufacturing the light detection device.

FIG. 63 is a diagram illustrating an example of a method of manufacturing the light detection device.

FIG. 64 is a diagram illustrating an example of a method of manufacturing the light detection device.

FIG. 65 is a diagram illustrating an example of a schematic configuration of a light detection device according to a fifteenth embodiment.

FIG. 66 is a diagram illustrating an example of a method of manufacturing the light detection device.

FIG. 67 is a diagram illustrating an example of a method of manufacturing the light detection device.

FIG. 68 is a diagram illustrating an example of a method of manufacturing the light detection device.

FIG. 69 is a diagram illustrating an example of a method of manufacturing the light detection device.

FIG. 70 is a diagram illustrating a first layout example of dummy chips.

FIG. 71 is a diagram illustrating a first layout example of dummy chips.

FIG. 72 is a diagram illustrating an effect of dummy chips. FIG. 73 is a diagram illustrating an example of a schematic configuration of a wafer.

FIG. 74 is a diagram illustrating a second layout example of dummy chips.

FIG. 75 is a diagram illustrating an effect of dummy chips. FIG. 76 is a diagram illustrating an example of a schematic configuration of a wafer.

FIG. 77 is a diagram illustrating a third layout example of dummy chips.

FIG. 78 is a diagram illustrating an effect of dummy chips. FIG. 79 is a diagram illustrating an example of a schematic configuration of a wafer.

FIG. 80 is a diagram illustrating a fourth layout example of dummy chips.

FIG. 81 is a diagram illustrating an effect of dummy chips. FIG. 82 is a diagram illustrating an example of a schematic configuration of a wafer.

FIG. 83 is a diagram illustrating a fifth layout example of dummy chips.

FIG. 84 is a diagram illustrating an effect of dummy chip 2D.

FIG. 85 is a diagram illustrating an example of a schematic configuration of a wafer.

FIG. 86 is a diagram illustrating an example of a schematic configuration of a wafer.

FIG. 87 is a diagram illustrating an effect of dummy chips.

FIG. 88 is a diagram illustrating an example of a schematic configuration of a wafer.

FIG. 89 is a diagram illustrating a seventh layout example of dummy chips.

FIG. 90 is a diagram illustrating an effect of dummy chips.

FIG. 91 is a diagram illustrating an example of a schematic configuration of a wafer.

FIG. 92 is a diagram illustrating a modification.

FIG. 93 is a diagram illustrating a modification.

FIG. 94 is a diagram illustrating an example of a schematic configuration of a light detection device according to a sixteenth embodiment.

FIG. 95 is a diagram illustrating an example of a schematic configuration of a light detection device according to a seventeenth embodiment.

FIG. 96 is a diagram illustrating an example of a schematic configuration of a light detection device according to an eighteenth embodiment.

FIG. 97 is a diagram illustrating an example of a schematic configuration of a light detection device according to a nineteenth embodiment.

FIG. 98 is a diagram illustrating an example of a schematic configuration of a light detection device according to a twentieth embodiment.

FIG. 99 is a diagram illustrating an example of a schematic configuration of a light detection device according to a twenty-first embodiment.

FIG. 100 is a diagram illustrating an example of a schematic configuration of a light detection device according to a twenty-second embodiment.

FIG. 101 is a diagram illustrating an example of a schematic configuration of a light detection device according to a twenty-third embodiment.

FIG. 102 is a diagram illustrating an example of a method of manufacturing the light detection device.

FIG. 103 is a diagram illustrating an example of a method of manufacturing the light detection device.

FIG. 104 is a diagram illustrating an example of a method of manufacturing the light detection device.

FIG. 105 is a diagram illustrating an example of a method of manufacturing the light detection device.

FIG. 106 is a diagram illustrating an example of a method of manufacturing the light detection device.

FIG. 107 is a diagram illustrating an example of a method of manufacturing the light detection device.

FIG. 108 is a diagram illustrating an example of a schematic configuration of a light detection device according to a twenty-fourth embodiment.

FIG. 109 is a diagram illustrating an example of a schematic configuration of a light detection device according to the twenty-fourth embodiment.

FIG. 110 is a diagram illustrating an example of a method of manufacturing the light detection device.

FIG. 111 is a diagram illustrating an example of a method of manufacturing the light detection device.

FIG. 112 is a diagram illustrating an example of a method of manufacturing the light detection device.

FIG. 113 is a diagram illustrating an example of a method of manufacturing the light detection device.

FIG. 114 is a diagram illustrating an example of a method of manufacturing the light detection device.

FIG. 115 is a diagram illustrating an example of a method of manufacturing the light detection device.

FIG. 116 is a diagram illustrating an example of a method of manufacturing the light detection device.

FIG. 117 is a diagram illustrating an example of a method of manufacturing the light detection device.

FIG. 118 is a diagram illustrating an example of a method of manufacturing the light detection device.

FIG. 119 is a diagram illustrating an example of a method of manufacturing the light detection device.

FIG. 120 is a diagram illustrating an example of CMP.

FIG. 121 is a diagram illustrating an example of CMP.

FIG. 122 is a diagram illustrating an example of a schematic configuration of a light detection device according to a twenty-fifth embodiment.

FIG. 123 is a diagram illustrating an example of a method of manufacturing the light detection device.

FIG. 124 is a diagram illustrating an example of a method of manufacturing the light detection device.

FIG. 125 is a diagram illustrating an example of a method of manufacturing the light detection device.

FIG. 126 is a diagram illustrating an example of a method of manufacturing the light detection device.

FIG. 127 is a diagram illustrating an example of a method of manufacturing the light detection device.

FIG. 128 is a diagram illustrating an example of a method of manufacturing the light detection device.

### DESCRIPTION OF EMBODIMENTS

Embodiments of the present disclosure will be described below in detail with reference to the drawings. Unless otherwise specified, in each of the following embodiments, the same parts are denoted by the same reference signs, and a repetitive description thereof will be omitted.

The present disclosure will be described in the following order of items.
1. First embodiment
2. Second embodiment
3. Third embodiment
4. Fourth embodiment
5. Fifth embodiment
6. Sixth embodiment
7. Seventh embodiment
8. Eighth embodiment
9. Example of manufacturing method
10. Example of application to imaging device
11. Example of effects
12. Example of application to mobile body
13. Ninth embodiment
14. Tenth embodiment
15. Eleventh embodiment
16. Twelfth embodiment
17. Thirteenth embodiment
18. Fourteenth embodiment
19. Fifteenth embodiment
20. Dummy chips layout example
21. Sixteenth embodiment
22. Seventeenth embodiment
23. Eighteenth embodiment
24. Nineteenth embodiment
25. Twentieth embodiment
26. Twenty-first embodiment
27. Twenty-second embodiment
28. Twenty-third embodiment
29. Example of application to imaging device
30. Example of manufacturing method
31. Twenty-fourth embodiment
32. Twenty-fifth embodiment

### 1. First Embodiment

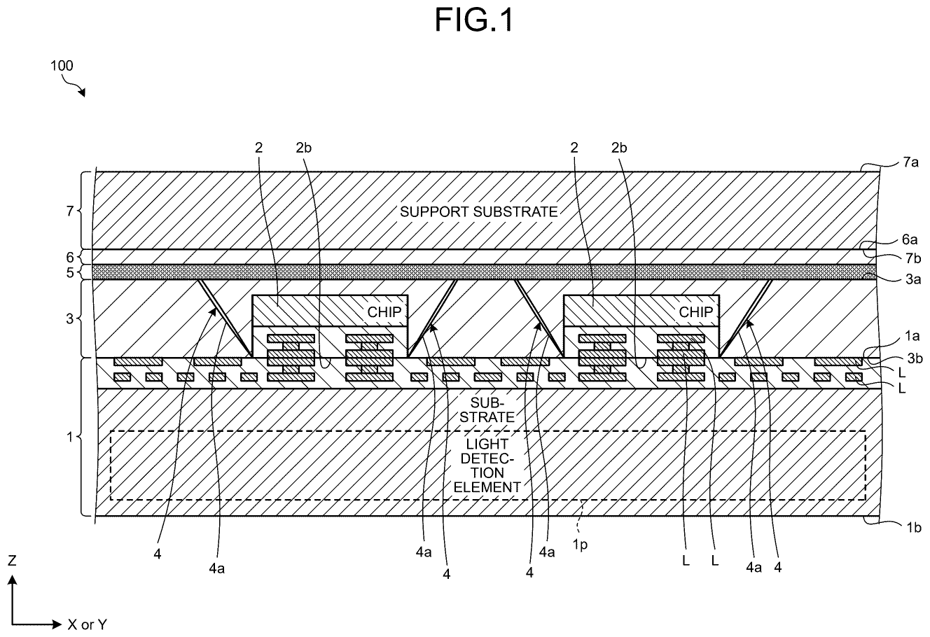

FIG. 1 is a diagram illustrating an example of a schematic configuration of a light detection device according to a first embodiment. The figure schematically illustrates a cross section of a light detection device 100. The light detection device 100 includes a substrate 1, a chip 2, a buried layer 3, a seam portion 4, a sealing layer 5, an auxiliary layer 6, and a support substrate 7. Note that the “layer” may be appropriately replaced with a term such as a “film” and a “member” within a range without contradiction. Furthermore, “provide” may be appropriately read as “form”, “dispose”, or the like.

The figures are illustrated with an XYZ coordinate system. The Z-axis direction corresponds to the thickness direction of the substrate or the layer. The X-axis direction and the Y-axis direction (XY plane direction) correspond to planar directions of a substrate or a layer. The substrate 1 and the support substrate 7 face each other. In this example, the substrate 1, among the substrate 1 and the support substrate 7, is located on the Z-axis negative direction side, and the support substrate 7 is located on the Z-axis positive direction side. The chip 2, the buried layer 3, the seam portion 4, the sealing layer 5, and the auxiliary layer 6 are located between the substrate 1 and the support substrate 7.

The light detection device 100 includes a wiring layer. Wiring lines provided in the wiring layer are all denoted as wiring lines L in the drawings. An example of the material of the wiring line L is copper (Cu) or the like. Some vias connecting the wiring lines L of different wiring layers are also illustrated with the same hatching as the wiring lines L.

The substrate 1 is, for example, a semiconductor substrate such as a silicon (Si) semiconductor substrate, and includes a light detection element 1p. An example of the light detection element is a photoelectric conversion element such as a photo diode (PD). For example, a plurality of photoelectric conversion elements arranged in an array in the XY plane direction can correspond to the light detection element 1p.

Although not illustrated, the substrate 1 also includes a circuit element such as a transistor for driving each photoelectric conversion element and extracting an electric signal corresponding to the amount of received light of each photoelectric conversion element. A circuit including such a circuit element is also referred to as a pixel circuit.

Among the front surfaces of the substrate 1, a surface on the Z-axis positive direction side is denoted as a front surface 1a in the drawing. The surface on the Z-axis negative direction side is denoted as a back surface 1b in the drawing. The light detection device 100 illustrated is a back-illuminated light detection device that detects light incident on the back surface 1b of the substrate 1.

The substrate 1 has a wiring layer on the front surface 1a side. The wiring line L of the wiring layer of the substrate 1 can constitute a part of the pixel circuit. The wiring layer of the illustrated substrate 1 is a multi-layered wiring layer, and some wiring lines L are exposed on the front surface 1a.

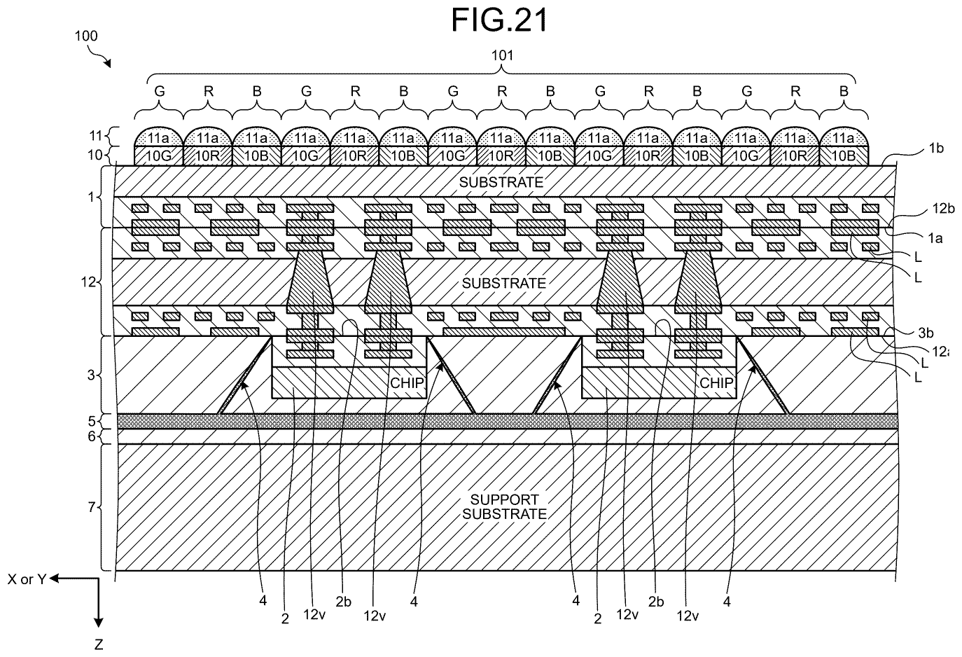

The chip 2 is provided for the substrate 1. Being provided for the substrate 1 may be understood to include not only provided directly on the substrate 1 but also provided through another element (for example, an additional substrate 12 in FIG. 21 described below). In the example illustrated in FIG. 1, the chip 2 is provided directly on the substrate 1, more specifically on the front surface 1a of the substrate 1. The mounting surface of the chip 2 is denoted as a mounting surface 2b in the drawing. The chip 2 has a wiring layer on the mounting surface 2b side. The wiring layer of the exemplified chip 2 is a multi-layered wiring layer, and some wiring lines I are exposed on the mounting surface 2b.

The chip 2 is provided on the substrate 1 such that the mounting surface 2b of the chip 2 is in contact with the front surface 1a of the substrate 1. More specifically, the chip 2 is mounted on the substrate 1 such that the wiring line L of the chip 2 and the wiring line L of the substrate 1 are in contact with and electrically connected to each other. When the material of the wiring line L is Cu, this type of connection is also referred to as Cu-Cu bonding or the like. The mounting surface 2b of the chip 2 and the front surface 1a of the substrate 1 define a bonding surface (chip bonding surface) between the chip 2 and the substrate 1.

The chip 2 may be any chip (IC or the like) that can be used for the light detection device 100. An example of the chip 2 is a logic chip, which drives a transistor of a pixel circuit or processes an electric signal extracted from the pixel circuit, for example. Another example of the chip 2 is a memory chip, which stores data used in processing on the logic chip and data obtained by the processing, for example. Still another example of the chip 2 is an artificial intelligence (AI) chip, which is specifically designed to perform high-speed arithmetic processing using a trained model (for example, a trained Deep Neural Network (DNN)).

As understood from FIG. 1, the chip 2 provided on the substrate 1 forms a step. In this example, the chip 2 is a step portion having a protruding shape protruding in the Z-axis positive direction with respect to the front surface 1a of the substrate 1. Note that the number of chips 2 included in the light detection device 100 is not limited to the example illustrated in FIG. 1. The light detection device 100 may include one or more optional number of chips 2.

The buried layer 3 is provided so as to cover the chip 2, more specifically, so as to cover the substrate 1 and the chip 2 in this example. The buried layer 3 can function as a protective layer that protects the chip 2. For example, the layer suppresses entry of moisture, chemicals, undesired gas, and the like into the chip 2. Examples of the material of the buried layer 3 include SiN and SiO2. Among the front surfaces of the buried layer 3, a surface on the Z-axis positive direction side is denoted as a front surface 3a in the drawing. The surface on the Z-axis negative direction side is denoted as a back surface 3b in the drawing.

The seam portion 4 occurs in the buried layer 3 due to the step formed by the chip 2. For example, the seam portion 4 extends from a rising portion of the step or a peripheral portion thereof as a starting point to the front surface 3a of the buried layer 3.

At least a part of the seam portion 4 may be an empty space. The empty space included in the seam portion 4 is denoted as an empty space 4a in the drawing. In the example illustrated in FIG. 1, entire portions of the seam portions 4 are formed as the empty space 4a. In the front surface 3a of the buried layer 3, a portion where the seam portion 4 is located is open.

The sealing layer 5 is provided so as to cover the buried layer 3 and the seam portion 4. The opening on the front surface 3a of the buried layer 3, formed by the seam portion 4, is also closed by the sealing layer 5. The sealing layer 5 suppresses communication of the seam portion 4 to the outside. The material of the sealing layer 5 may be the same as or different from the material of the buried layer 3. Some examples of the material of the sealing layer 5 will be described below.

The auxiliary layer 6 is provided so as to cover the sealing layer 5. The auxiliary layer 6 includes a material suitable for bonding with the support substrate 7, for example. An example of the material of the auxiliary layer 6 is mainly SiOx (including SiNx, SiON, SiCN, or SiOC). Among the front surfaces of the auxiliary layer 6, a surface on the Z-axis positive direction side is denoted as a front surface 6a in the drawing.

The support substrate 7 is located on a side opposite to the substrate 1 across the sealing layer 5, and directly or indirectly supports the sealing layer 5. The support substrate 7 may be, for example, a silicon (Si) semiconductor substrate or the like. In the example illustrated in FIG. 1, the support substrate 7 is located on the opposite side of the substrate 1 across the sealing layer 5 and the auxiliary layer 6, and is laminated to the auxiliary layer 6 so as to support the sealing layer 5 (that is, indirectly support the sealing layer 5) through the auxiliary layer 6. Among the front surfaces of the support substrate 7, a surface on the Z-axis positive direction side is denoted as a front surface 7a in the drawing. The surface on the Z-axis negative direction side is denoted as a back surface 7b in the drawing. The back surface 7b of the support substrate 7 and the front surface 6a of the auxiliary layer 6 define a bonding surface (support substrate bonding surface) between the support substrate 7 and the auxiliary layer 6. Incidentally, the light detection device 100 does not need to include the auxiliary layer 6. In this case, the support substrate 7 is laminated to the sealing layer 5 so as to directly support the sealing layer 5.

According to the light detection device 100 described above, the sealing layer 5 covering the buried layer 3 and the seam portion 4 are provided, making it possible to suppress communication of the seam portion 4 to the outside. Specifically, in the example illustrated in FIG. 1, it is possible to prevent the seam portion 4 from reaching the front surface 6a of the auxiliary layer 6, which is a bonding surface with the support substrate 7. Allowing the seam portion 4 to reach the front surface 6a of the auxiliary layer 6 would form an opening in the bonding surface with the support substrate 7, having a possibility of degradation of bonding quality due to occurrence of voids or the like. Such degradation in bonding quality is suppressed by the light detection device 100.

Several other embodiments based on the above technique will be described. The technical features of the embodiments may be appropriately combined within a range without contradiction.

### 2. Second Embodiment

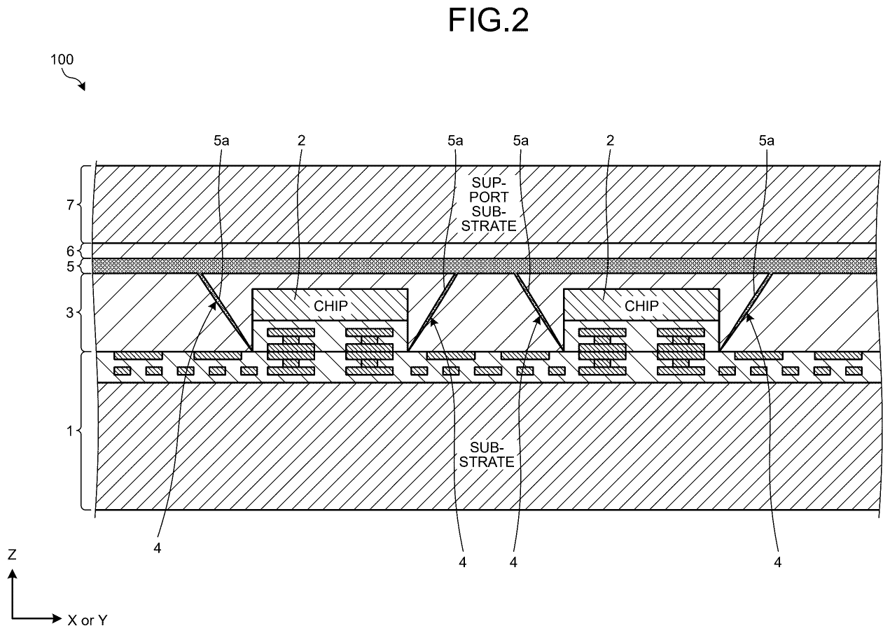

FIG. 2 is a diagram illustrating an example of a schematic configuration of a light detection device according to a second embodiment. The sealing layer 5 includes an extension 5a extending into the seam portion 4. The extension 5a extends so as to fill at least a part of the seam portion 4. In the example illustrated in FIG. 2, the extension 5a extends so as to fill the entire seam portion 4. The seam portion 4 has no empty space 4a (FIG. 1). The material of the sealing layer 5 (the material of the extension 5a) includes a low-permeability material. Examples of the low-permeability material include SiN-based materials. Examples of the SiN-based material include SiNx, SiCN, and SiON. The extension 5a of the sealing layer 5 described above fills the seam portion 4, leading to an enhanced effect of suppressing intrusion of moisture or the like into the chip 2, for example. This also leads to an increase in reliability and the like.

### 3. Third Embodiment

In one embodiment, the material of the sealing layer 5 includes a low Young's modulus material. Examples of the low Young's modulus material include a low-k material and an organic material. An example of the low-k material is porous SiO2 or the like. Examples of the organic material include silicone, siloxane, and polyimide. With the extension 5a of the sealing layer 5 described above filling the seam portion 4, for example, it is possible to alleviate the stress between the chips.

### 4. Fourth Embodiment

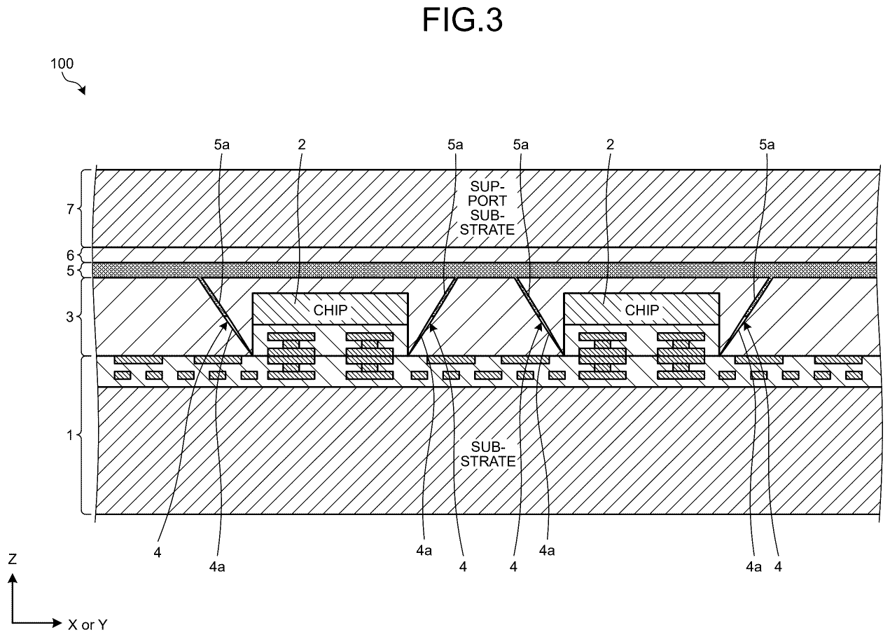

FIG. 3 is a diagram illustrating an example of a schematic configuration of a light detection device according to a fourth embodiment. The extension 5a of the sealing layer 5 extends so as to fill only a part of the seam portion 4. The remaining part of the seam portion 4 is an empty space 4a. By leaving the empty space 4a, the stress between the chips can be alleviated.

Hereinafter, unless otherwise specified, a case where the extension 5a of the sealing layer 5 extends so as to fill the entire seam portion 4 will be described.

### 5. Fifth Embodiment

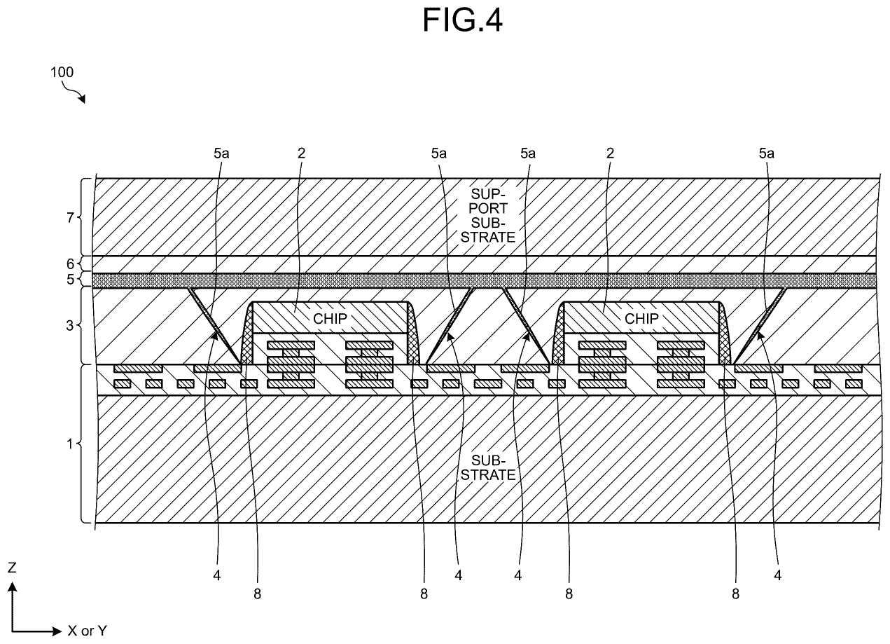

FIG. 4 is a diagram illustrating an example of a schematic configuration of a light detection device according to a fifth embodiment. The light detection device 100 further includes a side wall 8. The side wall 8 is provided so as to cover a side surface (side wall) of the chip 2. The buried layer 3 is provided so as to cover the substrate 1, the chip 2, and the side wall 8. An example of the material of the side wall 8 is an inorganic material or the like. An example of the inorganic material is mainly SiOx (including SiNx, SiON, SiCN, and SiOC). The presence of the side wall 8 can further increase the protectability of the chip 2.

### 6. Sixth Embodiment

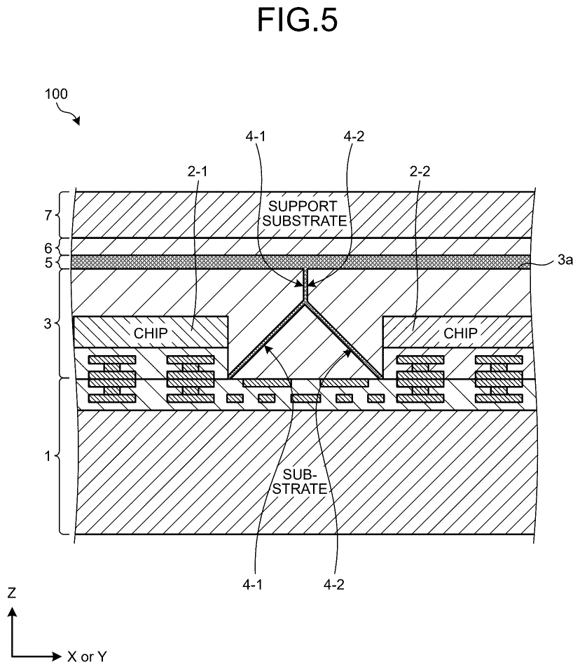

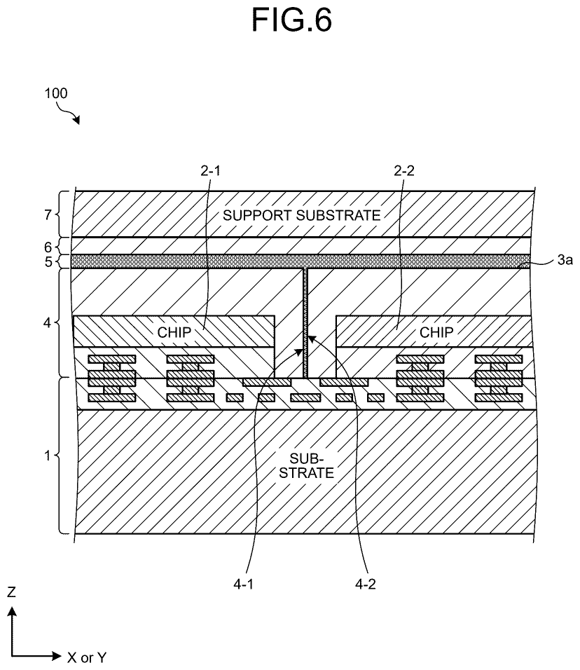

FIGS. 5 and 6 are diagrams illustrating an example of a schematic configuration of a light detection device according to a sixth embodiment. The seam portions 4 that have occurred due to the two different chips 2 are connected to each other. Among the two chips 2, a first chip is denoted as a chip 2-1 in the drawing. The second chip is denoted as a chip 2-2 in the drawing.

The seam portion 4 includes a seam portion 4-1 and a seam portion 4-2. The seam portion 4-1 is a first seam portion that has occurred due to the chip 2-1. The seam portion 4-2 is a second seam portion that has occurred due to the chip 2-2. In the example illustrated in FIG. 5, the seam portion 4-1 and the seam portion 4-2 are connected to each other on the way toward the front surface 3a of the buried layer 3 and extend to the front surface 3a of the buried layer 3. In the example illustrated in FIG. 6, the step provided by the seam portion 4-1 and the seam portion 4-2 are connected to each other from the beginning, and extend together to the front surface 3a of the buried layer 3. For example, even with the seam portion 4-1 and the seam portion 4-2 connected to each other in this manner, it is also possible to suppress communication of the portions to the outside.

### 7. Seventh Embodiment

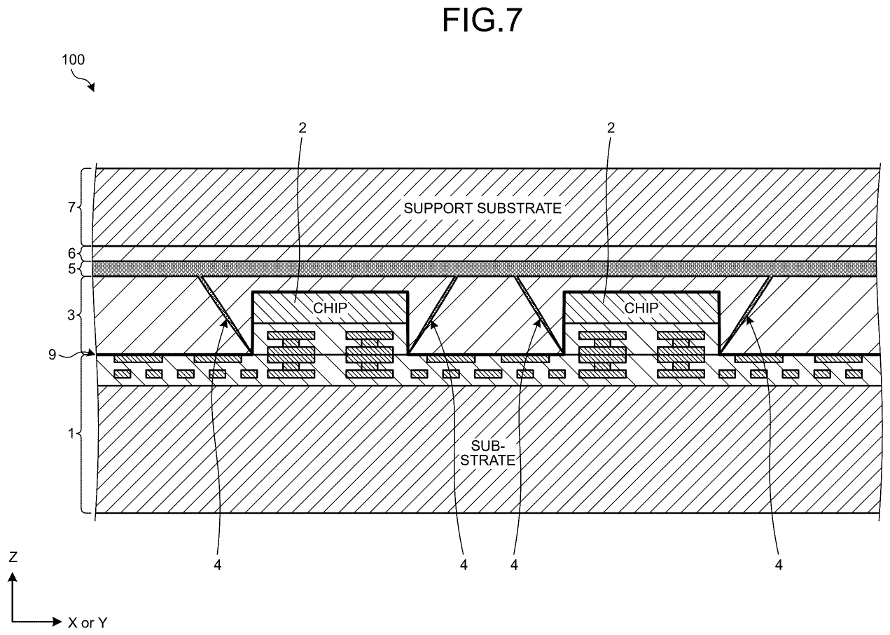

FIG. 7 is a diagram illustrating an example of a schematic configuration of a light detection device according to a seventh embodiment. The light detection device 100 further includes an additional layer 9. The additional layer 9 is provided between the substrate 1 and the chip 2, and the buried layer 3. In other words, the additional layer 9 is provided so as to cover the substrate 1 and the chip 2, with the buried layer 3 provided so as to cover the additional layer 9. The material of the additional layer 9 may be the same as or different from the material of the buried layer 3. An example of the material of the additional layer 9 is mainly SiNx (including SiOx, SiON, SiCN, and SiOC). The additional layer 9 may have a single layer structure or a stacked structure. The presence of the additional layer 9 can further increase the reliability.

### 8. Eighth Embodiment

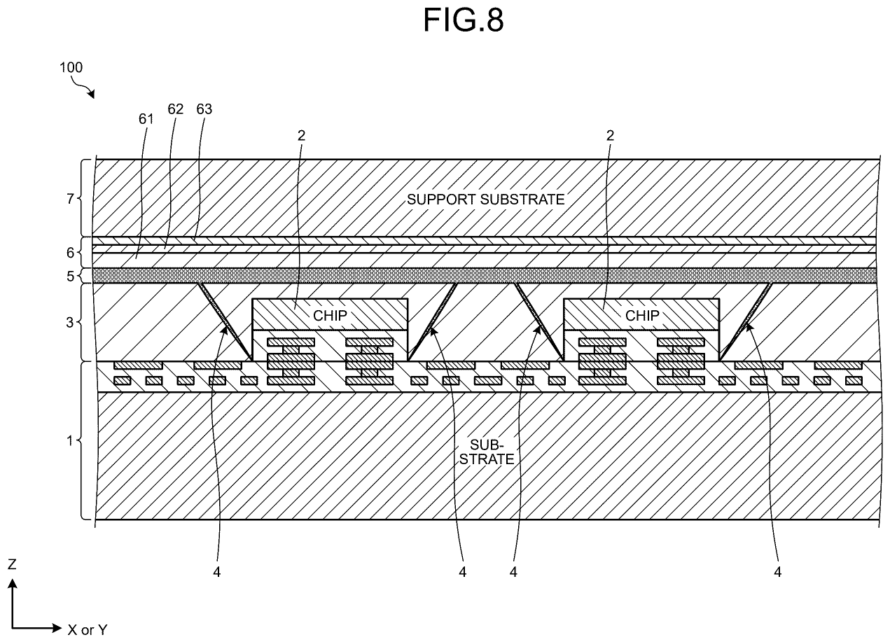

FIG. 8 is a diagram illustrating an example of a schematic configuration of a light detection device according to an eighth embodiment. The auxiliary layer 6 has a stacked structure. In this example, the auxiliary layer 6 has a three-layer structure, and includes a layer 61, a layer 62, and a layer 63 in this order in the Z-axis positive direction. The materials of the layer 61, the layer 62, and the layer 63 may be different from each other or may be the same material. With the various designs of the number of layers and material, it is possible to perform warpage adjustment, bonding margin enlargement, and the like.

### 9. Example of Manufacturing Method

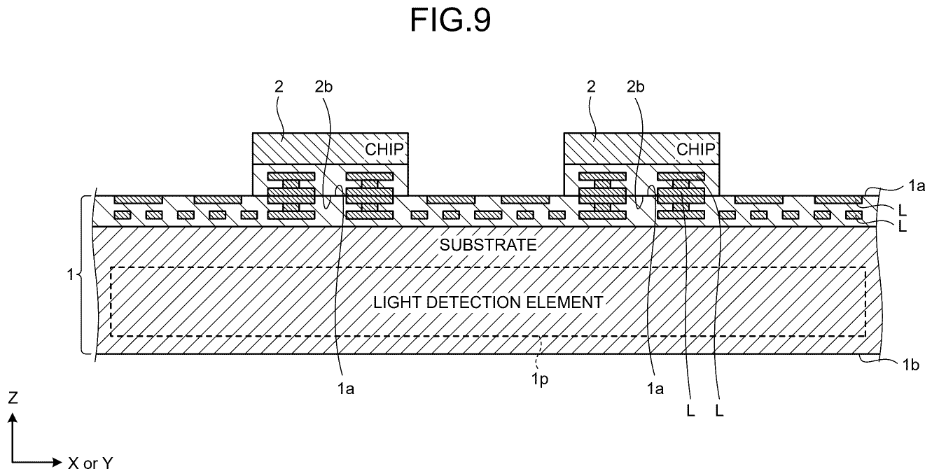

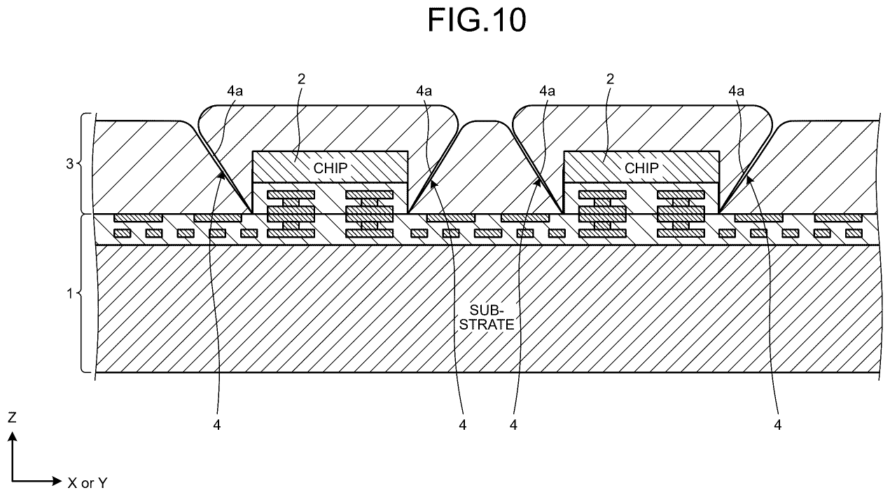

FIGS. 9 to 19 are diagrams illustrating examples of a method of manufacturing the light detection device. FIGS. 9 to 14 illustrate examples of a method of manufacturing the light detection device 100 (FIGS. 1 to 3 and FIGS. 5 to 8) according to the first to fourth embodiments and the sixth to eighth embodiments described above.

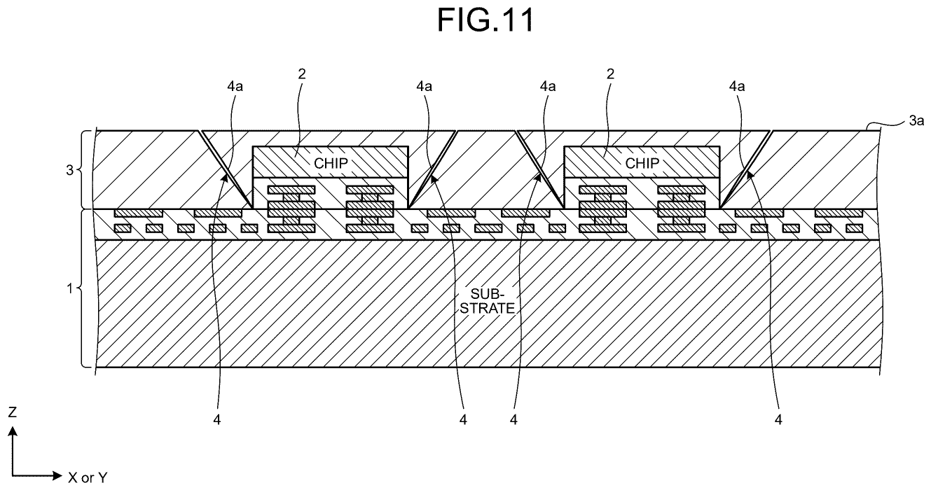

As illustrated in FIG. 9, the substrate 1 including a light detection element 1p is prepared, and the chip 2 is provided on the substrate 1. As illustrated in FIG. 10, the buried layer 3 is provided so as to cover the substrate 1 and the chip 2. Due to the step formed by the chip 2, the seam portion 4 occurs in the buried layer 3. At this point, the entire seam portion 4 is the empty space 4a.

As in the above-described sixth embodiment (FIGS. 5 and 6), the seam portions 4 corresponding to the adjacent chips 2 may be connected to each other. In the case of the seventh embodiment (FIG. 7) described above, the additional layer 9 (FIG. 7) is provided so as to cover the substrate 1 and the chip 2, and thereafter, the buried layer 3 is provided so as to cover the additional layer 9.

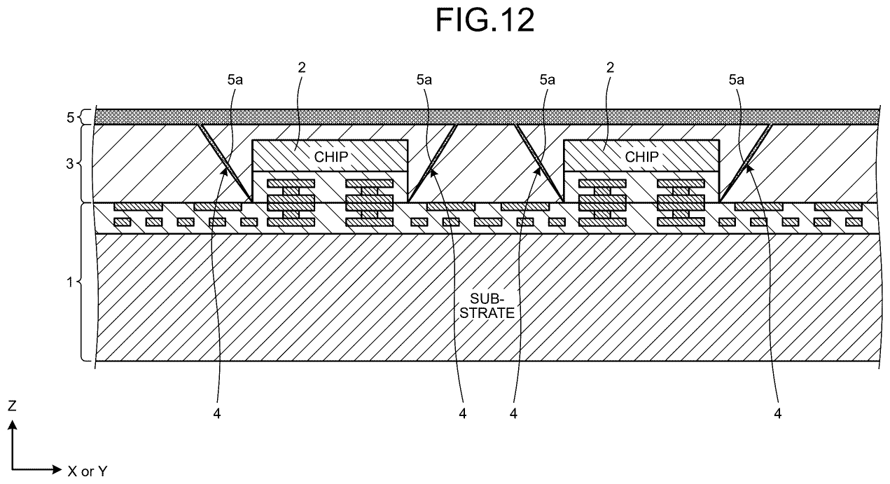

By polishing and cleaning the top (the portion on the Z-axis positive direction side) of the buried layer 3, a planarized front surface 3a is obtained as illustrated in FIG. 11. A portion of the front surface 3a where the seam portion 4 reaches is open. In this state, as illustrated in FIG. 12, the sealing layer 5 is provided so as to cover the buried layer 3. The opening of the front surface 3a is closed by the sealing layer 5.

In the case of the first embodiment (FIG. 1) described above, the entire seam portion 4 remains as the empty space 4a. In the case of the second embodiment and the third embodiment (FIG. 2) described above, the entire seam portion 4 is filled with the material of the sealing layer 5, and the filled portion is to be the extension 5a of the sealing layer 5. In the case of the above-described fourth embodiment (FIG. 3), only a part of the seam portion 4 is filled with the material of the sealing layer 5, and the filled portion is to be the extension 5a of the sealing layer 5. In the case of the above-described sixth to eighth embodiments (FIGS. 5 to 8), any mode may be adopted.

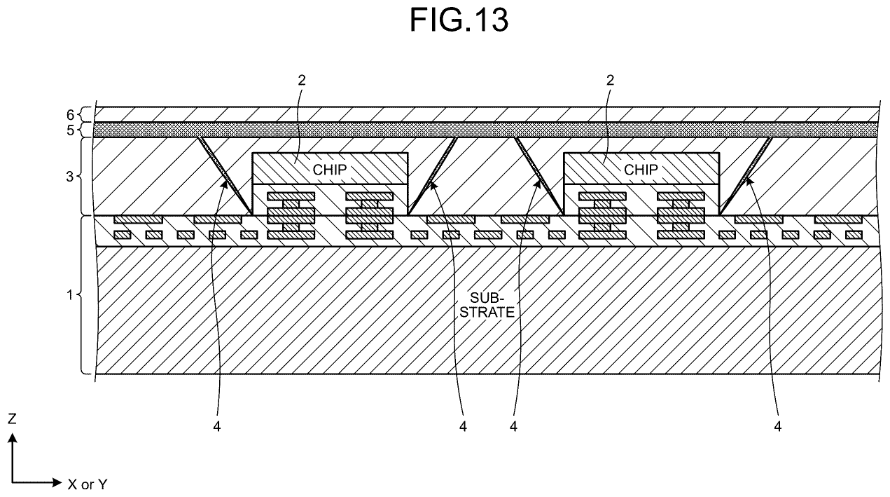

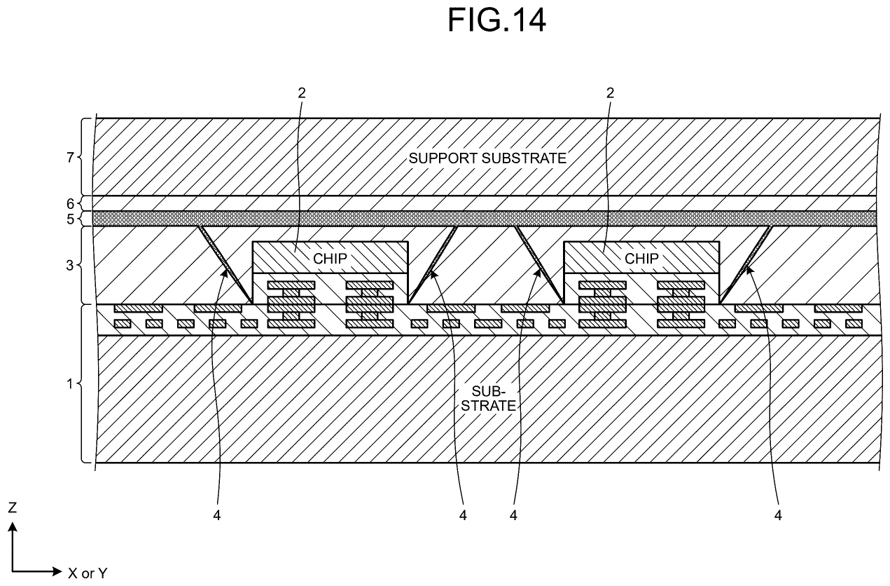

As illustrated in FIG. 13, the auxiliary layer 6 is provided so as to cover the sealing layer 5. Thereafter, the auxiliary layer 6 is polished and cleaned. Since the seam portion 4 is covered with the sealing layer 5, the seam portion 4 does not spread even when cleaning is performed. In the case of the above-described eighth embodiment (FIG. 8), a plurality of layers (for example, layer 61, layer 62, and layer 63) are provided to allow the auxiliary layer 6 to have a stacked structure. As illustrated in FIG. 14, the support substrate 7 is laminated to the auxiliary layer 6.

The methods described above, for example, enable manufacturing of the light detection device 100 according to the first to fourth embodiments and the sixth to eighth embodiments described above.

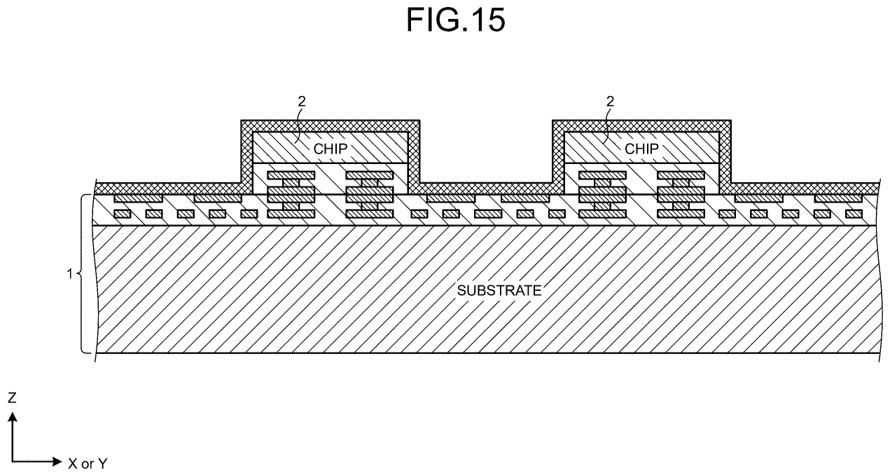

FIGS. 15 to 19 illustrate examples of the manufacturing method according to the above-described fifth embodiment (FIG. 4). The preparation of the substrate 1 and the placement of the chip 2 on the substrate 1 are similar to the procedure in FIG. 9 described above. As illustrated in FIG. 15, the material of the side wall 8 (FIG. 4) is provided so as to cover the substrate 1 and the chip 2.

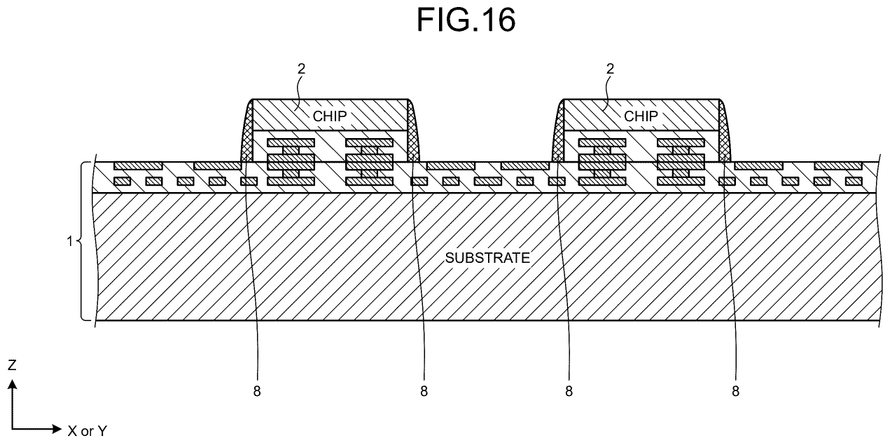

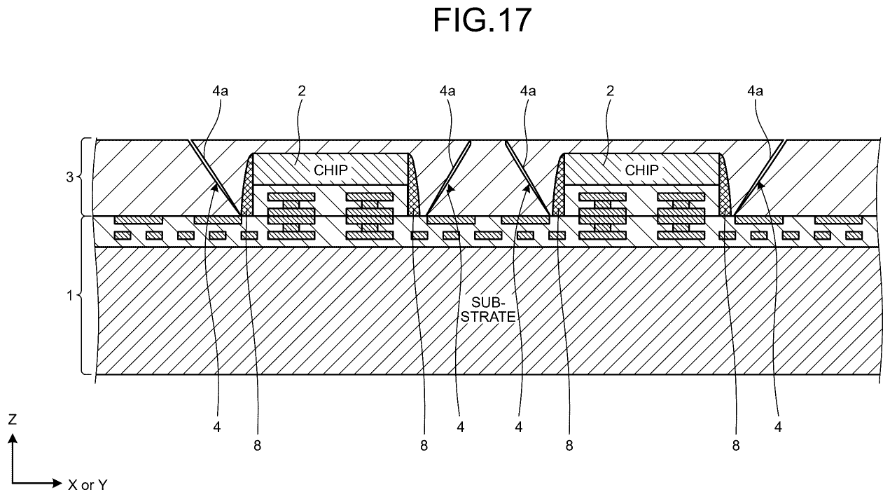

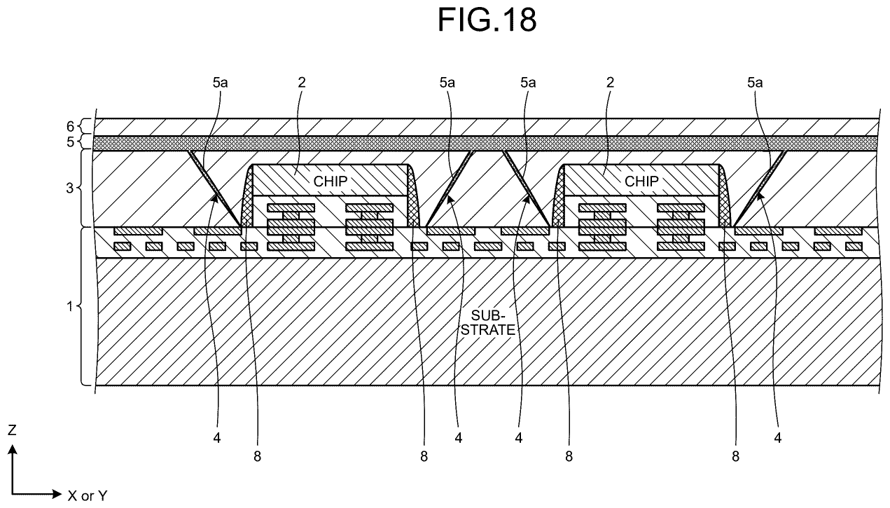

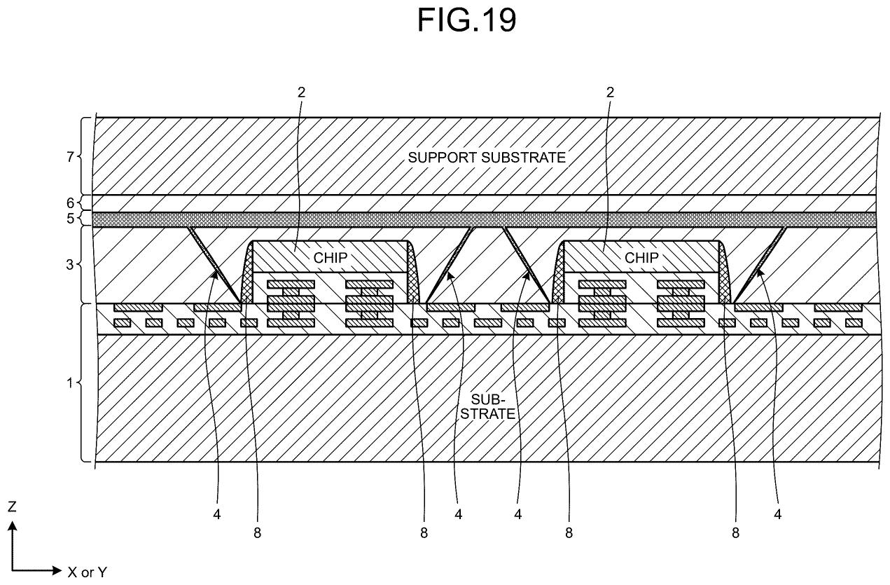

As illustrated in FIG. 16, etching (for example, dry etching) is performed such that the above-described material remains on the side surface of the chip 2. The material remaining on the side surface of the chip 2 forms the side wall 8. As illustrated in FIG. 17, the buried layer 3 is provided so as to cover the substrate 1, the chip 2, and the side wall 8. Due to the step formed by the chip 2, the seam portion 4 occurs in the buried layer 3. As illustrated in FIG. 18, the auxiliary layer 6 is provided so as to cover the sealing layer 5. As illustrated in FIG. 19, the support substrate 7 is laminated to the auxiliary layer 6.

The methods described above, for example, enable manufacturing of the light detection device 100 according to the fifth embodiment described above.

### 10. Example of Application to Imaging Device

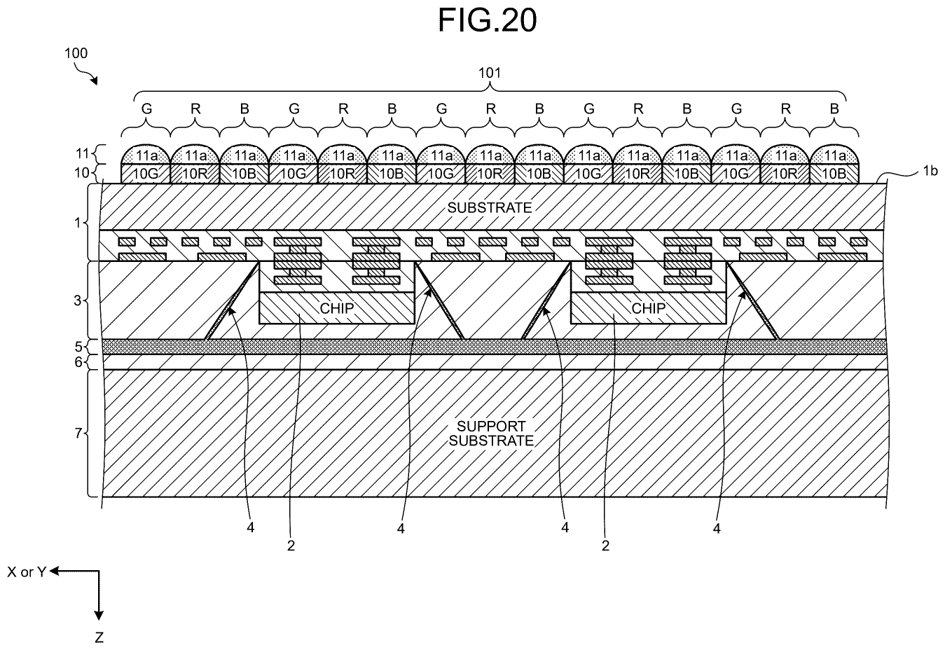

An application example of the light detection device 100 described above is an imaging device. This will be described with reference to FIGS. 20 to 23

FIG. 20 is a diagram illustrating an example of a schematic configuration of a light detection device according to an application example. Note that the direction of the Z axis is opposite to the direction in the previous drawings. The illustrated light detection device 100 is an imaging device configured to include a plurality of pixels 101. Examples of the pixel 101 include a pixel G that receives green light, a pixel R that receives red light, and a pixel B that receives blue light. The substrate 1 is a substrate (image sensor substrate) configured to include a photoelectric conversion element corresponding to each pixel 101. The light detection device 100 includes a filter layer 10 and a lens layer 11.

The filter layer 10 is provided on the side opposite to the chip 2 and the buried layer 3 across the substrate 1. In this example, the filter layer 10 is provided on the back surface 1b of the substrate 1. The filter layer 10 includes a plurality of filters corresponding to the plurality of pixels 101. The filter provided in the pixel G is denoted as a filter 10G in the drawing. The filter provided in the pixel R is denoted as a filter 10R in the drawing. The filter provided in the pixel B is denoted as a filter 10B in the drawing. The filter 10G allows passage of green light. The filter 10R allows passage of red light. The filter 10B allows passage of blue light. It is allowable to use various known materials such as resins.

The lens layer 11 is provided on the side opposite to the substrate 1 across the filter layer 10. The lens layer 11 includes a plurality of lenses 11a corresponding to the plurality of pixels 101. The lens 11a is a condenser lens that condenses light incident on the photoelectric conversion element of the substrate 1 through the filter layer 10. It is allowable to use various known materials such as resins.

For example, the light detection device 100 having the above configuration can be used as an imaging device. It is also allowable to use other configurations, and some examples will be described with reference to FIGS. 21 to 23.

FIG. 21 is a diagram illustrating an example of a schematic configuration of a light detection device according to an application example. The light detection device 100 further includes an additional substrate 12. The additional substrate 12 is provided between the substrate 1 and the buried layer 3. The additional substrate 12 is also considered to be an intermediate substrate located between the substrate 1 and the support substrate 7. Among the front surfaces of the additional substrate 12, a surface on the Z-axis positive direction side is denoted as a front surface 12a in the drawing. The surface on the Z-axis negative direction side is denoted as a back surface 12b in the drawing. The front surface 12a of the additional substrate 12 is in contact with the back surface 3b of the buried layer 3, while the back surface 12b of the additional substrate 12 is in contact with the front surface 1a of the substrate 1.

The additional substrate 12 has wiring layers individually on the front surface 12a side and the back surface 12b side. The wiring layer of the exemplified additional substrate 12 is a multi-layered wiring layer, and some wiring lines L are exposed on the front surface 12a or the back surface 12b.

The chip 2 is provided on the additional substrate 12 such that the mounting surface 2b of the chip 2 is in contact with the front surface 12a of the additional substrate 12. More specifically, the chip 2 is mounted on the additional substrate 12 such that the wiring line L of the chip 2 and the wiring line L of the additional substrate 12 are in contact with and electrically connected to each other. The mounting surface 2b of the chip 2 and the front surface 12a of the additional substrate 12 define a bonding surface (chip bonding surface) between the chip 2 and the additional substrate 12.

The additional substrate 12 is laminated to the substrate 1 such that the wiring line L of the additional substrate 12 and the wiring line L of the substrate 1 come in contact with each other to be electrically connected. The front surface 1a of the substrate 1 and the back surface 12b of the additional substrate 12 define a bonding surface (F2F bonding surface) between the substrate 1 and the additional substrate 12.

The additional substrate 12 includes a penetrating via 12v. The penetrating via 12v penetrates a portion (substrate portion) between the wiring layer on the front surface 12a side of the additional substrate 12 and the wiring layer on the back surface 12b side of the additional substrate 12 so as to connect therebetween. By also using the wiring layer of the additional substrate 12, more wiring lines and circuit elements can be formed. This leads to further functional enhancement of the light detection device 100. Note that the number of the additional substrates 12 to be provided may be two or more.

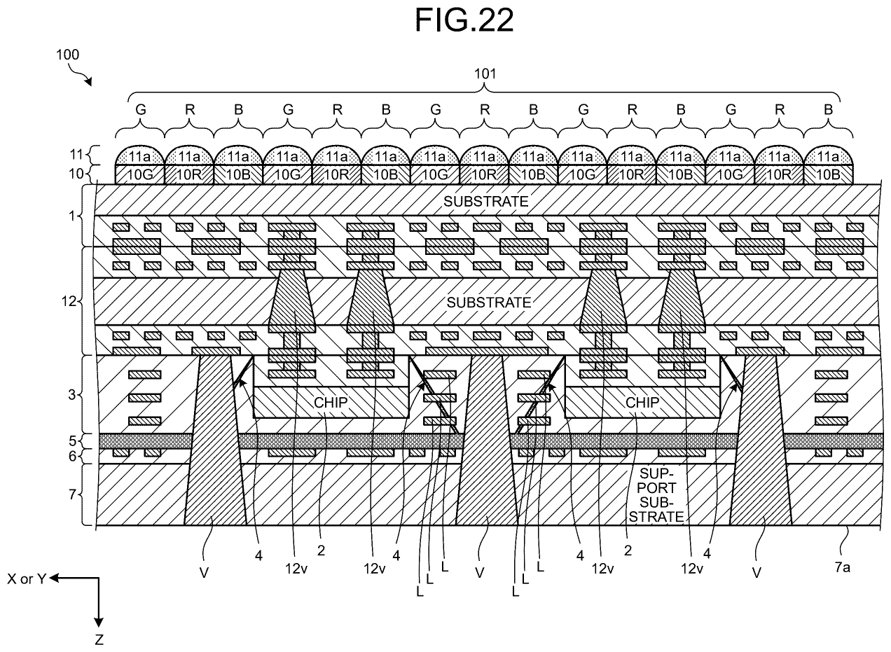

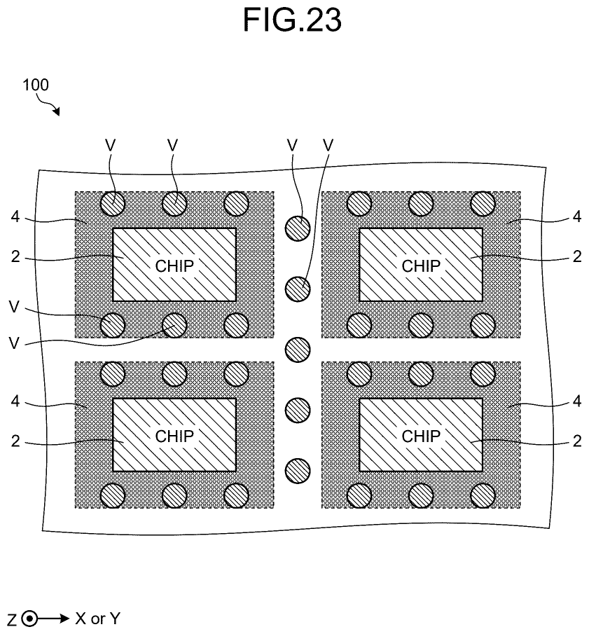

FIGS. 22 and 23 are diagrams illustrating an example of a schematic configuration of a light detection device according to an application example. As illustrated in FIG. 22, the wiring line L and the structure are also provided between the chips 2 disposed adjacent to each other at an interval. An example of the structure is a penetrating via V.

Specifically, as illustrated in FIG. 22, the wiring line L is also included in the buried layer 3 and the auxiliary layer 6. Some wiring lines L are provided between the adjacent chips 2. With the wiring line L provided also in the buried layer 3 and the auxiliary layer 6, it is possible to achieve further functional enhancement of the light detection device 100. The wiring line L may also be provided over the seam portion 4, improving the degree of freedom in layout accordingly.

The penetrating via V penetrates the buried layer 3, the sealing layer 5, the auxiliary layer 6, and the support substrate 7. The penetrating via V enables electrical access from the front surface 7a of the support substrate 7 to the wiring layer on the front surface 12a side of the additional substrate 12. The penetrating via V can also be referred to as a contact via. In the buried layer 3, at least some of the penetrating vias V are located between the adjacent chips 2. In addition, the penetrating via V may penetrate the seam portion 4. Specifically, FIG. 23 schematically illustrates a planar layout. In plan view (when viewed in the Z-axis direction), some of the plurality of penetrating vias V disposed around the chip 2 overlap the seam portion 4. The penetrating via V can be located at various positions, improving the degree of freedom in layout accordingly.

### 11. Example of Effects

The technology described above is specified as follows, for example. One of the disclosed techniques is the light detection device 100. As described with reference to FIG. 1 and the like, the light detection device 100 includes: the substrate 1 including the light detection element 1p; the chip 2 provided for the substrate 1; the buried layer 3 provided to cover the chip 2; the seam portion 4 occurring in the buried layer 3 and extending to the front surface 3a of the buried layer 3; and the sealing layer 5 provided to cover the buried layer 3 and the seam portion 4.

According to the light detection device 100 described above, with the sealing layer 5 provided to cover the buried layer 3 and the seam portion 4, it is possible to suppress communication of the seam portion 4 to the outside.

As described with reference to FIG. 1 and the like, the light detection device 100 may include the support substrate 7, which is located on the opposite side of the substrate 1 across the sealing layer 5 and directly or indirectly supports the sealing layer 5. Since the seam portion 4 covered with the sealing layer 5 does not reach the bonding surface with the support substrate 7, it is possible to suppress degradation of bonding quality due to occurrence of voids or the like.

As described with reference to FIGS. 1 and 3 and the like, at least a part of the seam portion 4 may be the empty space 4a. This makes it possible to alleviate the stress between the chips, for example.

As described with reference to FIGS. 2 and 3 and the like, the sealing layer 5 may include the extension 5a extending into the seam portion 4 so as to fill at least a part of the seam portion 4. The material of the sealing layer 5 may include a low-permeability material. This increases the effect of suppressing entry of moisture or the like into the chip 2, for example. The material of the sealing layer 5 may include a low Young's modulus material. This makes it possible to alleviate the stress between the chips, for example.

As described with reference to FIG. 4 and the like, the light detection device 100 may include the side wall 8 provided to cover the side surface of the chip 2. This makes it possible to further increase the protectability of the chip 2.

As described with reference to FIGS. 5 and 6 and the like, the chip 2 may include the chip 2-1 (first chip) and the chip 2-2 (second chip) provided separated from each other, the seam portion 4 may include the seam portion 4-1 (first seam portion) occurring due to the chip 2-1 and the seam portion 4-2 (second seam portion) occurring due to the chip 2-2, and the seam portion 4-1 and the seam portion 4-2 may be connected to each other. For example, even with the seam portion 4-1 and the seam portion 4-2 connected to each other in this manner, it is also possible to suppress communication of the portions to the outside.

As described with reference to FIG. 7 and the like, the light detection device 100 may include the additional layer 9 provided between the chip 2 and the buried layer 3. This makes it possible to further increase the reliability.

As described with reference to FIGS. 1 and 8 and the like, the light detection device 100 may include the auxiliary layer 6 provided so as to cover the sealing layer 5. This makes it possible to facilitate bonding with the support substrate 7.

The auxiliary layer 6 may have a stacked structure. With the various designs of the number of layers and material, it is possible to perform warpage adjustment, bonding margin enlargement, and the like.

As described with reference to FIG. 1 and the like, the chip 2 may include at least one of a logic chip, a memory chip, and an artificial intelligence (AI) chip. For example, it is possible to provide a highly functionalized light detection device provided with such various chips 2.

As described with reference to FIG. 20 and the like, the light detection device 100 may be an imaging device configured to include the plurality of pixels 101. The light detection device 100 may include: the filter layer 10 provided on the side opposite to the chip 2 and the buried layer 3 across the substrate 1; and the lens layer 11 provided on the side opposite to the substrate across the filter layer 10. The light detection device 100 can be applied to an imaging device.

As described with reference to FIG. 21 and the like, the light detection device 100 may include the additional substrate 12 provided between the substrate 1 and the buried layer 3. This leads to functional enhancement of the light detection device 100.

As described with reference to FIG. 22 and the like, the chip 2 may include two chips 2 disposed adjacent to each other at an interval, and the buried layer 3 may include the wiring line L provided between the two chips 2. This makes it possible to achieve further functional enhancement of the light detection device 100. The light detection device 100 may include the penetrating via V penetrating the buried layer 3, the sealing layer 5, and the support substrate 7. This enables access from the front surface 7a of the support substrate 7 to the wiring layer on the front surface 12a side of the additional substrate 12.

Note that the effects described in the present disclosure are merely examples and are not limited to the disclosed contents. There may be other effects.

### 12. Example of Application to Mobile Body

The technology described so far can be applied to various products. For example, the light detection device 100 described so far may be applied to devices mounted on any of mobile body such as automobiles, electric vehicles, hybrid electric vehicles, motorcycles, bicycles, personal mobility, airplanes, drones, ships, and robots.

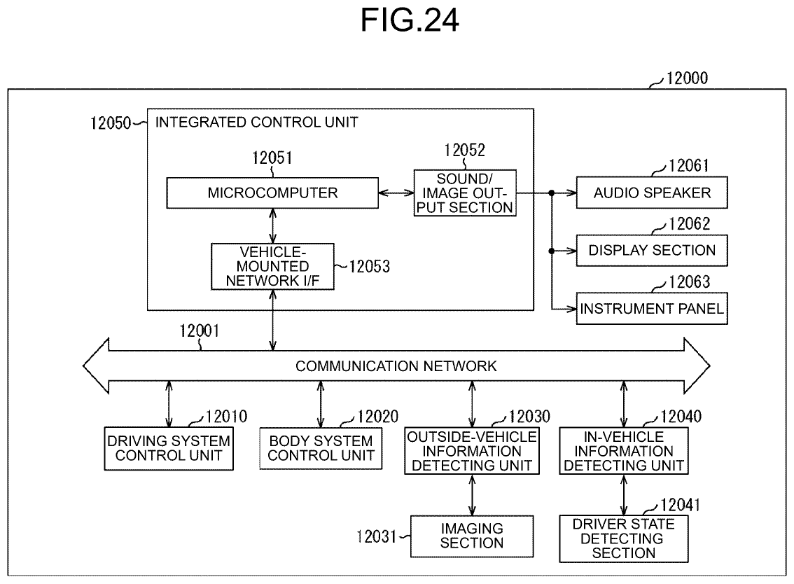

FIG. 24 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 24, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 24, an audio speaker 12061, a display section 12062, and an instrument panel 12063 are illustrated as the output device. The display section 12062 may, for example, include at least one of an on-board display and a head-up display.

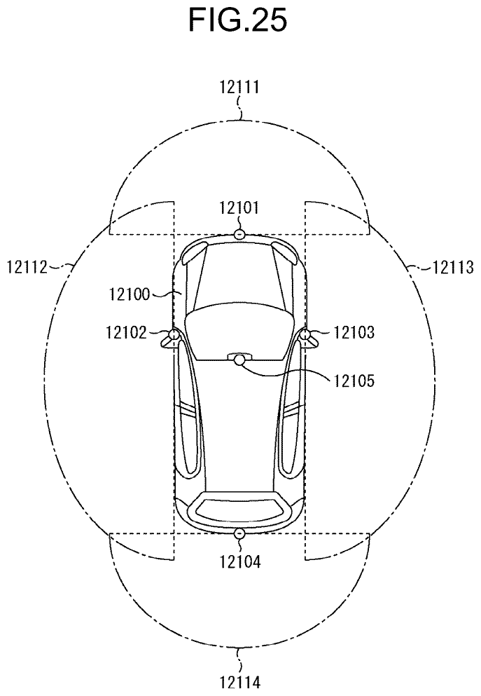

FIG. 25 is a diagram depicting an example of the installation position of the imaging section 12031.

In FIG. 25, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 25 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object.

When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The light detection device 100 described above can be applied to, for example, the imaging section 12031 among the above-described configurations. This makes it possible to further increase the reliability of a product including the light detection device 100.

Other embodiments of the light detection device 100 will be described. Note that the disclosed techniques, including the technical details described so far, may be appropriately combined within a range without contradiction. For example, the sealing layer 5 may, but does not need to, extend into the seam portion 4. The material of the sealing layer 5 may be a low-permeability material or a low Young's modulus material (for example, resin). The light detection device 100 may be an imaging device.

### 13. Ninth Embodiment

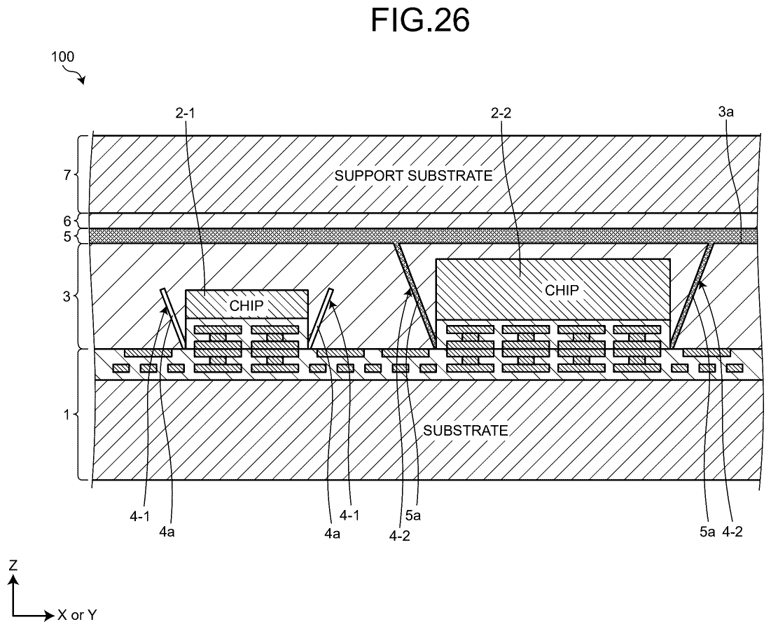

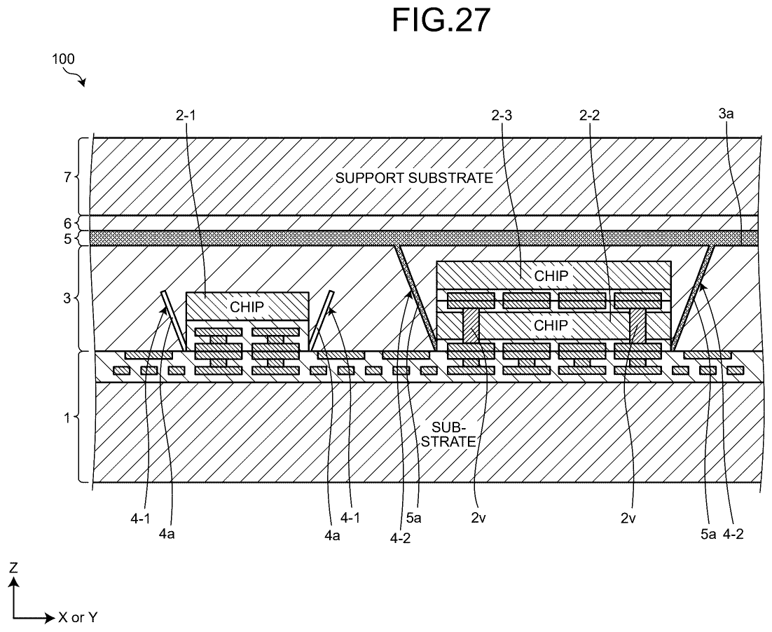

FIGS. 26 and 27 are diagrams illustrating an example of a schematic configuration of a light detection device according to a ninth embodiment. The chip 2 includes a plurality of chips 2. The plurality of chips 2 are illustrated as two chips 2 in FIG. 26, and three chips 2 in FIG. 27. The first chip is denoted as a chip 2-1 in the drawing. The second chip is denoted as a chip 2-2 in the drawing. The third chip is denoted as a chip 2-3 in the drawing. Note that the chip 2-1 and the chip 2-2 here may be understood separately from the chip 2-1 and the chip 2-2 of the sixth embodiment (FIGS. 5 and 6) described above.

In the example illustrated in FIG. 26, the chip 2-1 and the chip 2-2 have mutually different thicknesses (heights). The chip 2-2 has a thickness greater than the thickness of the chip 2-1. In other words, the chip 2-1 has a thickness smaller than the thickness of the chip 2-2. The seam portion 4 includes a seam portion 4-1 and a seam portion 4-2. The seam portion 4-1 is a first seam portion extending from the chip 2-1 toward the front surface 3a of the buried layer 3. The seam portion 4-2 is a second seam portion extending from the chip 2-2 toward the front surface 3a of the buried layer 3.

Since the thickness of the chip 2-1 is smaller than the thickness of the chip 2-2, the length of the seam portion 4-1 can be shorter than the length of the seam portion 4-2 in their thickness direction. The seam portion 4-2 can extend closer to the front surface 3a of the buried layer 3 compared with the seam portion 4-1. In the example illustrated in FIG. 26, the seam portion 4-2 reaches the front surface 3a of the buried layer 3, whereas the seam portion 4-1 does not reach the front surface 3a of the buried layer 3. The extension 5a of the sealing layer 5 can extend into the seam portion 4-2 so as to fill at least a part of the seam portion 4-2. In contrast, the seam portion 4-1 can be the empty space 4a.

In the example illustrated in FIG. 27, a chip 2-3 is provided on the chip 2-2. The chip 2-2 and the chip 2-3 are a plurality of chips 2 (stacked chips) stacked in this order. The chip 2-3 is electrically connected to the chip 2-2 through the wiring. The wiring lines also include a penetrating via 2v penetrating the chip 2. The chip 2-2 and the chip 2-3 as a whole have a thickness greater than the thickness of the chip 2-1. As long as this condition is satisfied, the thickness of the chip 2-2 may be the same as or different from the thickness of the chip 2-1. The similar applies to the chip 2-3. Note that the number of chips 2 to be stacked may be three or more.

The seam portion 4 is similar to FIG. 26 described above. The seam portion 4-2 may extend closer to the front surface 3a of the buried layer 3 compared with the seam portion 4-1. In the example illustrated in FIG. 27, the seam portion 4-2 reaches the front surface 3a of the buried layer 3, whereas the seam portion 4-1 does not reach the front surface 3a of the buried layer 3.

### <Example of Manufacturing Method>

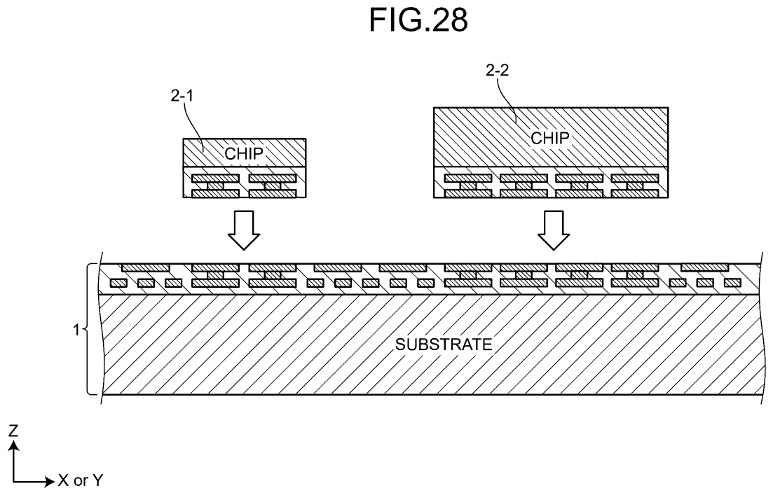

FIGS. 28 to 32 are diagrams each illustrating an example of a method of manufacturing the light detection device. Note that description overlapping with the above description regarding the manufacturing method will be omitted as appropriate.

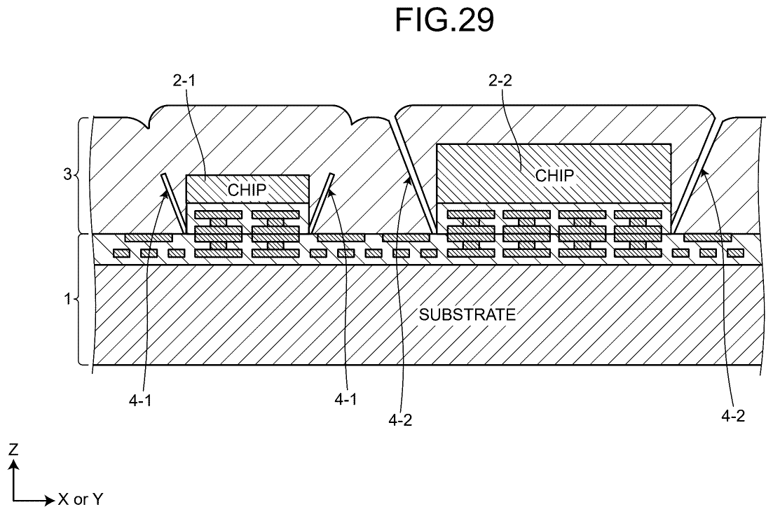

As illustrated in FIG. 28, the chip 2-1 and the chip 2-2 are located on the substrate 1. As illustrated in FIG. 29, the buried layer 3 is provided so as to cover the substrate 1, the chip 2-1, and the chip 2-2. A seam portion 4-1 and a seam portion 4-2 occur. At this point, both the seam portion 4-1 and the seam portion 4-2 are empty spaces.

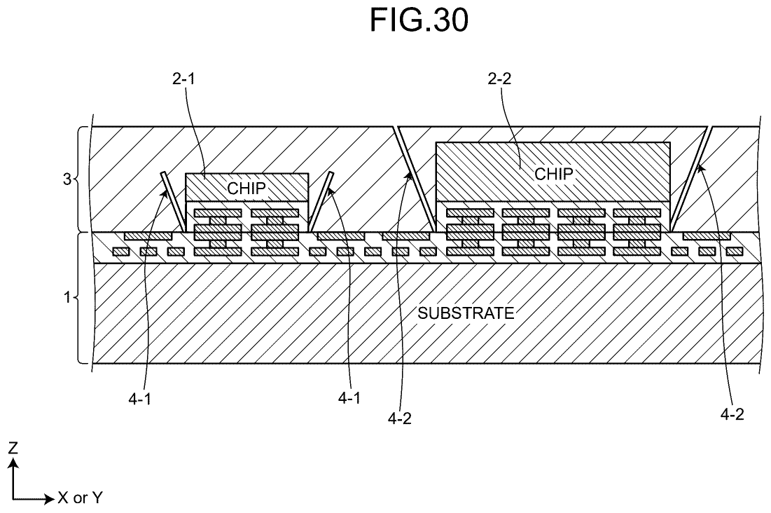

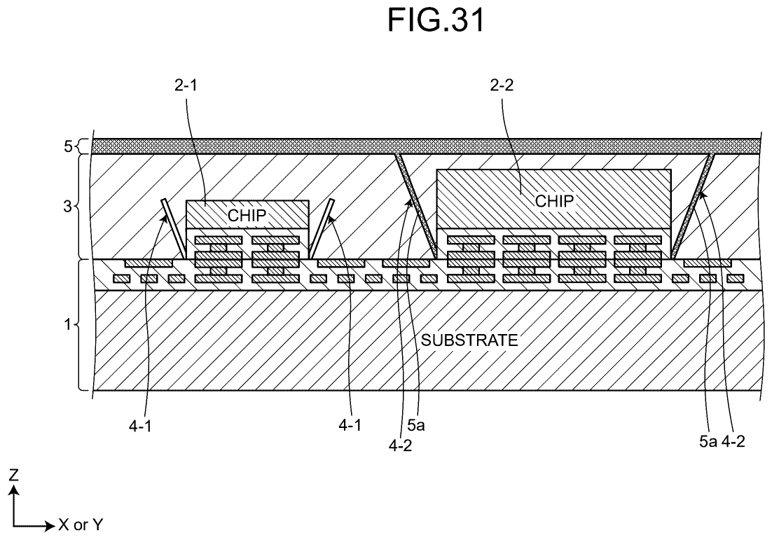

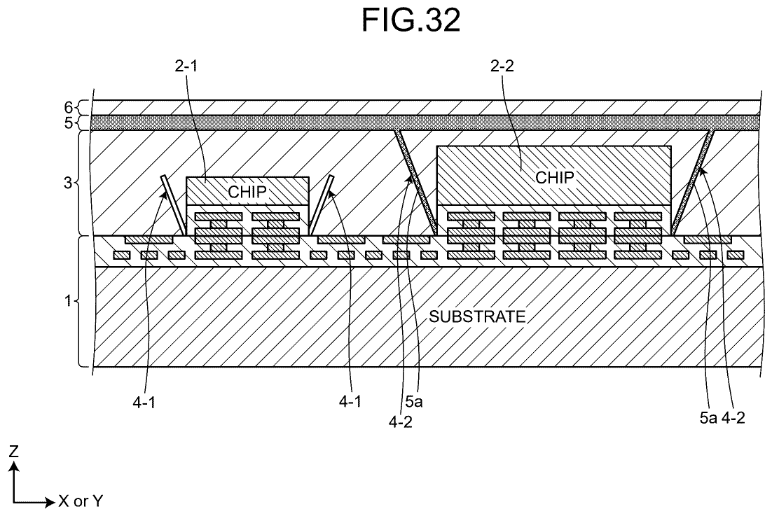

As illustrated in FIG. 30, the buried layer 3 is planarized. Among the seam portion 4-1 and the seam portion 4-2, the seam portion 4-2 has its upper portion open. As illustrated in FIG. 31, the sealing layer 5 is provided so as to cover the buried layer 3 and the seam portion 4-2. The sealing layer 5 extends into the seam portion 4-2, and the expending portion is to be the extension 5a of the sealing layer 5. As illustrated in FIG. 32, the auxiliary layer 6 is provided so as to cover the sealing layer 5. Thereafter, the support substrate 7 is laminated to the auxiliary layer 6 to obtain the configuration of FIG. 26 described above.

By replacing the chip 2-2 in the above manufacturing process with the stacked structure of the chip 2-2 and the chip 2-3, the configuration of FIG. 27 described above is obtained.

### <Modifications>

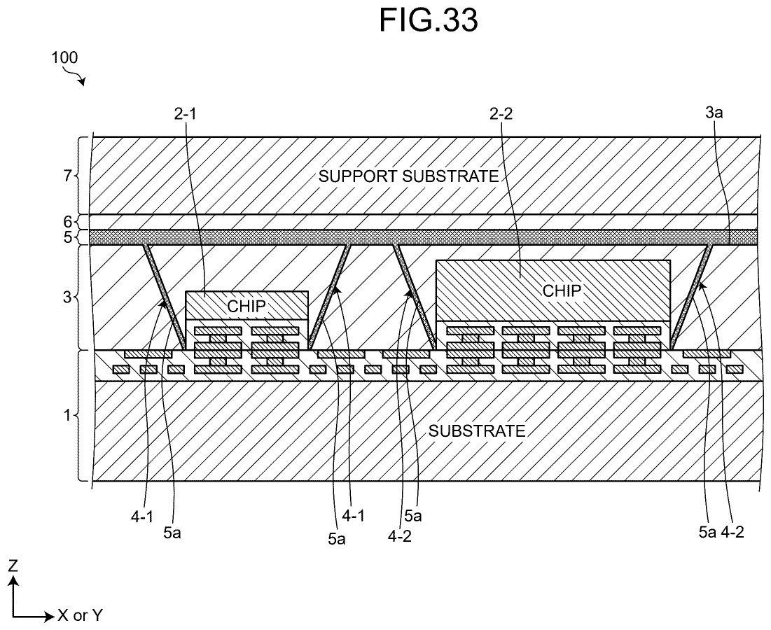

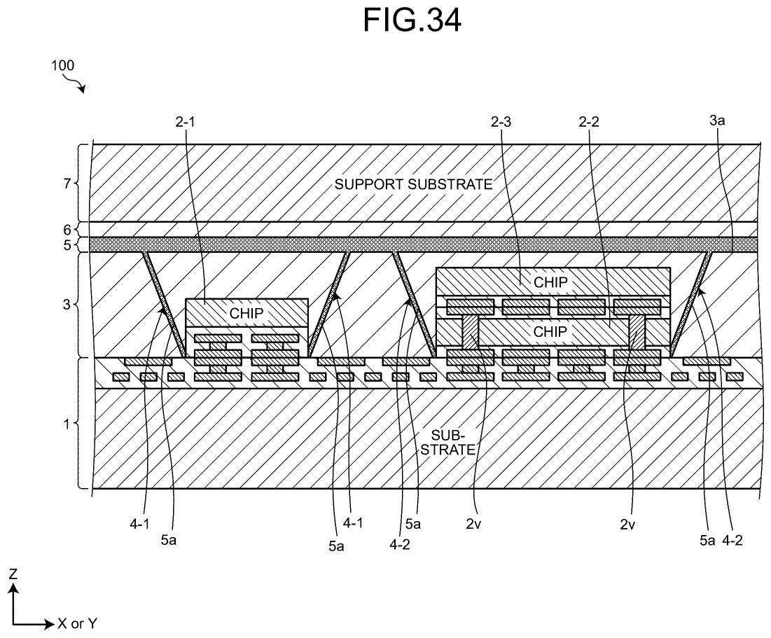

FIGS. 33 and 34 are diagrams illustrating modifications. The light detection devices 100 illustrated in FIGS. 33 and 34 are different from the light detection devices 100 in FIGS. 26 and 27 described above in that the seam portion 4-1 reaches the front surface 3a of the buried layer 3 and the extension 5a of the sealing layer 5 extends into the seam portion 4-1.

### 14. Tenth Embodiment

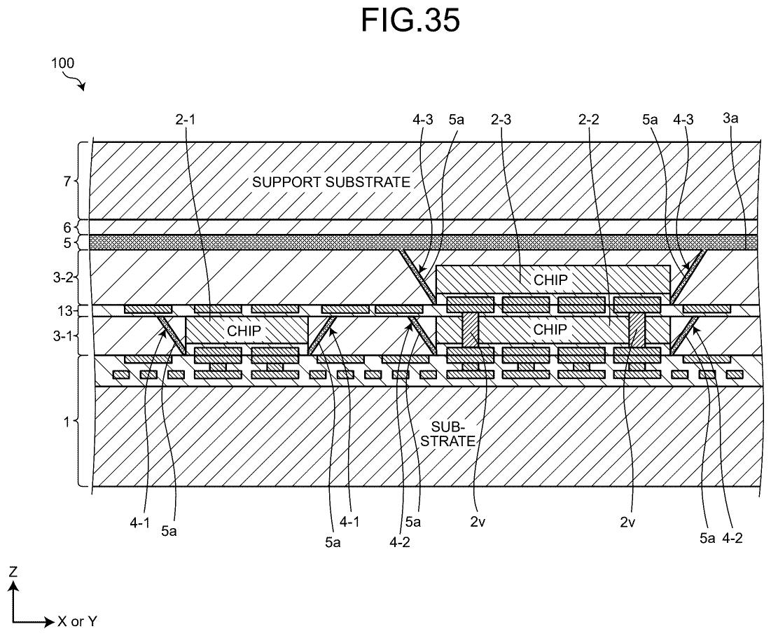

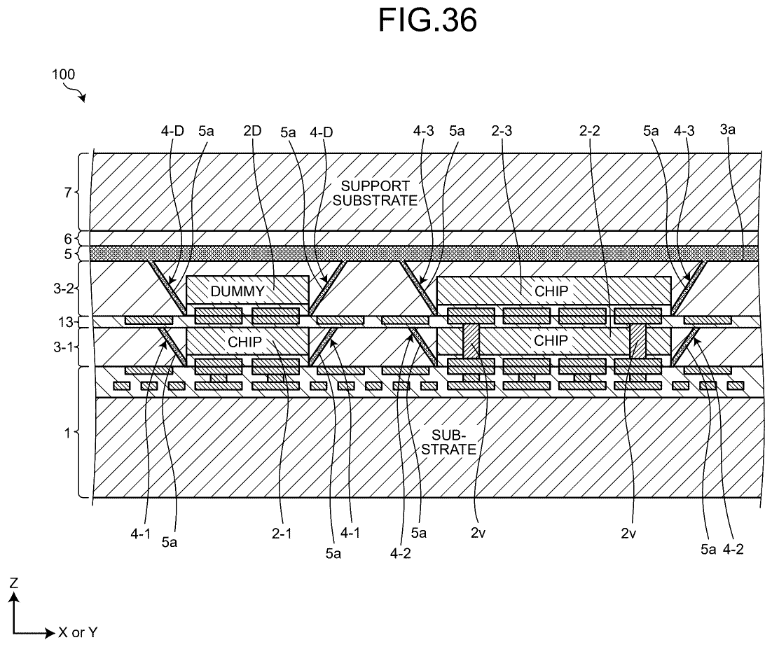

FIGS. 35 and 36 are diagrams illustrating an example of a schematic configuration of a light detection device according to a tenth embodiment. The layer structure of the light detection device 100 described above is multi-layered. The chip 2 includes two chips 2 located to be aligned in the height direction (Z-axis direction).

Referring to FIG. 35, a chip 2-2 and a chip 2-3 are exemplified as the two chips 2 located to be aligned in the height direction. The chip 2-2 is a lower chip located below (on the Z-axis negative direction side of) the chip 2-3. The chip 2-3 is an upper chip located above (the Z-axis positive direction side) the chip 2-2. Note that the chip 2-2 is located at the same height as the chip 2-1.

The light detection device 100 further includes a bonding layer 13. The bonding layer 13 is provided between the chip 2-2 and the chip 2-3. The bonding layer 13 is configured to include wiring lines so as to provide electrical connection between the chip 2-2 and the chip 2-3. The portion other than the wiring lines in the bonding layer 13 may be an insulating material, and in this sense, the bonding layer 13 can be rephrased as an insulating layer. The chip 2-2 and the chip 2-3 are provided on opposite sides to each other across the bonding layer 13, and are electrically connected to each other through the bonding layer 13.

The buried layer 3 includes a buried layer 3-1 and a buried layer 3-2. The buried layer 3-1 is a lower buried layer provided so as to cover the substrate 1, the side surface of the chip 2-1, and the side surface of the chip 2-2. The buried layer 3-2 is an upper buried layer provided so as to cover the bonding layer 13 and the chip 2-3.

The seam portion 4 includes a seam portion 4-1, a seam portion 4-2, and a seam portion 4-3. The seam portion 4-1 extends from the chip 2-1 toward the front surface 3a of the buried layer 3-1. The seam portion 4-2 extends from the chip 2-1 toward the front surface 3a of the buried layer 3-1. The seam portion 4-3 extends from the chip 2-3 toward the front surface 3a of the buried layer 3-2.

The seam portion 4-1 and the seam portion 4-2 are lower seam portions occurring in the buried layer 3-1 and extending to the front surface 3a of the buried layer 3-1. The seam portion 4-3 is an upper seam portion occurring in the buried layer 3-2 and extending to the front surface 3a of the buried layer 3-2.

The sealing layer 5 is provided so as to cover the buried layer 3-2 and the seam portion 4-3. The bonding layer 13 is provided so as to cover the buried layer 3-1, the seam portion 4-1, and the seam portion 4-2. The bonding layer 13 can function similarly to the sealing layer 5 onto the buried layer 3-1, the seam portion 4-1, and the seam portion 4-2.

In the example illustrated in FIG. 36, the chip 2 further includes a dummy chip 2D. The dummy chip 2D is located in the buried layer 3-2 above the chip 2-1. The dummy chip 2D creates a state as if the chip 2 having the same volume as the volume of the dummy chip 2D exists in the buried layer 3-2. The material of the dummy chip 2D may be the same as or different from the material of the chip 2. The dummy chip 2D need not have the function of the chip 2.

The chip 2-1 and the dummy chip 2D are provided on opposite sides to each other across the bonding layer 13. Note that the chip 2-1 and the dummy chip 2D may be but does not need to be electrically connected to each other. The dummy chip 2D has the same thickness as the thickness of the chip 2-3, for example.

The buried layer 3-2 is provided so as to cover the bonding layer 13, the dummy chip 2D, and the chip 2-3. The seam portion 4 further includes a seam portion 4-D extending from the dummy chip 2D toward the front surface 3a of the buried layer 3-2. The sealing layer 5 is provided so as to cover the buried layer 3-2, the seam portion 4-D, and the seam portion 4-3.

Without the dummy chip 2D, the entire portion needs to be filled with the buried layer 3, and for example, causing insufficient height of the buried layer 3 for the portion, making it difficult to planarize the buried layer 3. This problem is handled by the presence of the dummy chip 2D. That is, the presence of the dummy chip 2D makes it easier to planarize the buried layer 3-2 than a case without the dummy chip 2D.

### <Example of Manufacturing Method>

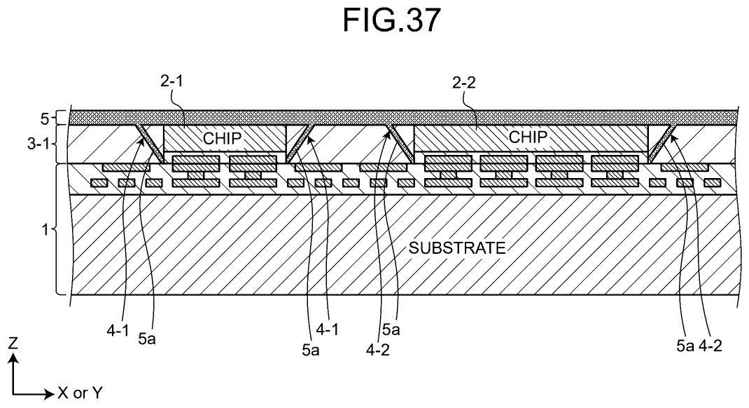

FIGS. 37 to 43 are diagrams each illustrating an example of a method of manufacturing the light detection device. As a premise, it is assumed that a manufacturing process similar to that in FIGS. 28 and 29 described above is completed. The buried layer 3-1 here corresponds to the buried layer 3 in FIGS. 28 and 29, and the thickness of the chip 2-2 here is different from the thickness of the chip 2-2 in FIGS. 28 and 29.

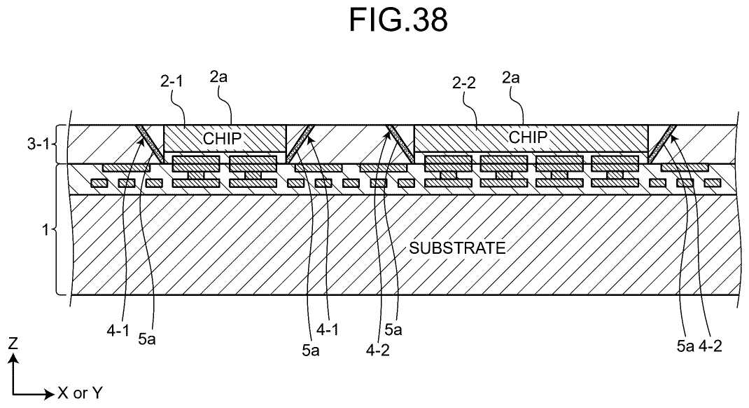

As illustrated in FIG. 37, the upper portion of the buried layer 3-1 is polished and cleaned, and then the sealing layer 5 is provided so as to cover the buried layer 3-1, the seam portion 4-1, and the seam portion 4-2. The sealing layer 5 extends into the seam portion 4-1 and the seam portion 4-2, and the extended portion is to be the extension 5a of the sealing layer 5. As illustrated in FIG. 38, the sealing layer 5 is removed by polishing. The extension 5a remains in the seam portion 4-1 and the seam portion 4-2. The chip 2-1 and the front surface 2a of the chip 2-2 are exposed. The front surface 2a is a surface on the Z-axis positive direction side of the chip 2-1 and the chip 2-2.

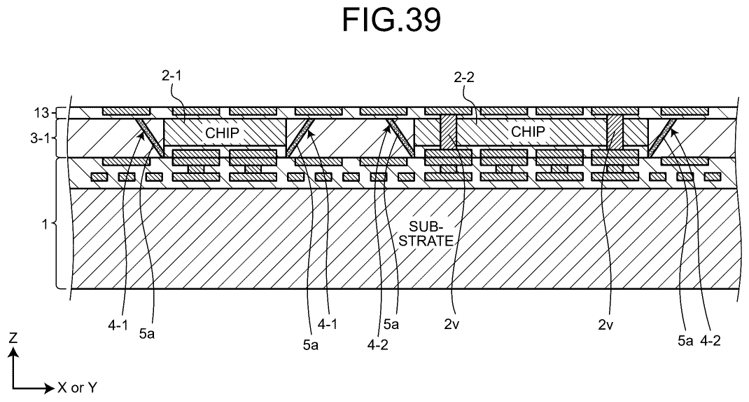

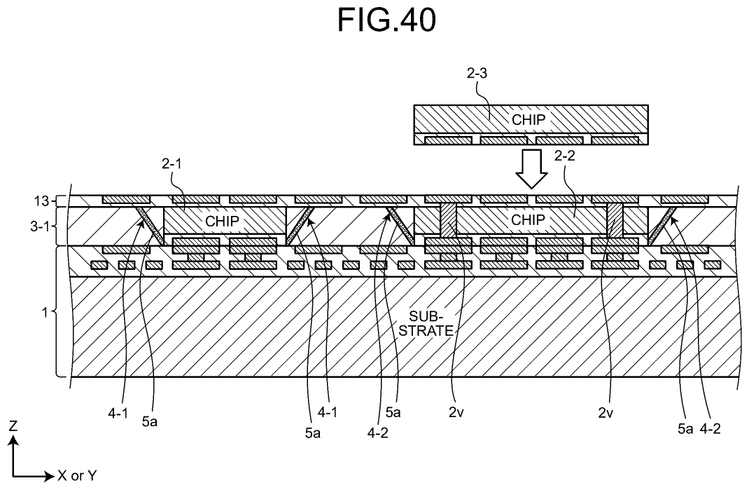

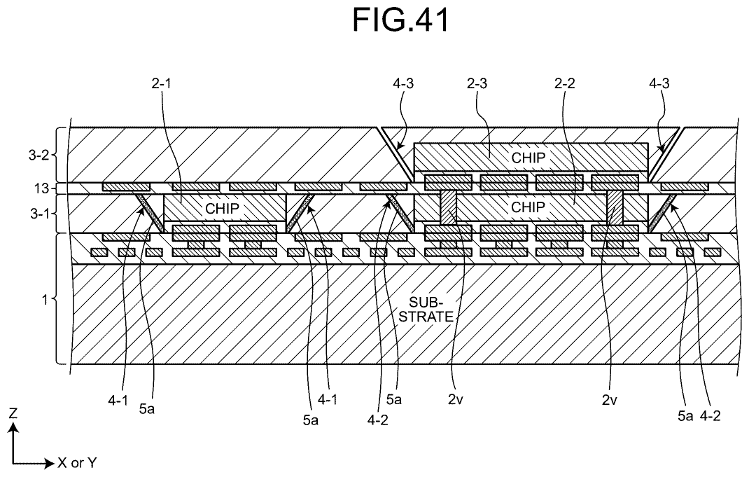

As illustrated in FIG. 39, a penetrating via 2v penetrating the chip 2-2 is provided. In addition, the bonding layer 13 is provided so as to cover the buried layer 3-1, the chip 2-1, the seam portion 4-1, the chip 2-2, and the seam portion 4-2. As illustrated in FIG. 40, the chip 2-3 is provided on the bonding layer 13 on the side opposite to the chip 2-2 across the bonding layer 13. As illustrated in FIG. 41, the buried layer 3-2 is provided so as to cover the bonding layer 13 and the chip 2-2. A seam portion 4-3 occurs. At this point, the seam portion 4-3 is an empty space.

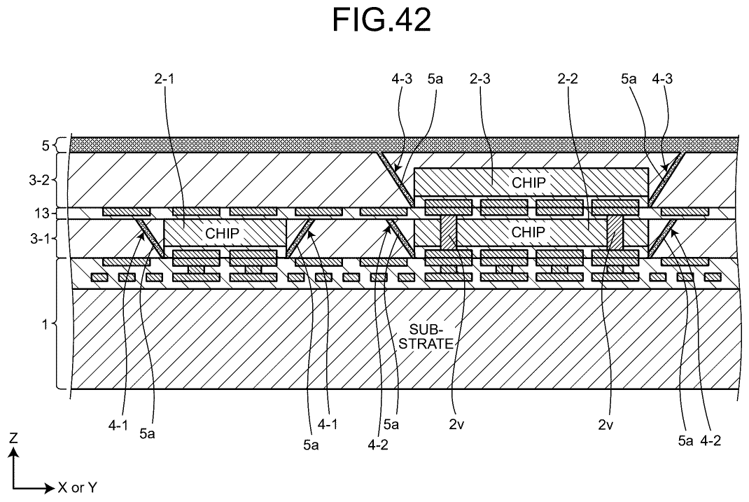

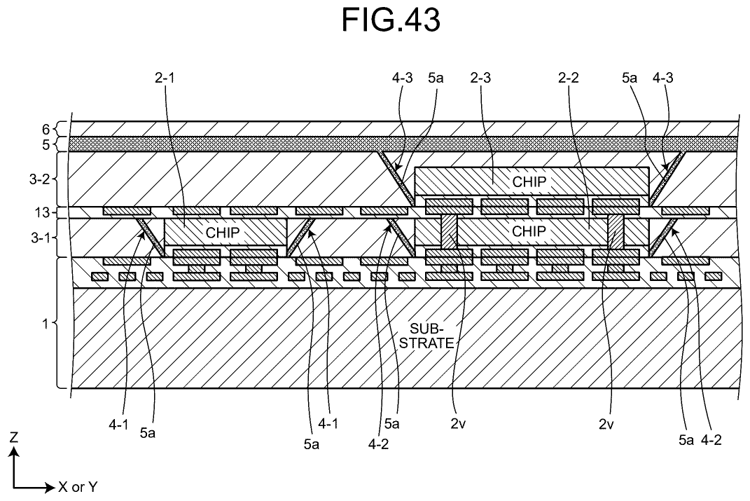

As illustrated in FIG. 42, the sealing layer 5 is provided so as to cover the buried layer 3-2, the chip 2-3, and the seam portion 4-3. The sealing layer 5 extends into the seam portion 4-3, and the expending portion is to be the extension 5a of the sealing layer 5. As illustrated in FIG. 43, the auxiliary layer 6 is provided so as to cover the sealing layer 5. Thereafter, by laminating the support substrate 7 to the auxiliary layer 6, the configuration of FIG. 35 described above is obtained.

In the above manufacturing process, the dummy chip 2D is also provided together with the chip 2-3, so as to obtain the configuration of FIG. 36 described above.

### <Modifications>

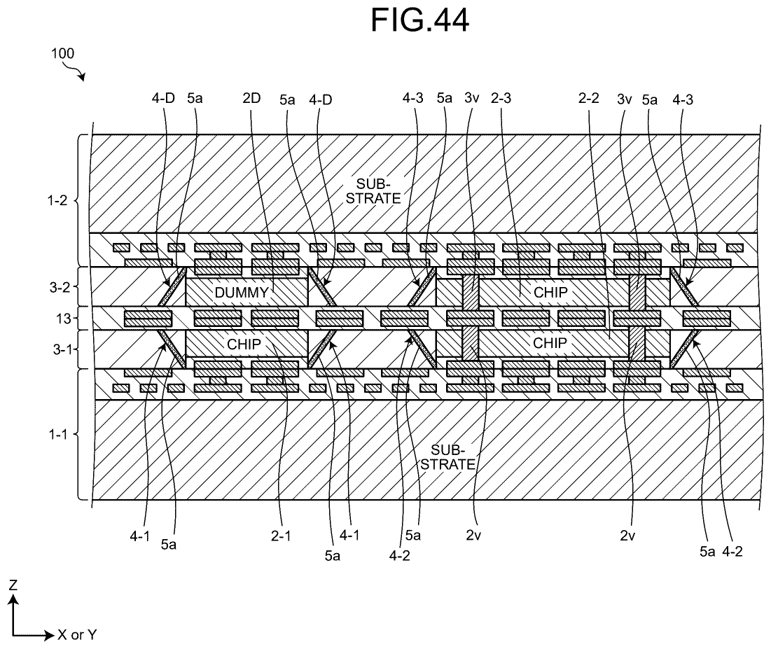

FIG. 44 is a diagram illustrating a modification. Two substrates 1 are prepared, with the chip 2 and the buried layer 3 provided on each substrate, and then these substrates are laminated to each other through the bonding layer 13. A first substrate of the two substrates 1 is referred to as a substrate 1-1 in the drawing. The second substrate is denoted as a substrate 1-2 in the drawing.

The manufacturing process similar to the process up to the manufacturing process of FIG. 39 described above is applied on the substrate 1-1. The substrate 1-1 is provided with the chip 2-1 and the chip 2-2, and then provided with the penetrating via 2v. The buried layer 3-1 is provided so as to cover the substrate 1-1, the chip 2-1, and the chip 2-2. A seam portion 4-1 and a seam portion 4-2 occur in the buried layer 3-1. The sealing layer 5 is provided so as to cover the buried layer 3-1, the seam portion 4-1, and the seam portion 4-2. The sealing layer 5 extends into the seam portion 4-1 and the seam portion 4-2, and the extended portion is to be the extension 5a of the sealing layer 5. The sealing layer 5 is removed by polishing. The extension 5a remains in the seam portion 4-1 and the seam portion 4-2. The bonding layer 13 is provided so as to cover the buried layer 3-1, the seam portion 4-1, and the seam portion 4-2.

The substrate 1-2 is provided with the chip 2-3 and the dummy chip 2D and then provided with a penetrating via 3v penetrating the chip 2-3. The buried layer 3-2 is provided so as to cover the substrate 1-2, the chip 2-2, and the dummy chip 2D. A seam portion 4-3 and a seam portion 4-D occur in the buried layer 3-2. The sealing layer 5 is provided so as to cover the buried layer 3-2, the seam portion 4-3, and the seam portion 4-D. The sealing layer 5 extends into the seam portion 4-3 and the seam portion 4-D, and the extended portion is to be the extension 5a of the sealing layer 5. The sealing layer 5 is removed by polishing. The extension 5a remains in the seam portion 4-3 and the seam portion 4-D.

By laminating the buried layer 3-2 on the substrate 1-2 side obtained as described above to the bonding layer 13 on the substrate 1-1 side, the configuration of FIG. 44 is obtained. This lamination may be performed by laminating a wafer (for example, a semiconductor wafer) including the substrate 1-1 and a wafer including the substrate 1-2. The inside of the seam portion 4 is filled with the extension 5a, and the opening of the seam portion is covered with the bonding layer 13. The bonding layer 13 is considered to function as the sealing layer 5 covering the seam portion 4.

### <Section Summary>

The light detection devices 100 according to the ninth embodiment and the tenth embodiment described above are specified as follows, for example. As described with reference to FIGS. 26 and 33 and the like, the chip 2 may include the chip 2-1 (first chip) and the chip 2-2 (second chip) having a thickness greater than the thickness of the chip 2-1; the seam portion 4 may include the seam portion 4-1 (first seam portion) extending from the chip 2-1 toward the front surface 3a of the buried layer 3 and the seam portion 4-2 (second seam portion) extending from the chip 2-2 toward the front surface 3a of the buried layer 3; and the seam portion 4-2 may extend to a position closer to the front surface 3a of the buried layer 3, compared with the seam portion 4-1. Alternatively, as described with reference to FIGS. 27, 34, and the like, the chip 2 may include the chip 2-1 (first chip), and the chip 2-2 (second chip) and the chip 2-3 (third chip) stacked in order; the chip 2-2 and the chip 2-3 may have a thickness greater than the thickness of the chip 2-1 as a whole; the seam portion 4 may include the seam portion 4-1 (first seam portion) extending from the chip 2-1 toward the front surface 3a of the buried layer 3 and the seam portion 4-2 (second seam portion) extending from the chip 2-2 toward the front surface 3a of the buried layer 3; and the seam portion 4-2 may extend to a position closer to the front surface 3a of the buried layer 3, compared with the seam portion 4-1. Even in a configuration including chip portions having mutually different thicknesses as described above, it is possible to suppress communication of the seam portion 4 to the outside.

As described with reference to FIGS. 26, 27, 33, 34, and the like, the sealing layer 5 may include the extension 5a extending into the seam portion 4-2 so as to fill at least a part of the seam portion 4-2. This makes it possible to obtain benefits of the extension 5a. For example, when the material of the sealing layer 5 contains a low-permeability material, it is possible to increase the effect of suppressing entry of moisture and the like into the chip 2; and when the material of the sealing layer 5 contains a low Young's modulus material, it is possible to alleviate the stress between the chips.

As described with reference to FIGS. 26, 27, and the like, the seam portion 4-1 may be in a state not reaching the front surface 3a of the buried layer 3, and the seam portion 4-2 may be in a state reaching the front surface 3a of the buried layer 3. As described above, even when the seam portion 4-2 reaching the front surface 3a of the buried layer 3 and the seam portion 4-1 not reaching the front surface 3a are mixed, it is possible to suppress communication of the seam portion 4 to the outside.

As described with reference to FIGS. 35 and 36 and the like, the chip 2 may include the chip 2-2 (lower chip) and the chip 2-3 (upper chip) located to be aligned in the height direction; the light detection device 100 may further include the bonding layer 13 provided between the chip 2-2 and the chip 2-3; the buried layer 3 may include the buried layer 3-1 (lower buried layer) provided to cover the side surface of the chip 2-2 and the buried layer 3-2 (upper buried layer) provided to cover the chip 2-3 and the bonding layer 13; the seam portion 4 may include the seam portion 4-2 (lower seam portion) occurring in the buried layer 3-1 and extending to the front surface 3a of the buried layer 3-1 and the seam portion 4-3 (upper seam portion) occurring in the buried layer 3-2 and extending to the front surface 3a of the buried layer 3-2; and the bonding layer 13 may be provided so as to cover the buried layer 3-1 and the Seam portion 4-2; and the sealing layer 5 may be provided so as to cover the buried layer 3-2 and the seam portion 4-3. Even with such a configuration, communication of the seam portion 4 to the outside can be suppressed.

As described with reference to FIG. 36 and the like, the chip 2 may further include the chip 2-1 (lower chip) and the dummy chip 2D provided on opposite sides to each other across the bonding layer 13, and the buried layer 3-2 may be provided so as to cover the chip 2-3, the dummy chip 2D, and the bonding layer 13. This configuration makes it easier to planarize the buried layer 3-2 than a case without the dummy chip 2D.

### 15. Eleventh Embodiment

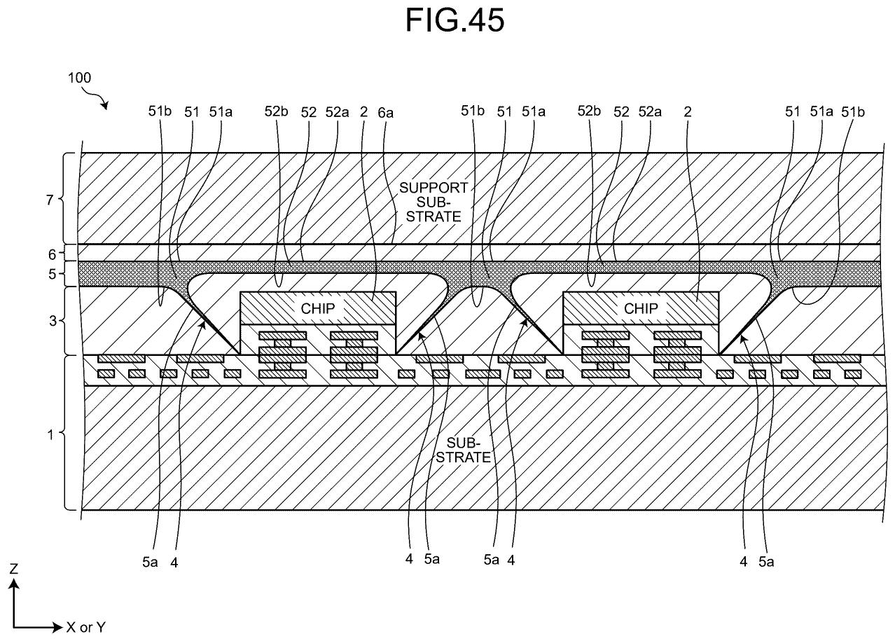

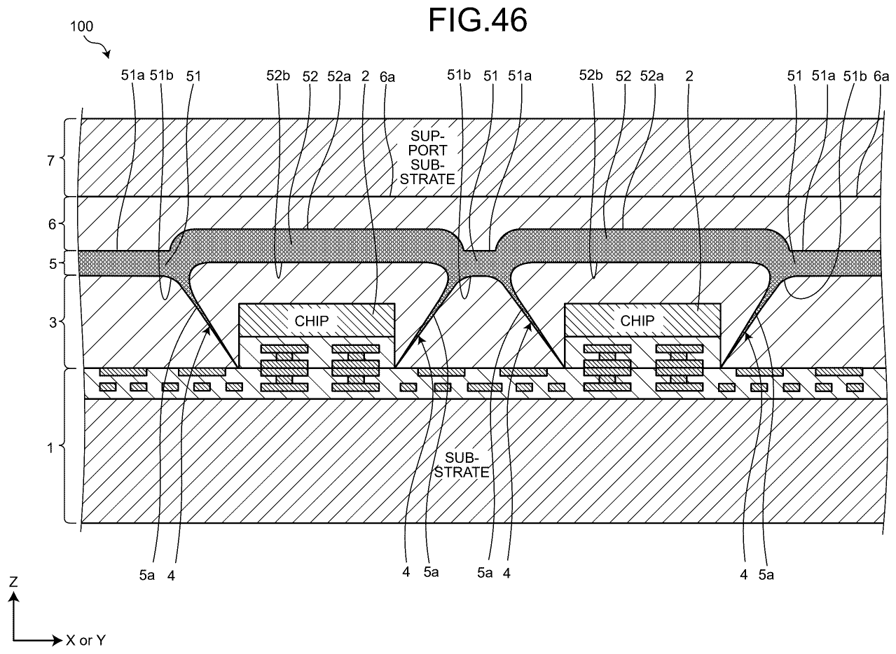

FIGS. 45 and 46 are diagrams illustrating an example of a schematic configuration of a light detection device according to an eleventh embodiment. The sealing layer 5 includes a first portion 51 and a second portion 52.

The first portion 51 is a portion of the sealing layer 5 and covers the seam portion 4. At least a part of the first portion 51 is located between the adjacent chips 2. The second portion 52 is a portion of the sealing layer 5 and does not cover the seam portion 4. At least a part of the second portion 52 is located above the corresponding chip 2. The second portion 52 may be a portion other than the first portion 51 in the sealing layer 5.

A surface of the first portion 51 on the Z-axis positive direction side is denoted as a front surface 51a in the drawing. The surface on the Z-axis negative direction side is denoted as a back surface 51b in the drawing. A surface of second portion 52 on the Z-axis positive direction side is denoted as front surface 52a in the drawing. The surface on the Z-axis negative direction side is denoted as a back surface 52b in the drawing. The back surface 51b of the first portion 51 is located below (on the Z-axis negative direction side) the back surface 52b of the second portion 52.

In the example illustrated in FIG. 45, the front surface 51a of the first portion 51 is located at the same height as the front surface 52a of the second portion 52. The entire surface of the sealing layer 5 is a planarized surface.

In the example illustrated in FIG. 46, the front surface 51a of the first portion 51 and the front surface 52a of the second portion 52 are located at mutually different heights. In this example, the front surface 52a of the second portion 52 is located above (in the Z-axis positive direction side) the front surface 51a of the first portion 51. The entire surface of the sealing layer 5 is a non-planarized surface. However, the auxiliary layer 6 (for example, SiO2) provided on the sealing layer 5 has a front surface 6a being a planarized surface, ensuring the planarization. Planarizing of the sealing layer 5 by polishing or the like is difficult depending on the material of the sealing layer 5. In this case, performing planarization using the auxiliary layer 6 that can be more easily planarized, instead of the sealing layer 5, will facilitate the manufacturing process. The auxiliary layer 6 can also be referred to as a planarization facilitation layer.

According to the configuration of FIGS. 45 and 46, the thickness of the sealing layer 5 on the seam portion 4 can be increased as compared with the configuration described above. Accordingly, it is possible to enhance the functionality of the sealing layer 5 to suppress communication of the seam portion 4 to the outside. In addition, there is no need to planarize the buried layer 3, for example, making it possible to prevent the chemical solution from entering the seam portion 4 which can occur at the time of polishing or cleaning the buried layer 3.

### <Example of Manufacturing Method>

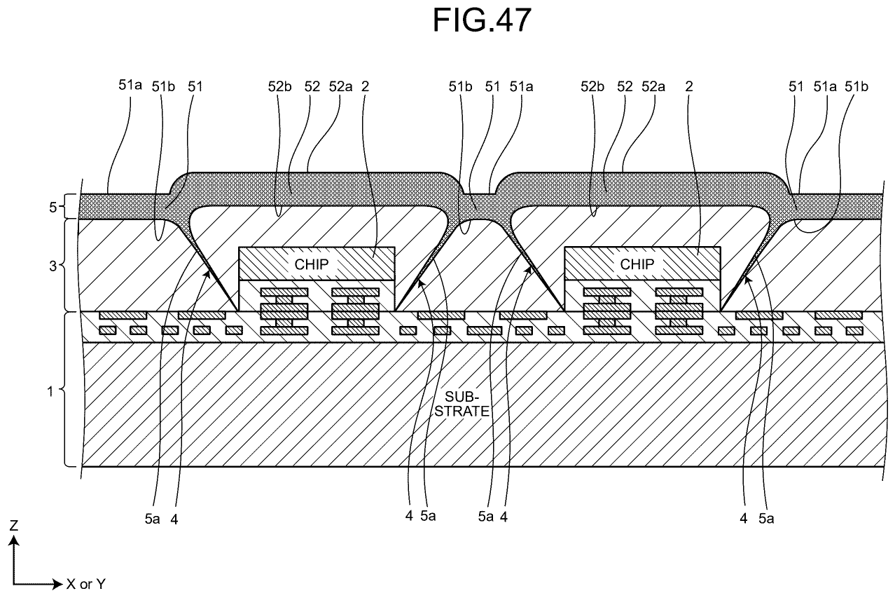

FIGS. 47 to 51 are diagrams illustrating an example of a method of manufacturing the light detection device. FIGS. 47 to 49 illustrate examples of a manufacturing method for obtaining the configuration of FIG. 45 described above. As a premise, it is assumed that a manufacturing process similar to that in FIGS. 9 and 10 described above is completed.

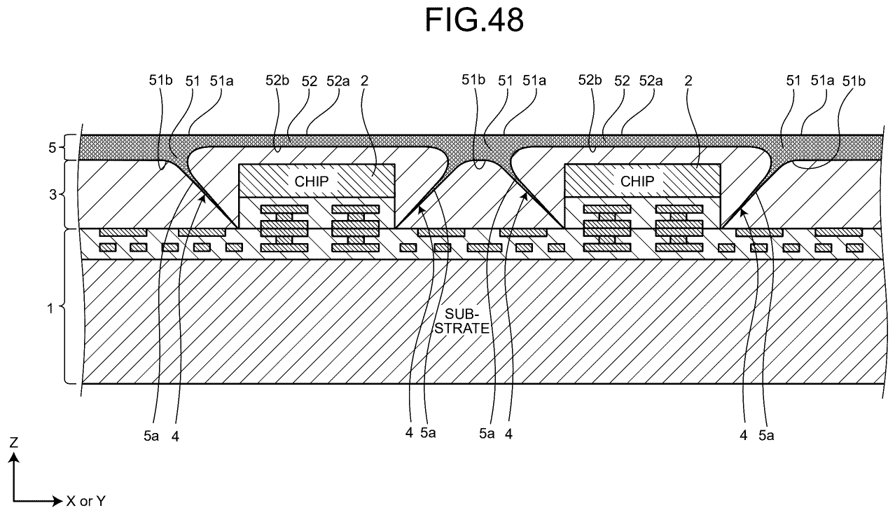

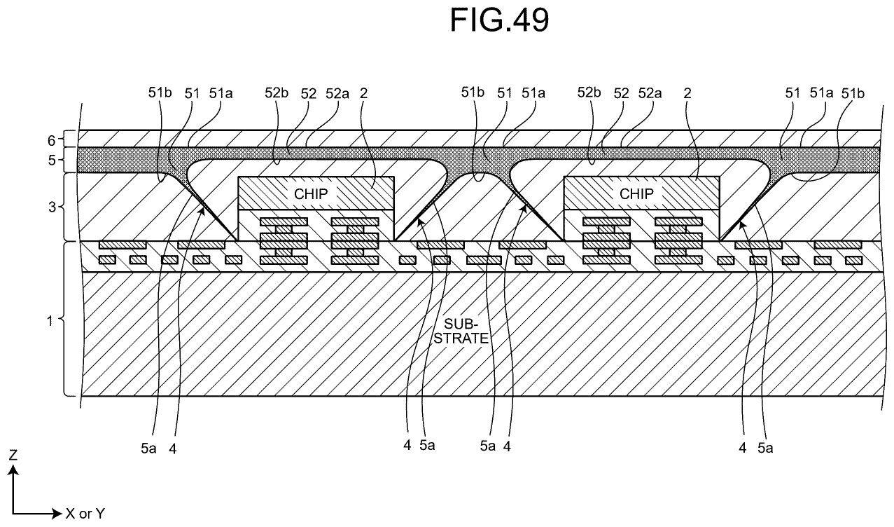

As illustrated in FIG. 47, the sealing layer 5 is provided on the buried layer 3 without polishing the buried layer 3. The sealing layer 5 extends into the seam portion 4, and the expending portion is to be the extension 5a of the sealing layer 5. As illustrated in FIG. 48, by polishing and cleaning the top of the sealing layer 5 so as to obtain the sealing layer 5 including the first portion 51 and the second portion 52 as in FIG. 45 described above. the front surface 51a of the first portion 51 and the front surface 52a of the second portion 52 are both located at the same height, making the front surface of the entire sealing layer 5 a planarized surface. As illustrated in FIG. 49, the auxiliary layer 6 is provided so as to cover the sealing layer 5. Thereafter, by laminating the support substrate 7 to the auxiliary layer 6, the configuration of FIG. 45 described above is obtained.

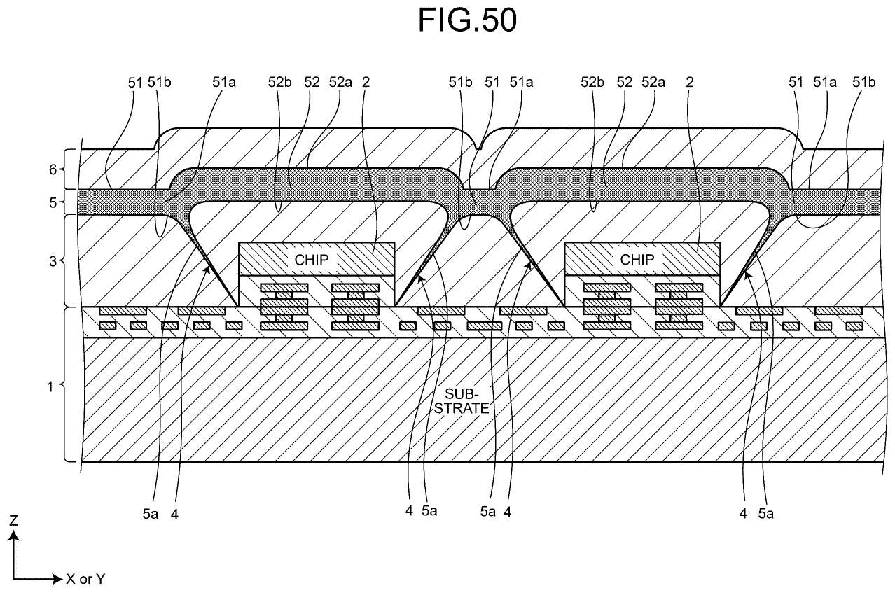

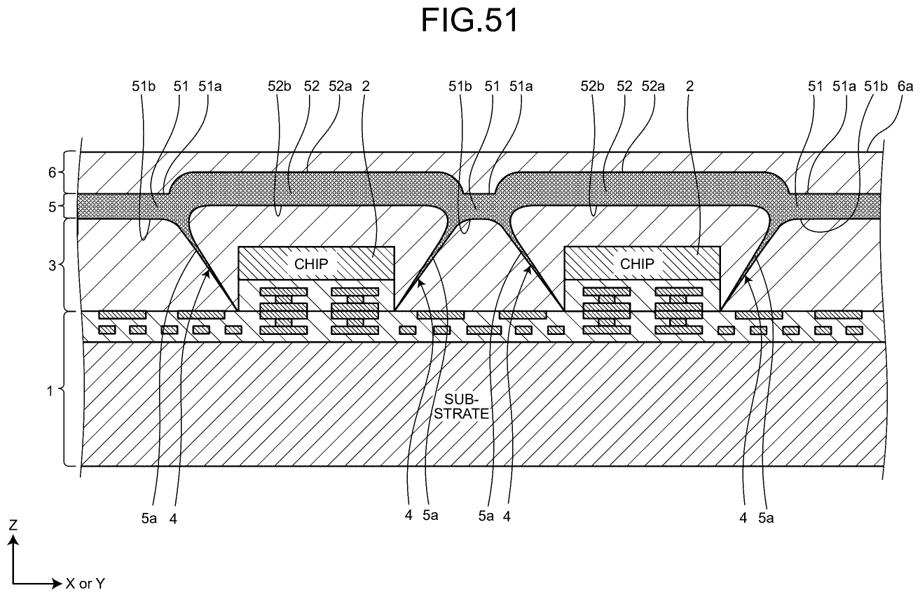

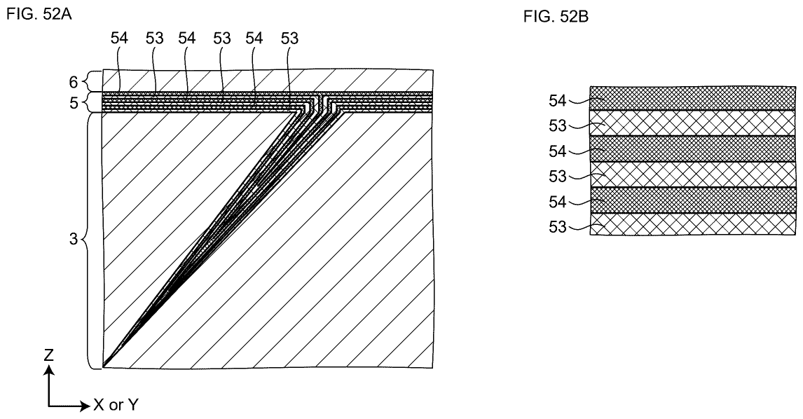

FIGS. 50 and 51 illustrate an example of a manufacturing method for obtaining the configuration of FIG. 46 described above. As a premise, it is assumed that the manufacturing process of FIG. 47 described above is completed.

As illustrated in FIG. 50, the sealing layer 5 including the first portion 51 and the second portion 52 similar to those in FIG. 49 described above is obtained, and the auxiliary layer 6 is provided so as to cover the sealing layer 5 without polishing the sealing layer 5. As illustrated in FIG. 51, the top of the auxiliary layer 6 is polished and cleaned to obtain the auxiliary layer 6 having the planarized front surface 6a. Thereafter, by laminating the support substrate 7 to the auxiliary layer 6, the configuration of FIG. 46 described above is obtained.

### 16. Twelfth Embodiment

In one embodiment, the sealing layer 5 may have a stacked structure. This will be described with reference to FIG. 52.

FIG. 52 is a diagram illustrating an example of a schematic configuration of the sealing layer. (A) of FIG. 52 schematically illustrates a cross section of the sealing layer 5 and its periphery. (B) of FIG. 52 schematically illustrates a cross section obtained by enlarging a part of the sealing layer 5.

The sealing layer 5 has a stacked structure including a stack of a plurality of layers. The plurality of layers may include, for example, two types of layers. One type of layer of the two types of layers may be an inorganic layer, and the other type of layer may be an organic layer. The inorganic layer is denoted as an inorganic layer 53 in the drawing. The organic layer is denoted as an organic layer 54 in the drawing.

The material of the inorganic layer 53 may be various known inorganic materials. Examples of the inorganic material include Al₂O₃, SiN, SiON, and SiCN.

The material of the organic layer 54 may be various known organic materials. Examples of materials include polymers and hybrid polymers. Examples of the polymer include PEN, PET, and PEG. The hybrid polymer is a material containing a polymer and a metal material, for example. An example of a hybrid polymer when the metal material is aluminum is Alcone. The organic layer 54 may be formed using a method such as spin coating, an inkjet method, and an MLD method, for example. The MLD method can be suitably used for forming the sealing layer 5 including the extension 5a extending to the inside of the seam portion 4.

In the example illustrated in FIG. 52, the sealing layer 5 has a six-layer structure including three inorganic layers 53 and three organic layers 54. The inorganic layers 53 and the organic layers 54 are alternately stacked. However, the number of the inorganic layers 53 and the number of the organic layers 54 may be smaller or larger than the number illustrated in FIG. 52.

The stacked structure of the sealing layer 5 can enhance the functionality of the sealing layer 5. For example, it is possible to improve a gas (water vapor or the like) barrier property or improve robustness against deformation.

### <Section Summary>

The light detection devices 100 according to the eleventh embodiment and the twelfth embodiment described above are specified as follows, for example. As described with reference to FIGS. 45, 46, and the like, the sealing layer 5 may include the first portion 51 that covers the seam portion 4 and the second portion 52 that does not cover the seam portion 4, and the back surface 51b of the first portion 51 may be located below (on the Z-axis negative direction side) the back surface 52b of the second portion 52. As described with reference to FIG. 45 and the like, the front surface 51a of the first portion 51 may be located at the same height as the front surface 52a of the second portion 52. Alternatively, as described with reference to FIG. 46 and the like, the light detection device 100 may include the auxiliary layer 6 provided so as to cover the sealing layer 5, the front surface 52a of the second portion 52 may be located above (the Z-axis positive direction side) the front surface 51a of the first portion 51, and the front surface 6a of the auxiliary layer 6 may be a planarized surface. For example, such a configuration makes it possible to increase the thickness of the sealing layer 5 on the seam portion 4. Accordingly, it is possible to enhance the functionality of the sealing layer 5 to suppress communication of the seam portion 4 to the outside. In addition, there is no need to planarize the buried layer 3, for example, making it possible to prevent the chemical solution from entering the seam portion 4 which can occur at the time of polishing or cleaning the buried layer 3.

As described with reference to FIG. 52 and the like, the sealing layer 5 may have a stacked structure including a stack of a plurality of layers. The plurality of layers of the sealing layer 5 may include the inorganic layer 53 and the organic layer 54. This configuration can enhance the functionality of the sealing layer 5. For example, it is possible to improve a gas (water vapor or the like) barrier property or improve robustness against deformation.

### 17. Thirteenth Embodiment

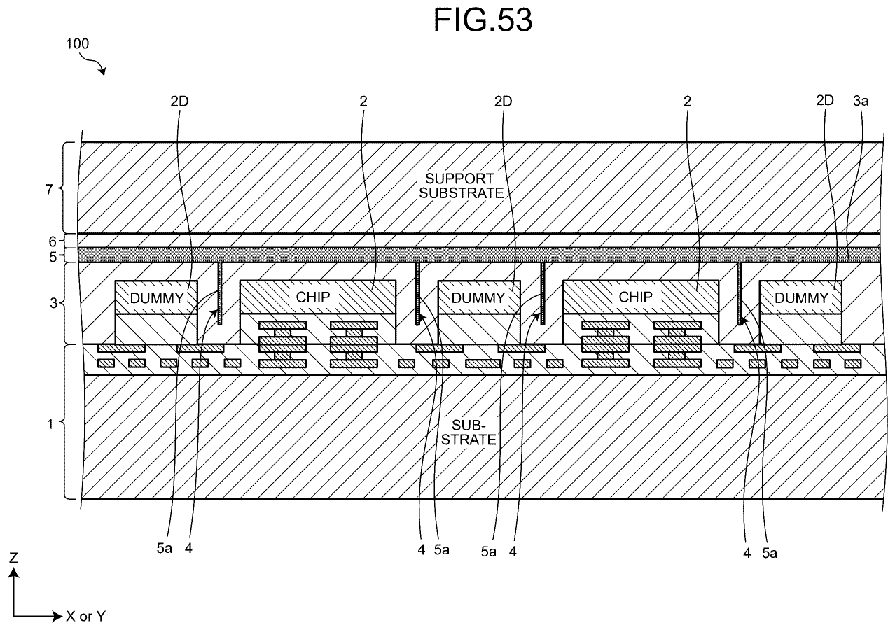

FIG. 53 is a diagram illustrating an example of a schematic configuration of a light detection device according to a thirteenth embodiment. The light detection device 100 includes a dummy chip 2D. Note that the dummy chip 2D here may be understood separately from the dummy chip 2D of the tenth embodiment (FIG. 36) described above.

The dummy chip 2D is used to narrow a peripheral interval of the chip 2. The dummy chip 2D is arranged so as to be adjacent to the chip 2 at an interval. In this example, the chip 2 includes two chips 2 provided separated from each other. The dummy chip 2D is provided between the two chips 2.

The buried layer 3 is provided so as to cover the substrate 1, the chip 2, and the dummy chip 2D. The seam portion 4 extends to the front surface 3a of the buried layer 3 in a portion between the chip 2 and the dummy chip 2D. The aspect ratio of the portion where the seam portion 4 occurs in the buried layer 3 increases in accordance with the area of the dummy chip 2D. The aspect ratio here corresponds to a ratio of the length in the Z-axis direction to the length in the XY plane direction. With an increase in the aspect ratio, the extending direction of the seam portion 4 is restricted. The extending direction of the seam portion 4 is brought close to the height direction (Z-axis positive direction) of the chip 2 and the dummy chip 2D. The aspect ratio may be designed so that such a seam portion 4 can be easily obtained. For example, the aspect ratio may be designed within a range of 1 to 3.

The seam portion 4 extends in the height direction (Z-axis positive direction) of the chip 2 and the dummy chip 2D. Extending in the height direction may include not only a case of extending in the same direction as the height direction but also a case of extending at a certain angle with respect to the height direction. Examples of the upper limit value of such an angle include less than 30 degrees, less than 25 degrees, less than 20 degrees, less than 15 degrees, less than 10 degrees, and less than 5 degrees. The lower limit value of the angle may be 0 degrees. Note that, hereinafter, extending along the height direction of the chip 2 and the dummy chip 2D is also referred to as extending in the vertical direction.

Since the seam portion 4 extends in the vertical direction, the sealing layer 5 easily extends into the seam portion 4 when the sealing layer 5 is provided so as to cover the buried layer 3 and the seam portion 4. It is highly likely to obtain the benefits of the extension 5a of the sealing layer 5 as described above.

### <Example of Manufacturing Method>

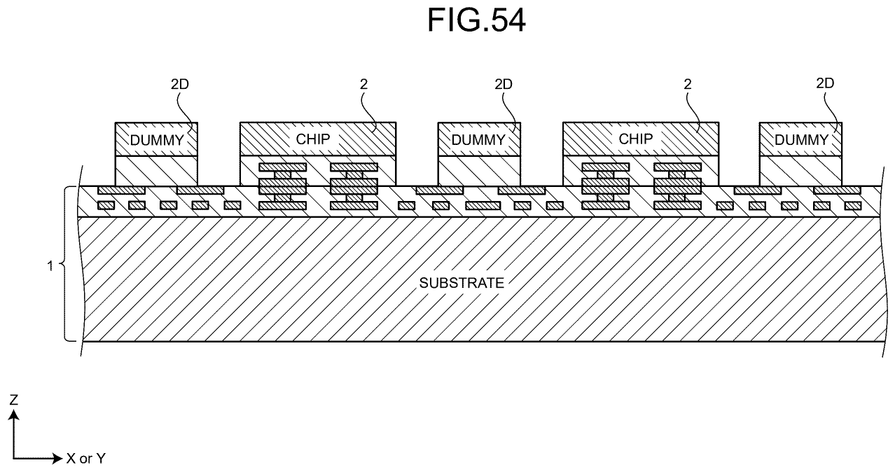

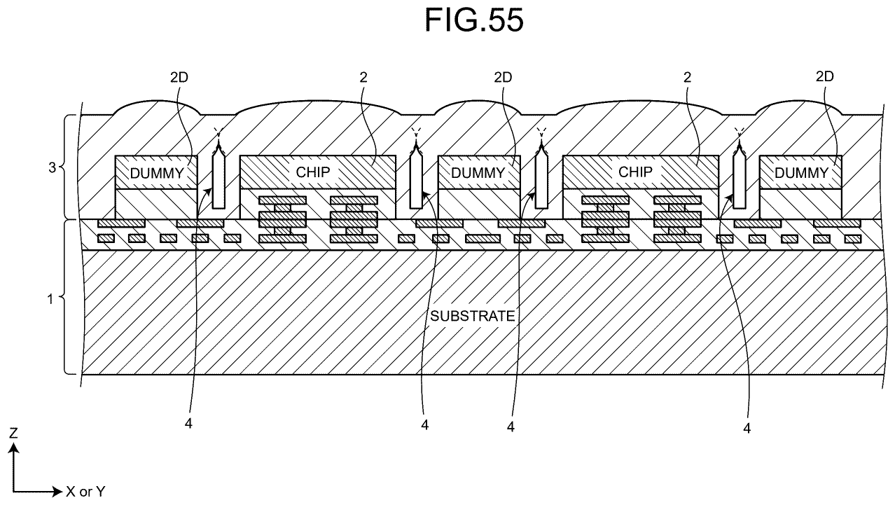

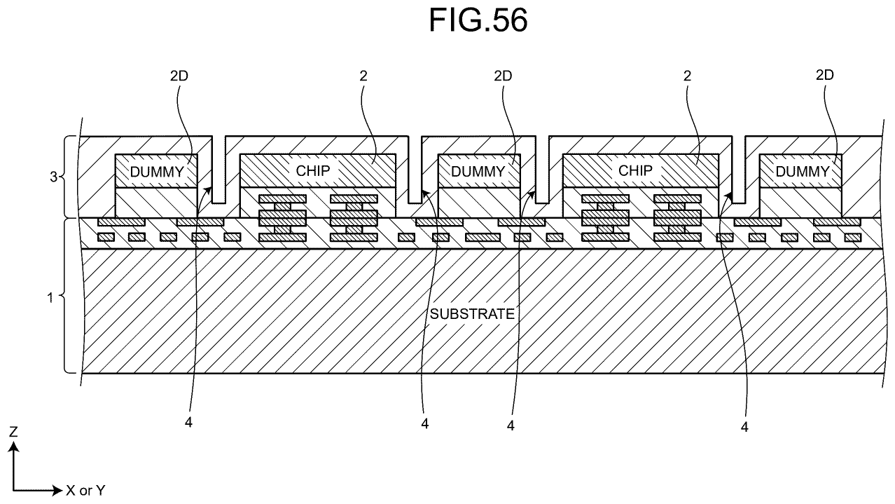

FIGS. 54 to 58 are diagrams illustrating an example of a method of manufacturing the light detection device. As illustrated in FIG. 54, the chip 2 and the dummy chip 2D are provided on the substrate 1. As illustrated in FIG. 55, the buried layer 3 is provided (deposited, for example) so as to cover the substrate 1, the chip 2, and the dummy chip 2D. The seam portion 4 occurs due to the overhang during deposition. That is, the top of the chip 2 is deposited earlier than the deposition rate of the bottom in the portion between the chip 2 and the dummy chip 2D. The overhang blocks the material of the buried layer 3 in the middle of deposition, causing occurrence of the seam portion 4 between the chip 2 and the dummy chip 2D interrupting the deposition in the middle. However, since the peripheral interval of the chip 2 is narrowed by the area of the dummy chip 2D, the extending direction of the seam portion 4 is brought close to the height direction (Z-axis positive direction) of the chip 2 and the dummy chip 2D. At this point, the seam portion 4 is an empty space.

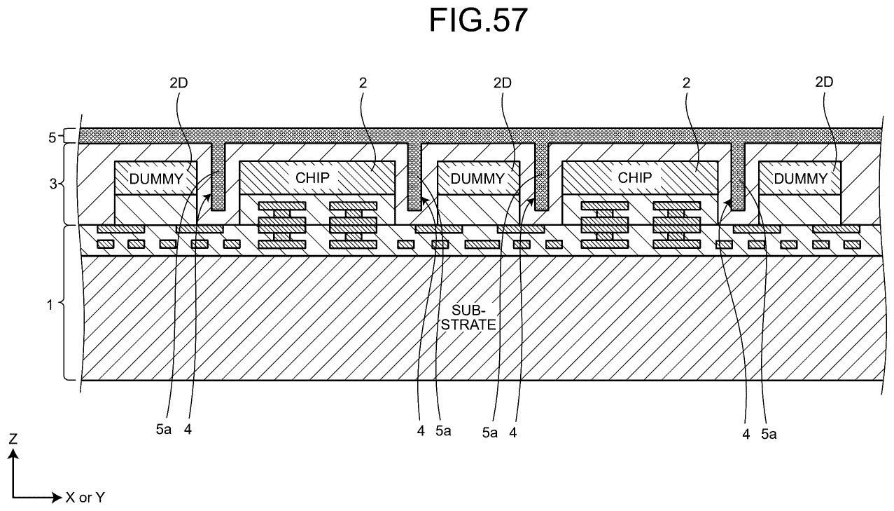

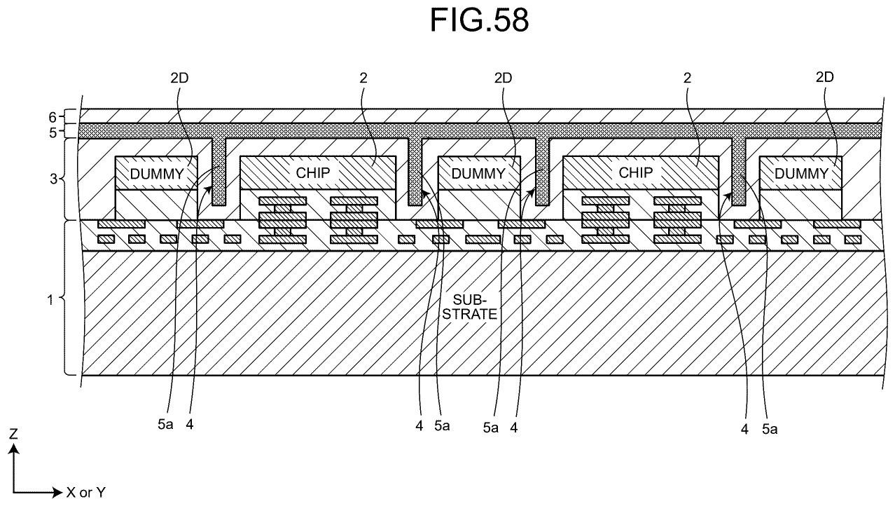

As illustrated in FIG. 56, the top of the buried layer 3 is polished and cleaned. The top of the seam portion 4 is opened. As illustrated in FIG. 57, the sealing layer 5 is provided so as to cover the buried layer 3 and the seam portion 4. Since the seam portion 4 extends in the vertical direction, the sealing layer 5 easily extends into the seam portion 4, and the extended portion is to be the extension 5a of the sealing layer 5. As illustrated in FIG. 58, the auxiliary layer 6 is provided so as to cover the sealing layer 5. Thereafter, by laminating the support substrate 7 to the auxiliary layer 6, the configuration of FIG. 53 described above is obtained.

### 18. Fourteenth Embodiment

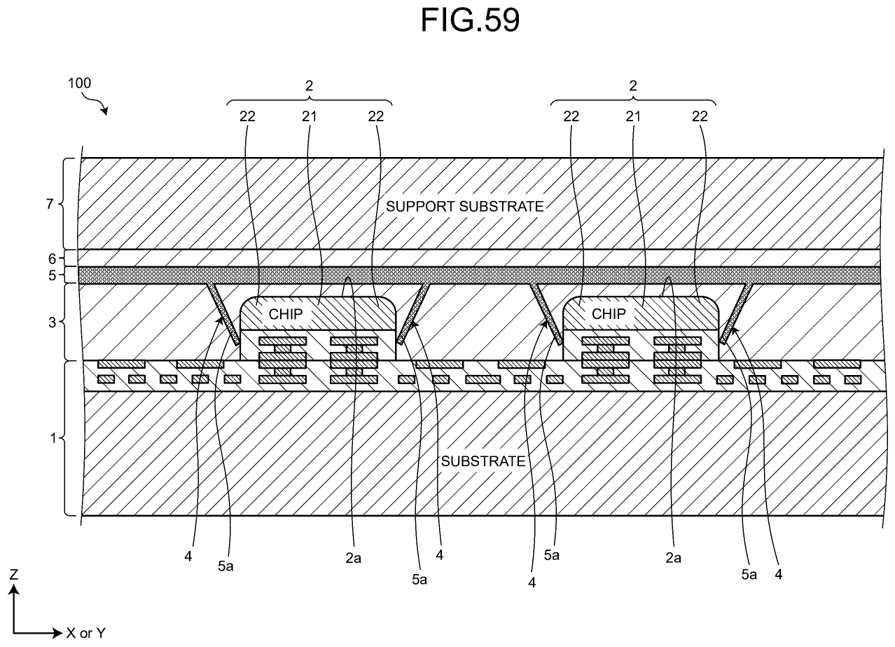

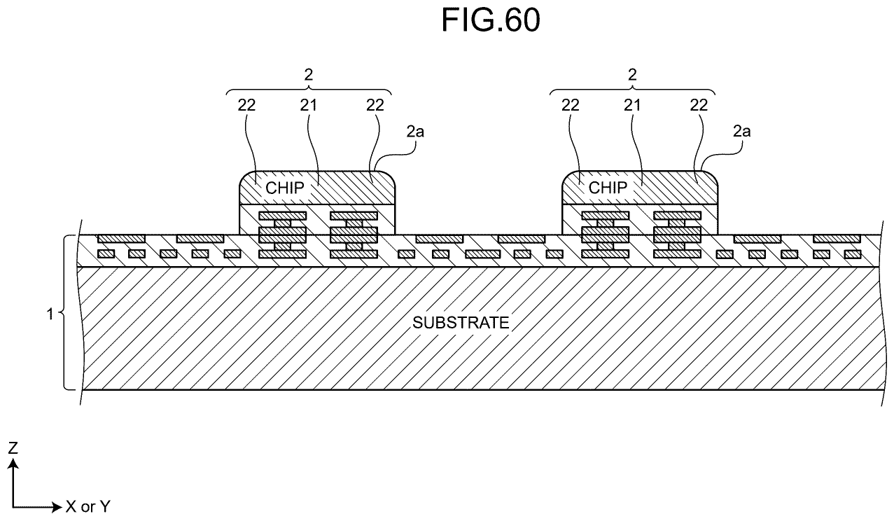

FIG. 59 is a diagram illustrating an example of a schematic configuration of a light detection device according to a fourteenth embodiment. The chip 2 has a shape in which the width (length in the XY plane direction) decreases toward the front surface 2a.

A portion located at the center of the chip 2 in the XY plane direction is denoted as a central portion 21 in the drawing. In the chip 2, a portion located outside the central portion 21 and including an edge of the chip 2 is denoted as an edge portion 22 in the drawing. The edge portion 22 of the chip 2 has a round shape on the front surface 2a of the chip 2. The edge portion 22 may have a shape other than the round shape. Another example of the shape is a tapered shape.

The buried layer 3 is provided so as to cover the chip 2. The seam portion 4 extends from the chip 2 to the front surface 3a of the buried layer 3. Since the width on the front surface 2a side of the chip 2 is narrowed, the seam portion 4 extends in the height direction of the chip 2, that is, extends in the vertical direction. This is because of improved buried nature of the buried layer 3 in the bottom around the chip 2, more specifically, in the portion between the adjacent chips 2 in this example. The benefits of extending the seam portion 4 in the vertical direction are as described above.

### <Example of Manufacturing Method>

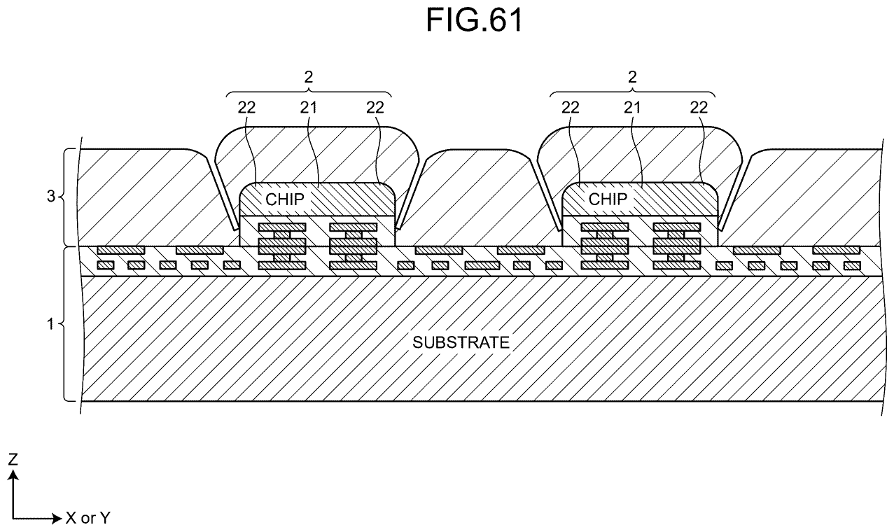

FIGS. 60 to 64 are diagrams illustrating an example of a method of manufacturing the light detection device. As illustrated in FIG. 60, a chip 2 having a narrow front surface 2a side width is provided on the substrate 1. For example, the chip 2 is processed such that the angle of the corner of the edge portion 22 of the chip 2 is less than 90 degrees. An example of the processing is chamfering of the front surface 2a of the chip 2. Examples of the chamfering include C chamfering and R chamfering by plasma etching or the like. As illustrated in FIG. 61, the buried layer 3 is provided so as to cover the substrate 1 and the chip 2. As the degree of processing on the chips 2 as described above, the buried nature of the buried layer 3 in the bottom portion in the portion between the chips 2 is improved. The extending direction of the seam portion 4 that has occurred is brought close to the height direction (Z-axis positive direction) of the chip 2. At this point, the seam portion 4 is an empty space.

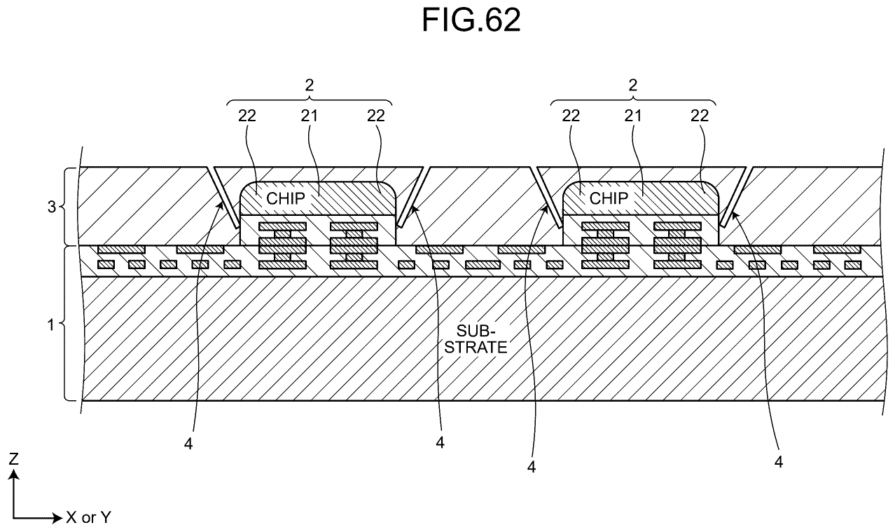

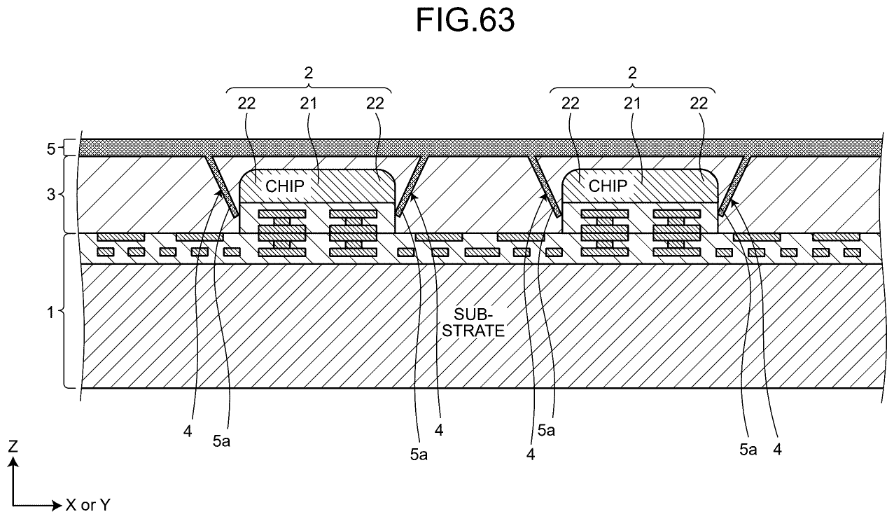

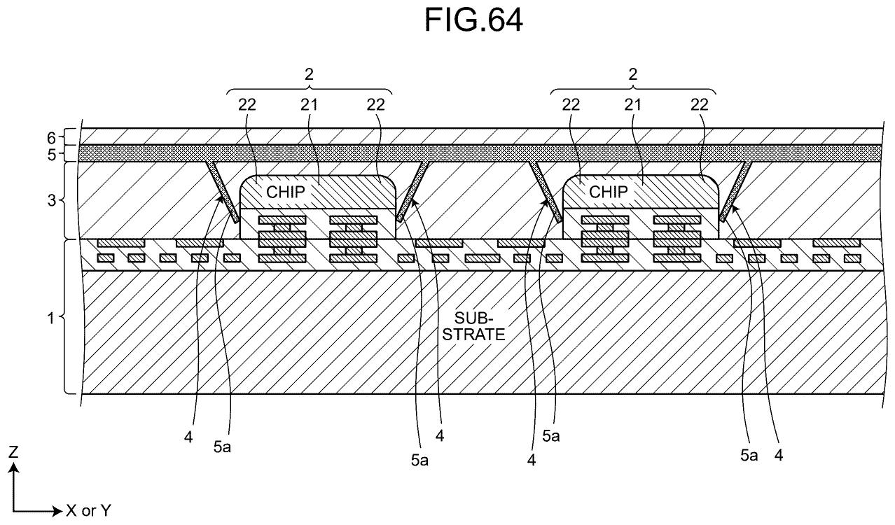

As illustrated in FIG. 62, the top of the buried layer 3 is polished and cleaned. The top of the seam portion 4 is opened. As illustrated in FIG. 63, the sealing layer 5 is provided so as to cover the buried layer 3 and the seam portion 4. Since the seam portion 4 extends in the vertical direction, the sealing layer 5 easily extends into the seam portion 4, and the extended portion is to be the extension 5a of the sealing layer 5. As illustrated in FIG. 64, the auxiliary layer 6 is provided so as to cover the sealing layer 5. Even when the auxiliary layer 6 is polished and cleaned, the seam portion 4 is covered with the sealing layer 5, preventing spread of the seam portion 4. Thereafter, the support substrate 7 is laminated to the auxiliary layer 6 to obtain the configuration of FIG. 59 described above.

### 19. Fifteenth Embodiment

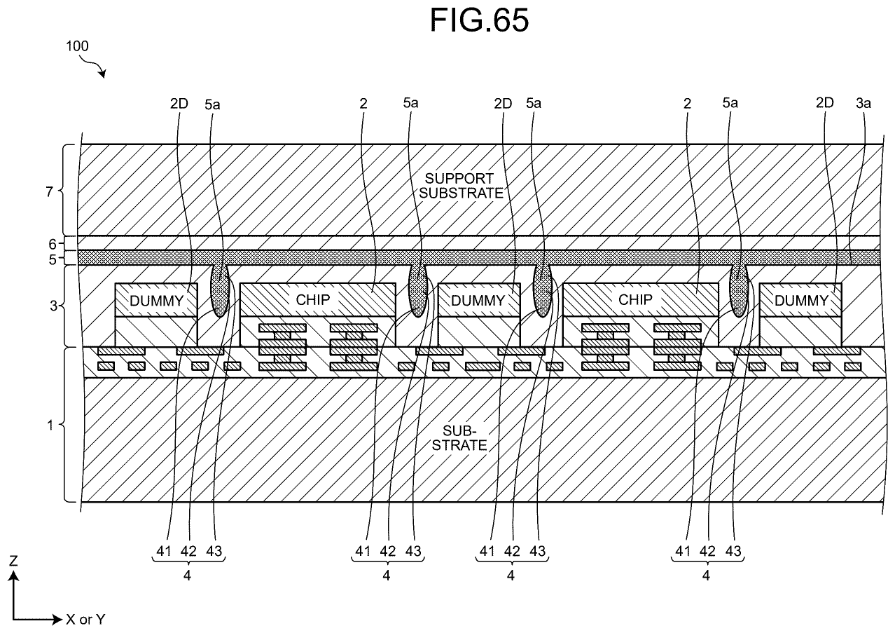

FIG. 65 is a diagram illustrating an example of a schematic configuration of a light detection device according to a fifteenth embodiment. The seam portion 4 has a shape with its width (length in the XY plane direction) changing with a growth in the extending direction. The shape of the seam portion 4 may be a shape having a local bulge.

The seam portion 4 includes an end portion 41, a central portion 42, and an end portion 43. The central portion 42 is a portion located at the center of the seam portion 4 in the extending direction of the seam portion 4. The end portion 41 and the end portion 43 are portions located at ends of the seam portion 4 in the extending direction of the seam portion 4. The end portion 41 and the end portion 43 are located on opposite sides of the central portion 42. In this example, the end portion 41, the central portion 42, and the end portion 43 are located in this order in the Z axis positive direction.

The central portion 42 has a width greater than a width of at least one of the end portion 41 and the end portion 43. In this example, the width of the central portion 42 is greater than the width of the end portion 41 and greater than the width of the end portion 43. The seam portion 4 has a shape having a central portion 42 bulging in the extending direction of the seam portion 4.

In the example illustrated in FIG. 65, the dummy chip 2D is provided on the substrate 1. However, even in a case without the dummy chip 2D, the seam portion 4 having a shape locally bulging can occur. When the dummy chip 2D is present, the extending direction of the seam portion 4 can be brought close to the height direction (Z-axis positive direction) of the chip 2 and the dummy chip 2D. In addition, a similar effect can be obtained by using the chip 2 having a narrow width on the front surface 2a side as illustrated in FIG. 59 described above instead of providing the dummy chip 2D.

### <Example of Manufacturing Method>

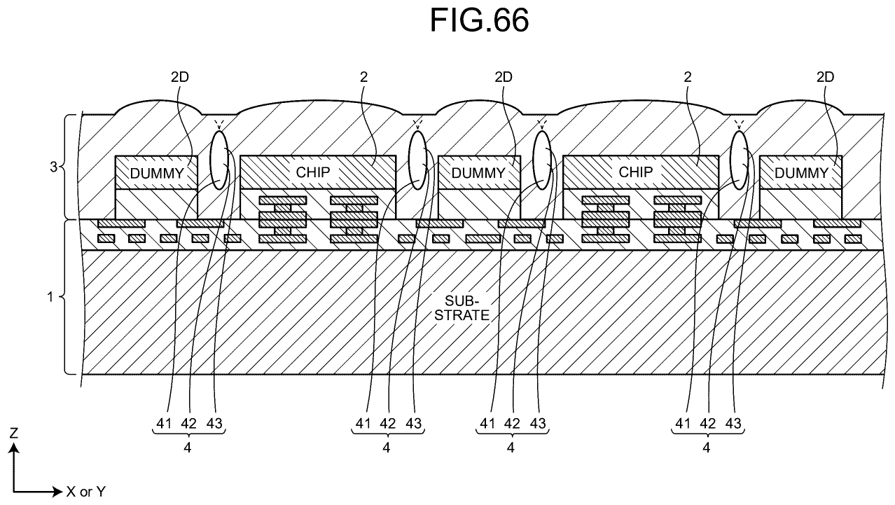

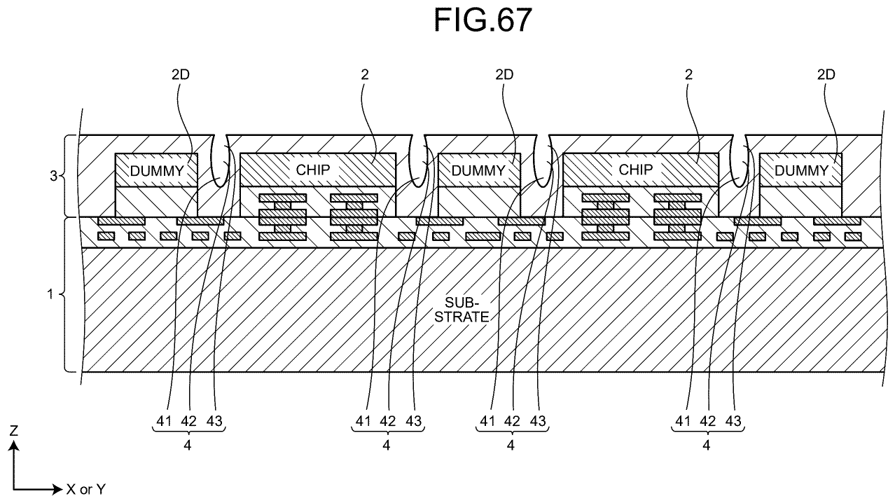

FIGS. 66 to 69 are diagrams illustrating an example of a method of manufacturing the light detection device. As a premise, it is assumed that a manufacturing process similar to that in FIG. 54 described above is completed. As illustrated in FIG. 66, the buried layer 3 is provided (deposited, for example) so as to cover the substrate 1, the chip 2, and the dummy chip 2D. The seam portion 4 occurs due to the overhang during deposition. The top of the chip 2 is deposited earlier than the deposition rate of the bottom in the portion between the chip 2 and the dummy chip 2D. The overhang blocks the material of the buried layer 3 in the middle of deposition, generating a locally empty space between the chip 2 and the dummy chip 2D interrupting the deposition in the middle. This empty space is to be the seam portion 4. Since the peripheral interval of the chip 2 is narrowed by the area of the dummy chip 2D, the extending direction of the seam portion 4 is brought close to the height direction (Z-axis positive direction) of the chip 2 and the dummy chip 2D.

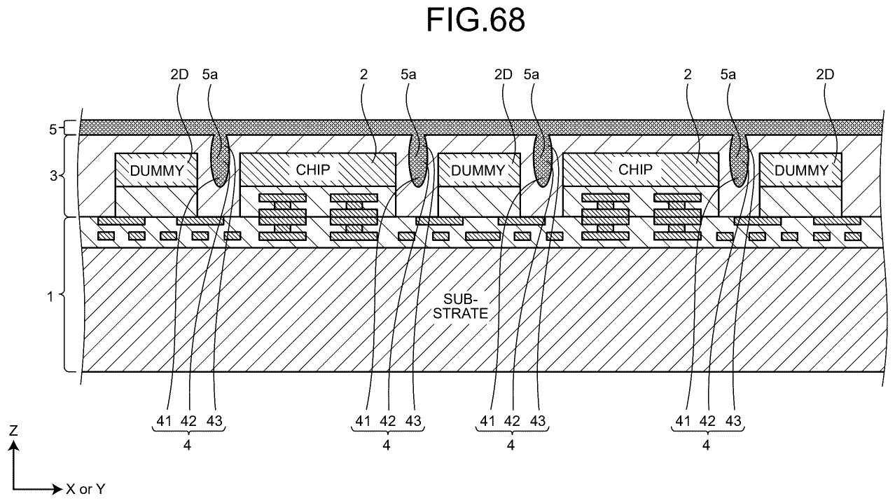

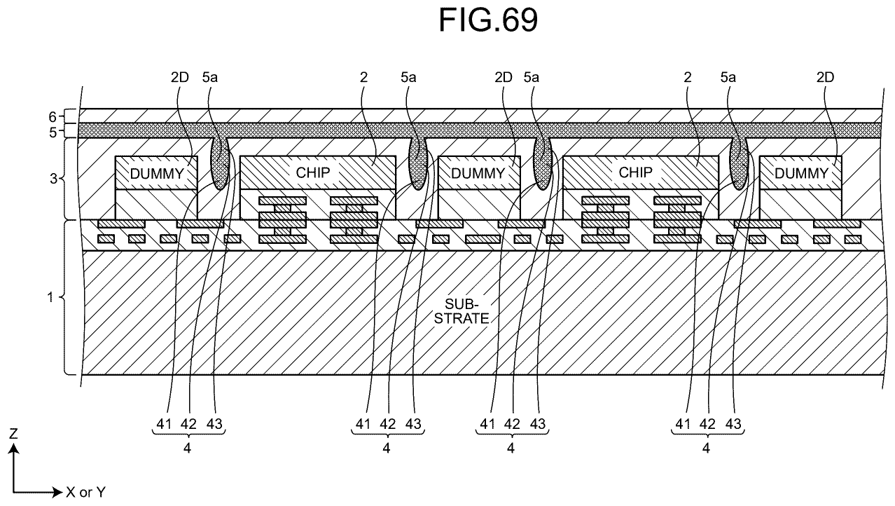

As illustrated in FIG. 67, the top of the buried layer 3 is polished and cleaned. The top of the seam portion 4 is opened. As illustrated in FIG. 68, the sealing layer 5 is provided so as to cover the buried layer 3 and the seam portion 4. Since the seam portion 4 extends in the vertical direction, the sealing layer 5 easily extends into the seam portion 4, and the extended portion is to be the extension 5a of the sealing layer 5. As illustrated in FIG. 69, the auxiliary layer 6 is provided so as to cover the sealing layer 5. Thereafter, the support substrate 7 is laminated to the auxiliary layer 6 to obtain the configuration of FIG. 65 described above.

### <Section Summary>

The light detection devices 100 according to the above-described thirteenth to fifteenth embodiments are specified as follows, for example. As described with reference to FIG. 53 and the like, the light detection device 100 may include the dummy chip 2D disposed adjacent to the chip 2 at an interval, the buried layer 3 may be provided so as to cover the chip 2 and the dummy chip 2D, and the seam portion 4 may extend to the front surface 3a of the buried layer 3 in a portion between the chip 2 and the dummy chip 2D. The seam portion 4 may extend in the height direction (Z-axis positive direction) of the chip 2 and the dummy chip 2D. The chip 2 may include two chips 2 provided separated from each other, and the dummy chip 2D may be provided between the two chips 2. With this configuration, the sealing layer 5 easily extends into the seam portion 4 when the sealing layer 5 is provided so as to cover the buried layer 3 and the seam portion 4. It is highly likely to obtain the benefits of the extension 5a of the sealing layer 5.

As described with reference to FIG. 59 and the like, the chip 2 may have a shape having its width decreasing toward the front surface 2a of the chip 2 (toward the Z-axis positive direction). The edge portion 22 of the chip 2 may have a tapered shape or a round shape on the front surface 2a of the chip 2. The seam portion 4 may extend in the height direction (Z-axis direction) of the chip 2. Even with this configuration, the sealing layer 5 easily extends into the seam portion 4 when the sealing layer 5 is provided so as to cover the buried layer 3 and the seam portion 4.

As described with reference to FIG. 65 and the like, the seam portion 4 may have a shape having a width changing with a growth of the portion in the extending direction. The seam portion 4 may include a central portion 42 located at the center in the extending direction of the seam portion 4 and an end portion 41 (which may be an end portion 43) located at the end in the extending direction of the seam portion 4. The central portion 42 may have a width greater than the width of the end portion 41 (which may be the end portion 43). Even with this shape of the seam portion 4, communication of the seam portion 4 to the outside can be suppressed. In addition, for example, by providing the dummy chip 2D or using the chip 2 having a narrowed width on the front surface 2a side, the extending direction of the seam portion 4 can be brought close to the height direction (Z-axis direction) of the chip 2.

### 20. Dummy Chips Layout Example

Some layout examples of the dummy chip 2D described in the thirteenth embodiment will be described.

### <First Layout Example>

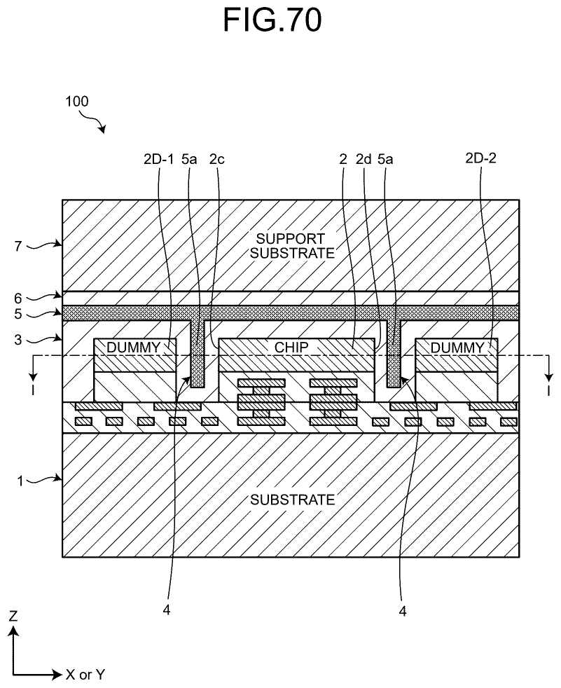

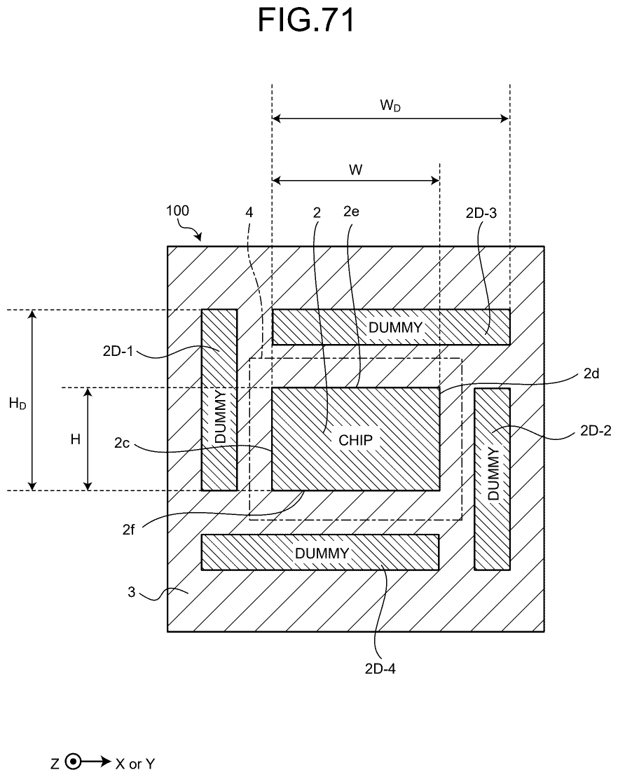

FIGS. 70 and 71 are diagrams illustrating a first layout example of the dummy chip. FIG. 70 schematically illustrates a cross section of the light detection device 100. FIG. 71 schematically illustrates a cross section (planar layout) of light detection device 100 as viewed along line I-I in FIG. 70. In the example illustrated in FIG. 70, the seam portion 4 is filled with the extension 5a. In FIG. 71, the seam portion 4 is drawn to be simplified with no width.

The chip 2 has a side surface 2c, a side surface 2d, a side surface 2e, and a side surface 2f. The side surface 2c and the side surface 2d are a pair of side surfaces facing each other. The side surface 2e and the side surface 2f are a pair of side surfaces facing each other and connecting the side surface 2c and the side surface 2d to each other. When there is no need to distinguish the side surface 2c, the side surface 2d, the side surface 2e, and the side surface 2f of the chip 2 in particular, they are also simply referred to as side surfaces of the chip 2.

As illustrated in FIG. 71, the dummy chip 2D extends so as to face the side surface of the chip 2 in plan view. The dummy chips 2D may be a plurality of dummy chips 2D each facing a mutually different side surface of the chip 2.

The number of dummy chips 2D to be provided for one chip 2 may be two or more. The material of the dummy chip 2D may include the same material as the material of the chip 2. In addition, the dummy chip 2D may have the same height as the height of the chip 2. The chip 2 and the dummy chip 2D may be alternately provided in the XY plane direction.

When the dummy chip 2D is present around the chip 2, it is possible to suppress stress acting on the material of the buried layer 3 from the chip 2 toward the periphery of the chip 2 at formation of the buried layer 3 (for example, at the time of deposition) as compared with the case without the dummy chip 2D.

The dummy chip 2D may include two or more dummy chips 2D. In the example illustrated in FIG. 71, the dummy chip 2D includes four dummy chips 2D. The dummy chip 2D facing the side surface 2c of the chip 2 is denoted as a dummy chip 2D-1 in the drawing. The dummy chip 2D facing the side surface 2d of the chip 2 is denoted as a dummy chip 2D-2 in the drawing. The dummy chip 2D facing the side surface 2e of the chip 2 is denoted as a dummy chip 2D-3 in the drawing. The dummy chip 2D facing the side surface 2f of the chip 2 is denoted as a dummy chip 2D-4 in the drawing. In the example illustrated in FIG. 71, the dummy chips 2D are disposed at intervals from each other. Near the corner of the chip 2, the dummy chips 2D are separated from each other.

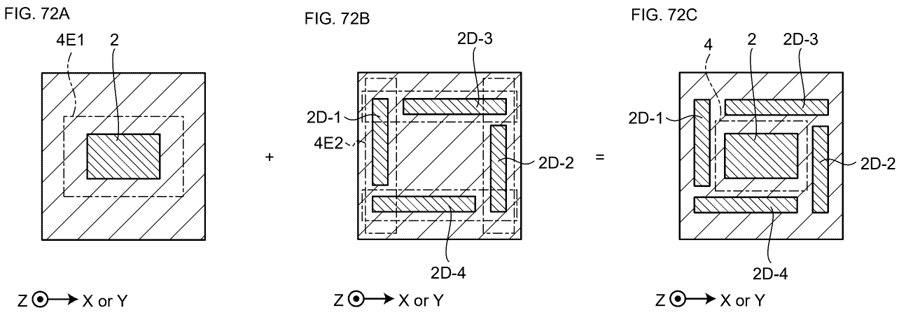

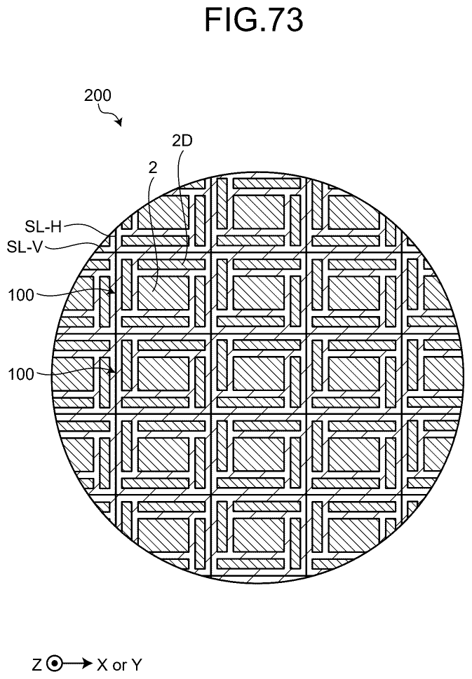

FIG. 72 is a diagram illustrating an effect of the dummy chip. (A) of FIG. 72 schematically illustrates a range of a seam portion 4E1 that can occur when only the chip 2 is provided. (B) of FIG. 72 schematically illustrates a range of a seam portion 4E2 that can occur when only the dummy chip 2D is provided. (C) of FIG. 72 schematically illustrates a range of the seam portion 4 that occurs when the chip 2 and the dummy chip 2D are provided. When the dummy chip 2D is present, the range of the seam portion 4 in plan view is narrowed. This means that the extending direction of the seam portion 4 is brought close to the height direction (Z-axis positive direction) of the chip 2 and the dummy chip 2D, that is, obtaining the seam portion 4 extending in the vertical direction.

Returning to FIG. 71, the dummy chip 2D may have a length of a half or more of the length of the side surface of the facing chip 2 in the extending direction of the dummy chip 2D. As an example, the length of the side surface 2c of the chip 2 is denoted as a length H in the drawing. The length of the side surface 2e of the chip 2 is denoted as a length W and illustrated. The length in the extending direction of the dummy chip 2D-1 facing the side surface 2c of the chip 2 is denoted as a length Hp in the drawing. The length in the extending direction of the dummy chip 2D-3 facing the side surface 2e of the chip 2 is denoted as a length W_{D} in the drawing.

The length H_{D} of the dummy chip 2D-1 may be designed to satisfy the following Formula (1).

H_{D}≥H/2 (1)

The dummy chip 2D-2 may be designed in a similar manner.

The dummy chip 2D-3 may be designed to satisfy the following Formula (2).

W_{D}≥W/2 (2)

The dummy chip 2D-4 may be designed in a similar manner.

When the dummy chip 2D has a certain length as described above, it is easy to obtain the effect of the dummy chip 2D, that is, the effect of bringing the extending direction of the seam portion 4 close to the height direction (Z-axis positive direction) of the chip 2 and the dummy chip 2D.

Furthermore, in the example illustrated in FIG. 71, the dummy chips 2D are disposed so as to sandwich the chip 2. Specifically, the dummy chip 2D-1 and the dummy chip 2D-2 are disposed on opposite sides across the chip 2 so as to sandwich the chip 2. In addition, the dummy chip 2D-3 and the dummy chip 2D-4 are arranged on opposite sides across the chip 2 so as to sandwich the chip 2. For example, it is possible to expand a region capable of having the effect of the dummy chip 2D as compared with a case of providing only the dummy chip 2D facing one side surface of the chip 2.

The components of the light detection device 100, such as the chip 2 and the dummy chip 2D, may be provided for each region partitioned by scribe lines on the wafer, for example. By dicing (cutting) the wafer along the scribe lines, the light detection device 100 is obtained. This will be described with reference to FIG. 73.

FIG. 73 is a diagram illustrating an example of a schematic configuration of a wafer. The wafer is denoted as a wafer 200 in the drawing. FIG. 73 schematically illustrates a part of the wafer 200 in plan view (as viewed in the negative direction of the Z-axis). The wafer 200 has scribe lines SL-H and scribe lines SL-V formed to be orthogonal to each other. When they are not particularly distinguished, they are simply referred to as the scribe lines SL.

One region surrounded by the scribe lines SL-H and the scribe lines SL-V corresponds to one light detection device 100. In this example, the chip 2 and the dummy chip 2D of the light detection device 100 are located inside the scribe lines SL (not located on the scribe lines SL). One piece (1 shot) obtained by dicing the wafer 200 along the scribe lines SL is to be the light detection device 100.

Regarding a second layout example to a seventh layout example described below, differences from the first layout example will be mainly described. The description of the first layout example may be appropriately incorporated within a range without contradiction. For example, the material of the dummy chip 2D may include the same material as the material of the chip 2. The dummy chip 2D may have the same height as the height of the chip 2. Furthermore, the dummy chip 2D may be disposed so as to sandwich the chip 2.

### <Second Layout Example>

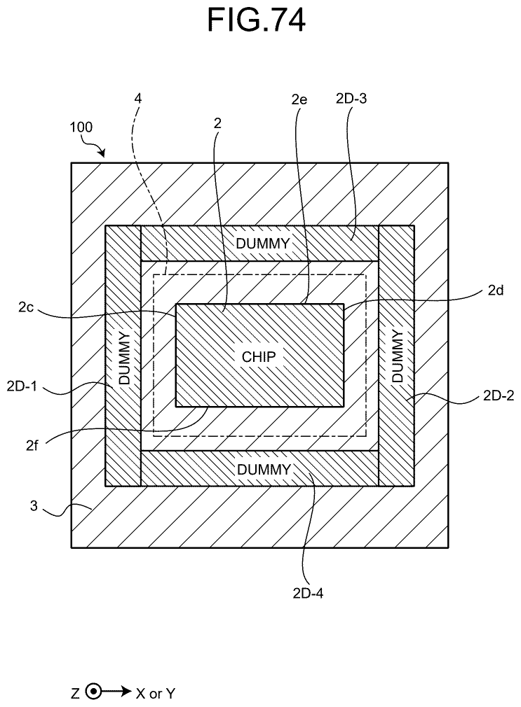

FIG. 74 is a diagram illustrating a second layout example of the dummy chips. The dummy chip 2D continuously extends so as to surround the chip 2. In this example, the dummy chips 2D-1 to 2D-4 are connected to each other and disposed so as to surround the chip 2. The entire periphery of the chip 2 is surrounded by the dummy chip 2D, making it possible to maximize the effect of the dummy chip 2D.

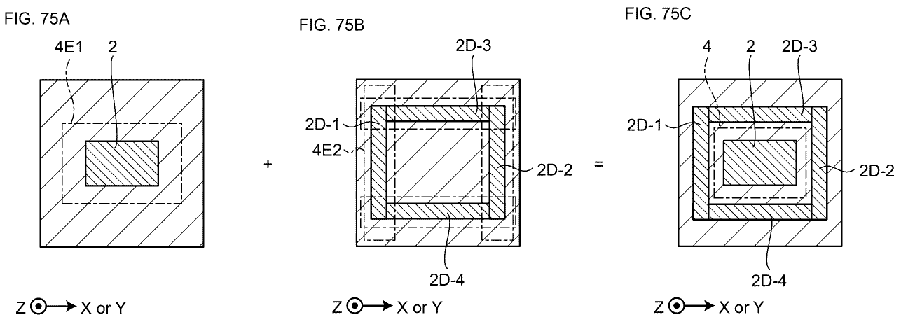

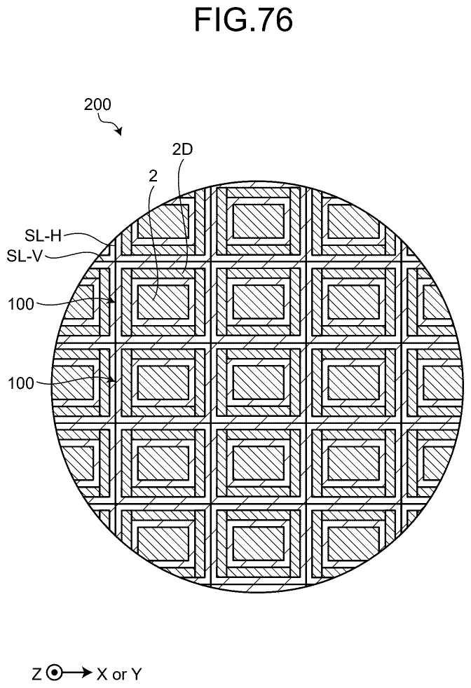

FIG. 75 is a diagram illustrating an effect of the dummy chip. The description is similar to that in FIG. 72, and thus will be omitted.

FIG. 76 is a diagram illustrating an example of a schematic configuration of a wafer. The chip 2 and the dummy chip 2D of the light detection device 100 are located inside the scribe lines SL. By dicing the wafer 200 along the scribe lines SL, the light detection device 100 is obtained.

### <Third Layout Example>

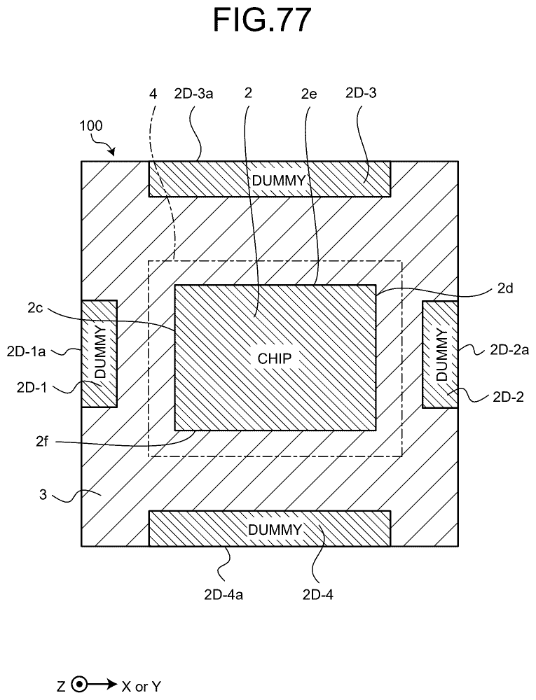

FIG. 77 is a diagram illustrating a third layout example of the dummy chips. The dummy chip 2D-1, the dummy chip 2D-2, the dummy chip 2D-3, and the dummy chip 2D-4, located to be separated from each other, are disposed so as to surround the chip 2.

Among the side surface of the dummy chip 2D-1, the side surface of the dummy chip 2D-2, the side surface of the dummy chip 2D-3, and the side surface of the dummy chip 2D-4, the side surfaces located on the side opposite to the chip 2 are each denoted as a side surface 2D-1a, a side surface 2D-2a, a side surface 2D-3a, and a side surface 2D-4a. These side surfaces constitute a part of the side surfaces of the light detection device 100. When the light detection device 100 is viewed from the side (when viewed in the X-axis direction or the Y-axis direction), the side surface 2D-1a, the side surface 2D-2a, the side surface 2D-3a, and the side surface 2D-4a are exposed from the buried layer 3 (not covered with the buried layer 3). The layout that allows the dummy chips 2D to be disposed on the outermost sides of the light detection device 100 makes it easier to ensure a region where the chip 2 is provided.

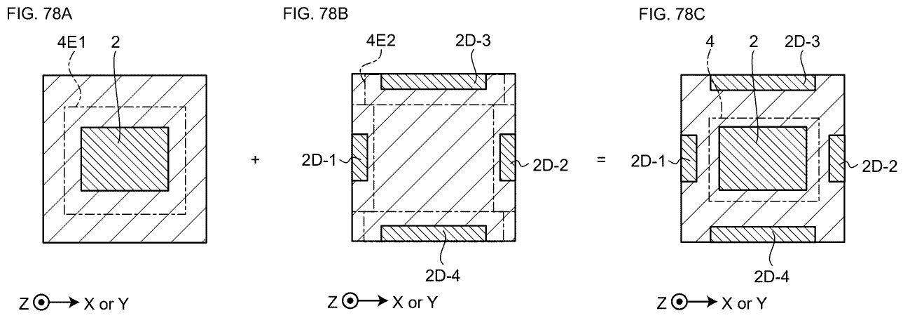

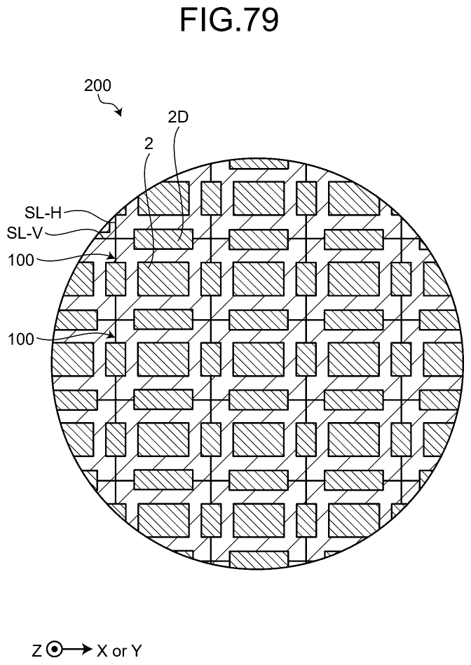

FIG. 78 is a diagram illustrating an effect of the dummy chip. The description is similar to that in FIG. 72, and thus will be omitted.

FIG. 79 is a diagram illustrating an example of a schematic configuration of a wafer. The chip 2 of the light detection device 100 is located inside the scribe line SL. On the other hand, the dummy chips 2D of the adjacent light detection devices 100 are provided to be connected to cross the scribe line SL. In other words, these dummy chips 2D are provided on the scribe line SL. The light detection device 100 is obtained by dicing the wafer 200 and the dummy chip 2D along the scribe line SL. Since the dummy chips 2D of the adjacent light detection devices 100 can be integrated, facilitating the manufacturing.

### <Fourth Layout Example>

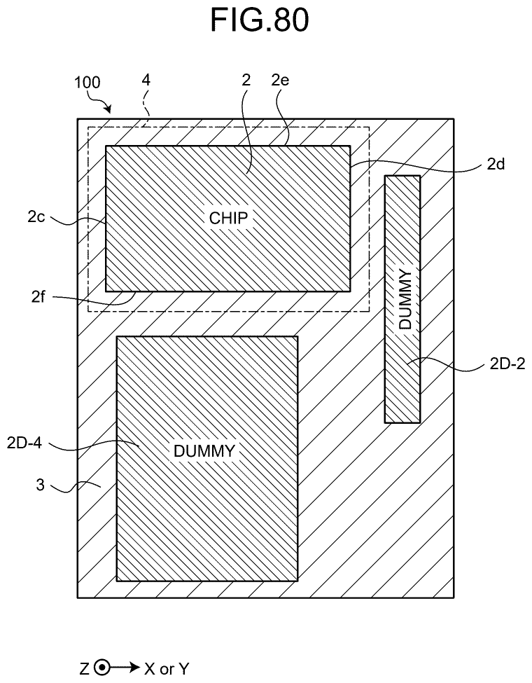

FIG. 80 is a diagram illustrating a fourth layout example of the dummy chips. The chip 2 is disposed near a corner of the light detection device 100. In this example, the chip 2 is disposed such that the side surface 2c and the side surface 2e of the chip 2 are located near the side surfaces of the light detection device 100. Two dummy chips 2D are disposed to face the other two side surfaces of the chip 2. In this example, a dummy chip 2D-2 facing a side surface 2d of the chip 2 and a dummy chip 2D-4 facing a side surface 2f of the chip 2 are disposed.

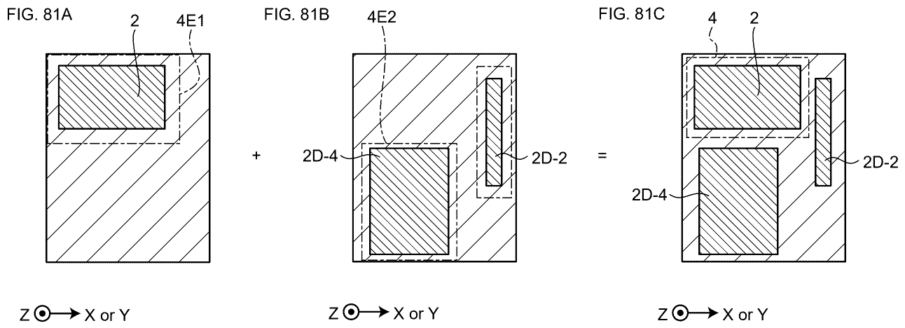

FIG. 81 is a diagram illustrating an effect of the dummy chip. The description is similar to that in FIG. 72, and thus will be omitted.

FIG. 82 is a diagram illustrating an example of a schematic configuration of a wafer. In this example, the chip 2 and the dummy chip 2D of the light detection device 100 are located inside the scribe lines SL. By dicing the wafer 200 along the scribe lines SL, the light detection device 100 is obtained.

### <Fifth Layout Example>

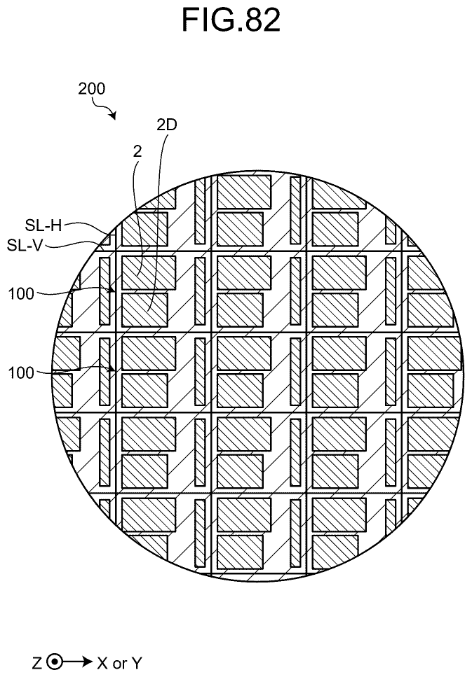

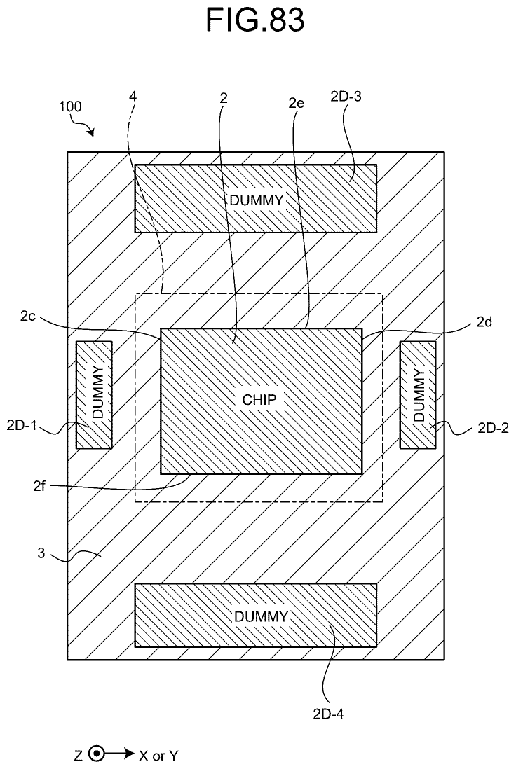

FIG. 83 is a diagram illustrating a fifth layout example of the dummy chips. The dummy chip 2D-1, the dummy chip 2D-2, the dummy chip 2D-3, and the dummy chip 2D-4, located to be separated from each other, are disposed so as to surround the chip 2. Unlike FIG. 77 described above, when the light detection device 100 is viewed from the side, the side surface 2D-1a of the dummy chip 2D-1, the side surface 2D-2a of the dummy chip 2D-2, the side surface 2D-3a of the dummy chip 2D-3, and the side surface 2D-4a of the dummy chip 2D-4 are not exposed from the buried layer 3 (covered by the buried layer 3).

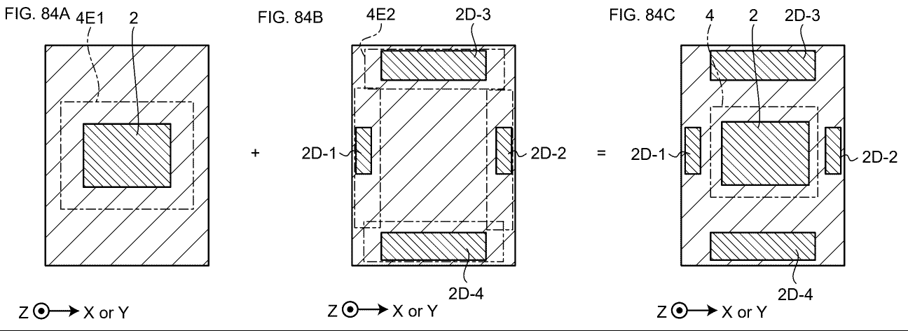

FIG. 84 is a diagram illustrating an effect of the dummy chip 2D. The description is similar to that in FIG. 72, and thus will be omitted.

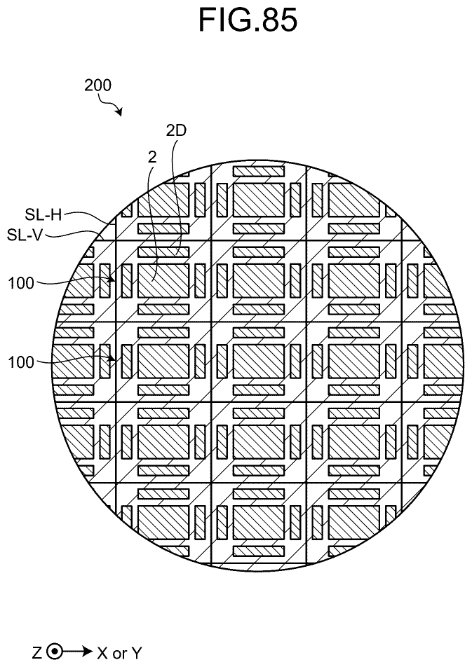

FIG. 85 is a diagram illustrating an example of a schematic configuration of a wafer. The chip 2 and the dummy chip 2D of the light detection device 100 are located inside the scribe lines SL. Unlike FIG. 79 described above, the dummy chips 2D of the adjacent light detection devices 100 are separated from each other without crossing the scribe line SL. By dicing the wafer 200 along the scribe lines SL, the light detection device 100 is obtained.

### <Sixth Layout Example>

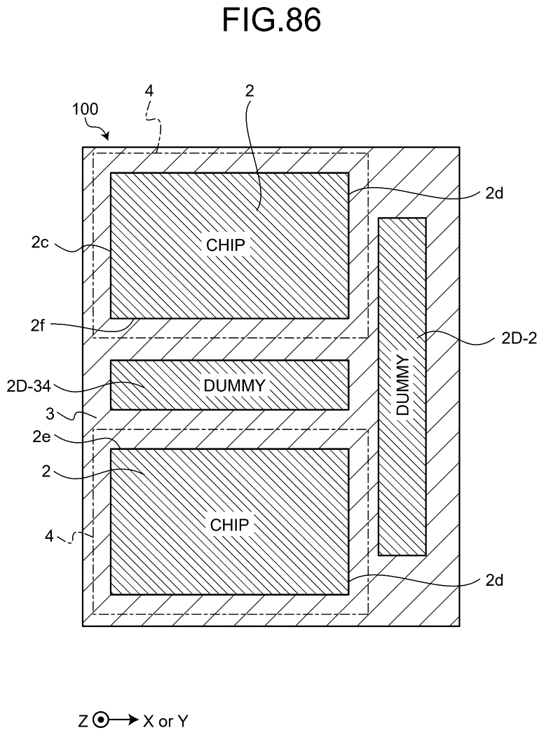

FIG. 86 is a diagram illustrating an example of a schematic configuration of a wafer. The chip 2 includes two or more chips 2, and FIG. 86 illustrates the two chips 2. The side surface 2e of one chip 2 and the side surface 2f of the other chip 2 face each other.

Two dummy chips 2D are disposed. One of the dummy chips 2D is disposed between the two chips 2. The dummy chip 2D is denoted as a dummy chip 2D-34 in the drawing. The other dummy chip 2D is a dummy chip 2D-2 disposed to extend along the side surfaces 2d of the two chips 2.

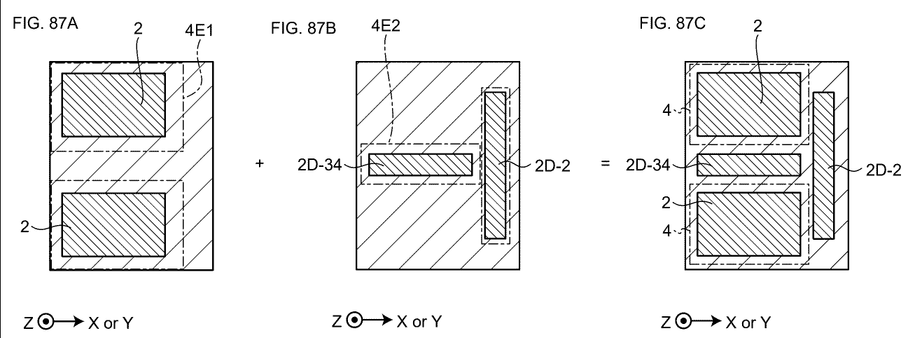

FIG. 87 is a diagram illustrating an effect of the dummy chip. The description is similar to that in FIG. 72, and thus will be omitted.

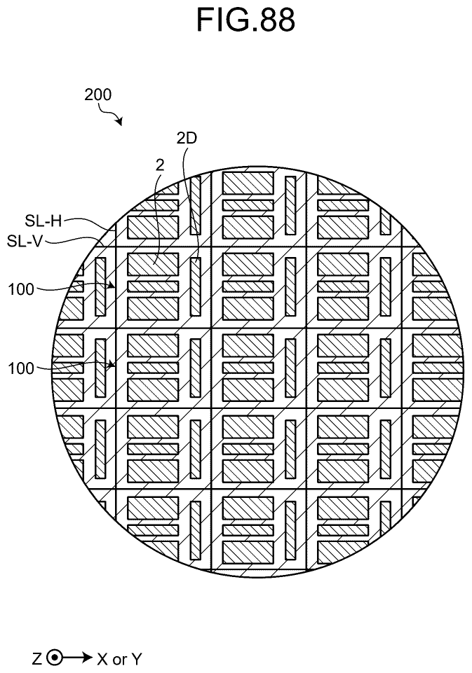

FIG. 88 is a diagram illustrating an example of a schematic configuration of a wafer. The chip 2 and the dummy chip 2D of the light detection device 100 are located inside the scribe lines SL. By dicing the wafer 200 along the scribe lines SL, the light detection device 100 is obtained.

### <Seventh Layout Example>

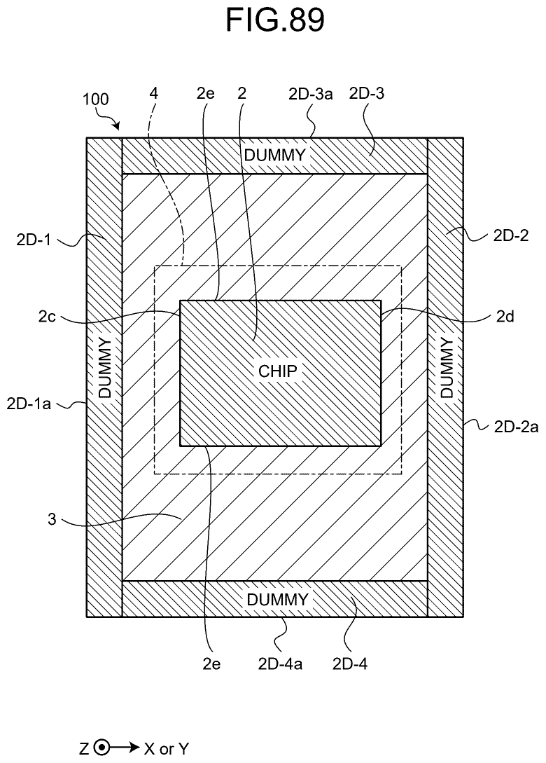

FIG. 89 is a diagram illustrating a seventh layout example of the dummy chips. Advantages of the second layout example (FIG. 74) and the third layout example (FIG. 77) described above are combined. The dummy chip 2D continuously extends so as to surround the chip 2. In this example, the dummy chips 2D-1 to 2D-4 are connected to each other and disposed so as to surround the chip 2. In addition, when the light detection device 100 is viewed from the side (when viewed in the X-axis direction or the Y-axis direction), the side surface 2D-1a of the dummy chip 2D-1, the side surface 2D-2a of the dummy chip 2D-2, the side surface 2D-3a of the dummy chip 2D-3, and the side surface 2D-4a of the dummy chip 2D-4 are exposed from the buried layer 3.

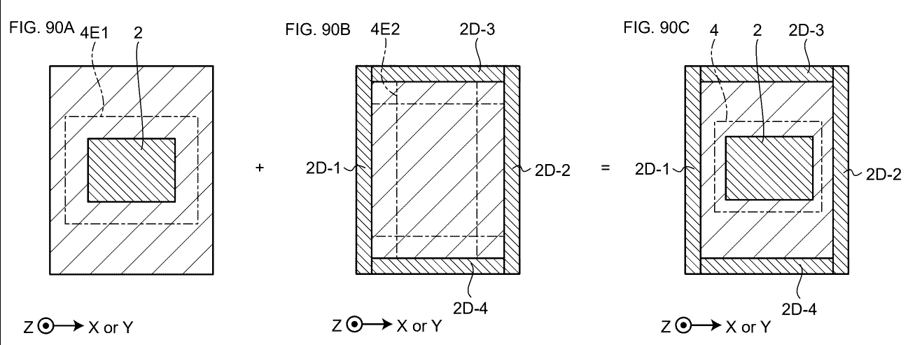

FIG. 90 is a diagram illustrating an effect of the dummy chip. The description is similar to that in FIG. 72, and thus will be omitted.

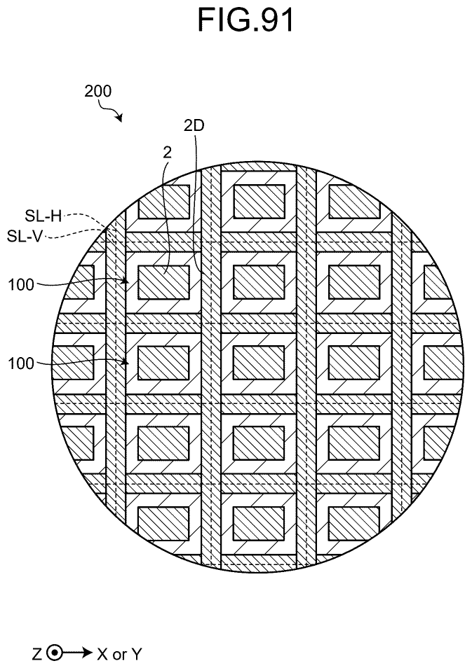

FIG. 91 is a diagram illustrating an example of a schematic configuration of a wafer. The chip 2 of the light detection device 100 is located inside the scribe line SL. On the other hand, the dummy chips 2D of the adjacent light detection devices 100 are provided to be connected to cross the scribe line SL. The light detection device 100 is obtained by dicing the wafer 200 and the dummy chip 2D along the scribe line SL.

### <Modifications>

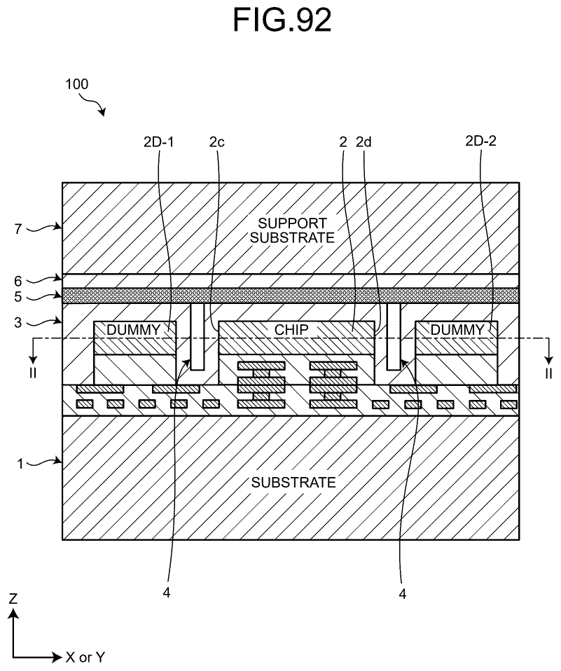

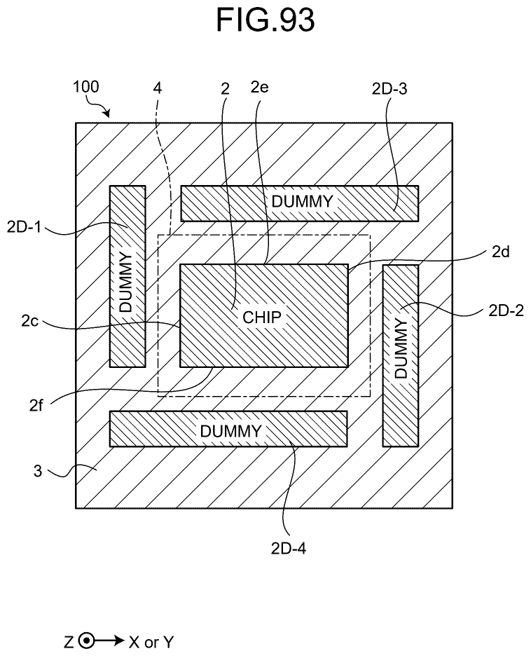

FIGS. 92 and 93 are diagrams illustrating modifications. FIG. 92 schematically illustrates a cross section of the light detection device 100. FIG. 93 schematically illustrates a cross section (planar layout) of light detection device 100 as viewed along line II-II in FIG. 92. The layout of the dummy chips 2D is the same as the first layout example described above (FIGS. 70 and 71). However, in this example, the sealing layer 5 does not have the extension 5a, and the seam portion 4 is an empty space. Even in this case, the effect of the dummy chip 2D can be obtained. Similarly, the seam portion 4 may be an empty space also in the second layout example to the seventh layout example described above.

### <Section Summary>

As described above, the light detection device 100 in which the dummy chip 2D is disposed is specified as follows, for example. As described with reference to FIGS. 71, 74, 77, 80, 83, 86, 89, 93, and the like, the dummy chip 2D may extend so as to face the side surface of the chip 2 in plan view (when viewed in the Z-axis negative direction), and may have a length (length H_{D}, length W_{D}) that is a half or more of the length (length H, length W) of the side surface of the chip 2 facing each other in the extending direction (H_{D}≥H/2, W_{D}≥W/2). When the dummy chip 2D has a certain length in this manner, it is easy to obtain the effect of the dummy chip 2D, that is, the effect of bringing the extending direction of the seam portion 4 close to the height direction (Z-axis positive direction) of the chip 2 and the chip 2 of the dummy chip 2D.

As described with reference to FIGS. 71, 74, 77, 83, 89, 93, and the like, the dummy chip 2D may be disposed so as to sandwich the chip 2 in plan view. The dummy chip 2D may include two or more dummy chips 2D. This makes it possible to expand a region capable of having the effect of the dummy chip 2D as compared with a case of providing only one dummy chip 2D facing one side surface of the chip 2.

As described with reference to FIGS. 70 and 71 and the like, the material of the dummy chip 2D may include the same material as the material of the chip 2. In addition, the dummy chip 2D may have the same height as the height of the chip 2 (the length in the Z-axis direction). For example, using such a dummy chip 2D, the extending direction of the seam portion 4 can be brought close to the height direction (Z-axis direction) of the chip 2 and the chip 2 of the dummy chip 2D.

As described with reference to FIG. 86 and the like, the chip includes two or more chips. For example, even in such a multi-chip configuration, the effect of the dummy chip 2D can be obtained.

As described with reference to FIGS. 74 and 89 and the like, the dummy chip 2D may continuously extend so as to surround the chip 2 in plan view. This configuration can maximize the effect of the dummy chip 2D.

As described with reference to FIGS. 77 and 89 and the like, the dummy chip 2D (for example, the dummy chip 2D-1, the dummy chip 2D-2, the dummy chip 2D-3, and the dummy chip 2D-4) may have a surface (for example, the side surface 2D-1a, the side surface 2D-2a, the side surface 2D-3a, and the side surface 2D-4a) exposed from the buried layer 3 when the light detection device 100 is viewed from the side (viewed in the X-axis direction or the Y-axis direction). With this configuration, the dummy chip 2D can be disposed on the outermost side of the light detection device 100. For example, this makes it easy to ensure a region where the chip 2 is located. Furthermore, since the dummy chips 2D of the adjacent light detection devices 100 can be integrated on the wafer 200, facilitating the manufacturing.

### 21. Sixteenth Embodiment

FIG. 94 is a diagram illustrating an example of a schematic configuration of a light detection device according to a sixteenth embodiment. The light detection device 100 includes a sealing layer 5-2 instead of the sealing layer 5. In this example, the light detection device 100 does not include the auxiliary layer 6. The support substrate 7 is bonded (laminated) through the sealing layer 5-2.

The buried layer 3 is provided so as to cover the side surface of the chip 2. the front surface 2a of the chip 2 is exposed from the buried layer 3. At least a part of the seam portion 4 is filled with a material different from the material of the buried layer 3. In this example, the extension 5a described so far extends into the seam portion 4 so as to fill at least a part of the seam portion 4.

The sealing layer 5-2 is provided so as to cover the buried layer 3, the seam portion 4, and the front surface 2a of the chip 2. The sealing layer 5-2 is in contact with not only the front surface 3a of the buried layer 3 but also the front surface 2a of the chip 2.

The sealing layer 5-2 has thermal conductivity higher than thermal conductivity of silicon (Si). A portion to which heat from the chip 2 is transferred is easily thermally connected to the outside through the sealing layer 5-2 (easily thermally exposed to improve heat dissipation or the like). For example, using a metal material for the buried layer 3 in order to improve the heat dissipation by the buried layer 3 might cause occurrence of leakage between the metal material and the chip 2, leading to degradation of the reliability of the device. Instead, by improving the heat dissipation using the sealing layer 5-2, it is possible to increase reliability of the device while suppressing the leakage.

### 22. Seventeenth Embodiment

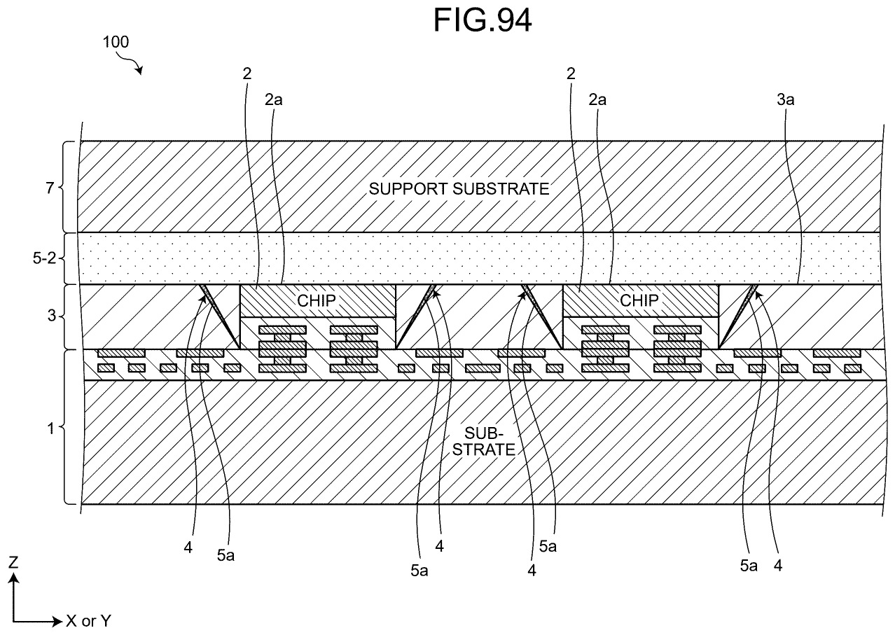

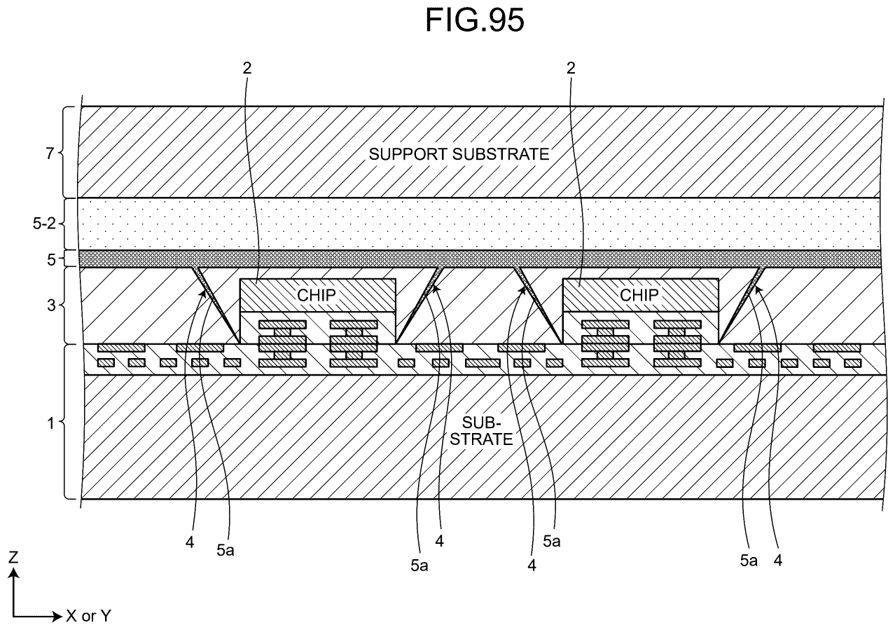

FIG. 95 is a diagram illustrating an example of a schematic configuration of a light detection device according to a seventeenth embodiment. The light detection device 100 includes the above-described sealing layer 5-2 instead of the auxiliary layer 6 described above. There are provided two sealing layers, namely, the sealing layer 5 and the sealing layer 5-2. The Sealing layer 5 is a first sealing layer provided so as to cover the buried layer 3 and the seam portion 4. The sealing layer 5-2 is a second sealing layer provided so as to cover the sealing layer 5. The support substrate 7 is bonded through the sealing layer 5-2. In this manner, it is also possible to improve heat dissipation using the sealing layer 5-2.

### 23. Eighteenth Embodiment

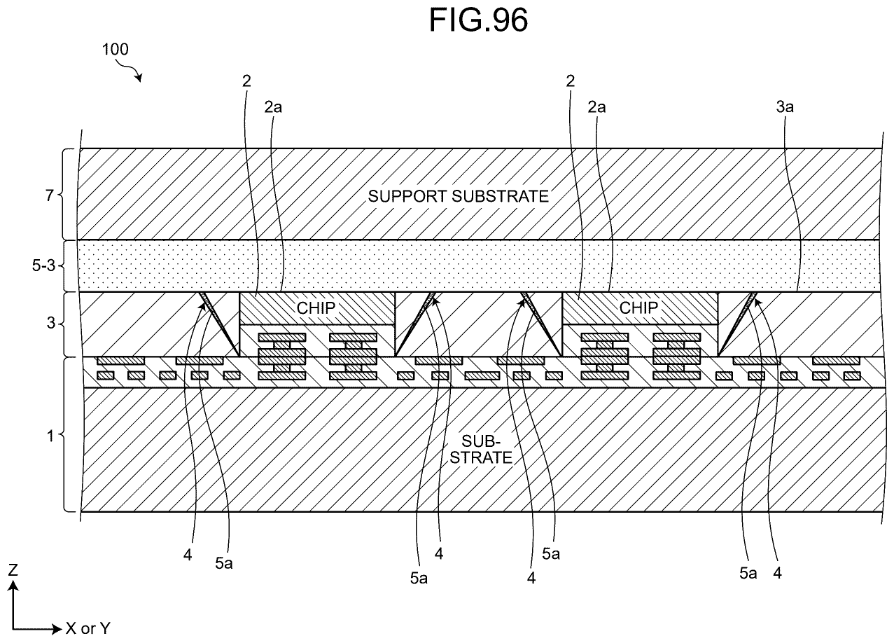

FIG. 96 is a diagram illustrating an example of a schematic configuration of a light detection device according to an eighteenth embodiment. The light detection device 100 is different from the configuration of FIG. 94 described above in including a sealing layer 5-3 instead of including the sealing layer 5-2.

The sealing layer 5-3 is a metal layer. Examples of the material of the metal layer include copper (Cu), aluminum (Al), tungsten (W), titanium (Ti), tantalum (Ta), gold (Au), silver (Ag), platinum (Pt), and palladium (Pd). The support substrate 7 is bonded through the sealing layer 5-3. In this manner, it is also possible to improve heat dissipation using the sealing layer 5-3, being a metal layer.

### 24. Nineteenth Embodiment

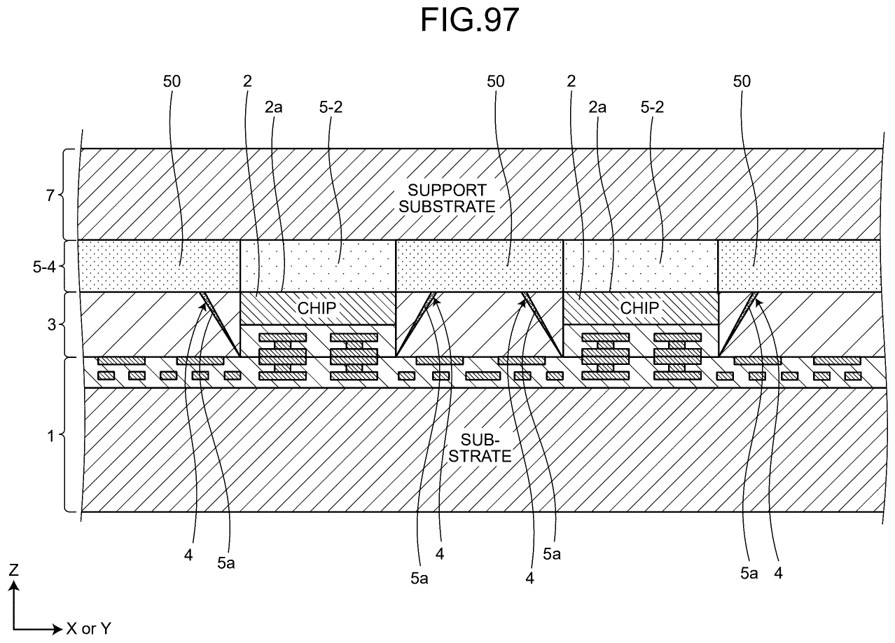

FIG. 97 is a diagram illustrating an example of a schematic configuration of a light detection device according to a nineteenth embodiment. In contrast to the configuration of FIG. 94 described above, the light detection device 100 includes a sealing layer 5-4 instead of including the sealing layer 5-2.

The sealing layer 5-4 includes an insulating layer 50 and a sealing layer 5-2 extending continuously in a plane direction (XY plane direction) of the sealing layer 5-4. The insulating layer 50 is a first portion that covers the buried layer 3, out of the buried layer 3 and the chip 2, in the sealing layer 5-4. The sealing layer 5-2 is a second portion provided so as to cover the buried layer 3 out of the buried layer 3 and the chip 2.

As the name indicates, the insulating layer 50 has an insulating property. Examples of the material of the insulating layer 50 include SiOx, SiNx, SiON, SiOC, SiCN, and SiC. As described above, the sealing layer 5-2 has thermal conductivity higher than thermal conductivity of silicon. The sealing layer 5-2 may be provided so as to be in contact with the front surface 2a of the chip 2. In this manner, it is also possible to improve heat dissipation using the sealing layer 5-2.

### 25. Twentieth Embodiment

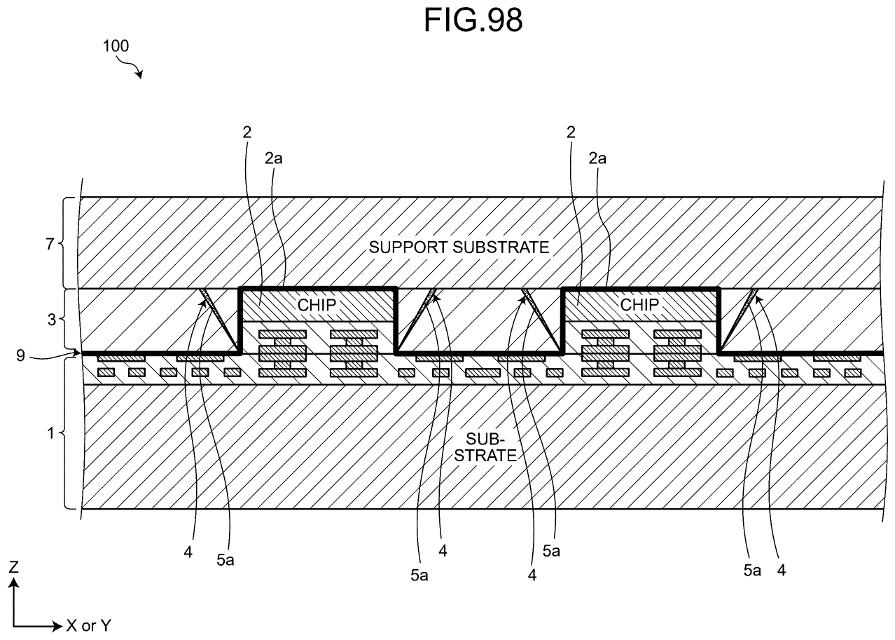

FIG. 98 is a diagram illustrating an example of a schematic configuration of a light detection device according to a twentieth embodiment. The light detection device 100 is different from the configuration of FIG. 94 described above in including an additional layer 9 instead of including the sealing layer 5-2. Note that the additional layer 9 here may be understood separately from the additional layer 9 of the seventh embodiment (FIG. 7) described above.

The additional layer 9 is provided between the chip 2 and the buried layer 3. More specifically, the additional layer 9 is provided so as to cover the substrate 1 and the chip 2. The buried layer 3 is provided so as to cover the additional layer 9 except for a portion of the additional layer 9 located above the chip 2.

The additional layer 9 in this embodiment is a metal layer (also referred to as a barrier metal). Examples of the material of the metal layer include titanium (Ti) and tantalum (Ta).

The inside of the seam portion 4 is filled with the extension 5a, and the seam portion 4 is covered with the additional layer 9. The support substrate 7 is bonded through the buried layer 3 and the additional layer 9. The support substrate 7 and the additional layer 9 can function as a sealing layer covering the buried layer 3, the seam portion 4, and the chip 2. In this manner, it is also possible to improve heat dissipation using the additional layer 9, being a metal layer. It is possible to reduce the number of manufacturing processes or reduce the thickness of the device (decrease the height) by eliminating the auxiliary layer 6.

### 26. Twenty-First Embodiment

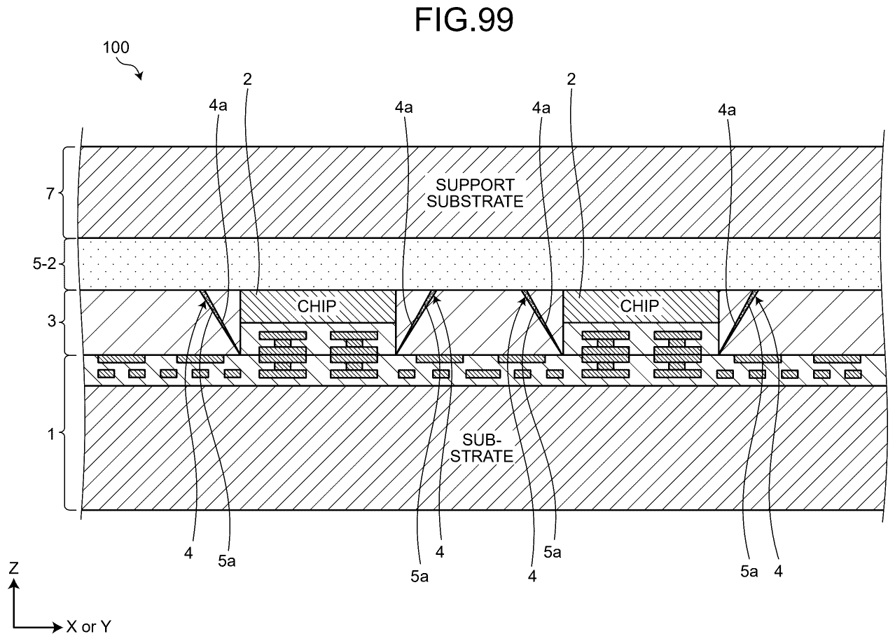

FIG. 99 is a diagram illustrating an example of a schematic configuration of a light detection device according to a twenty-first embodiment. As compared with the configuration of FIG. 94 described above, a part of the seam portion 4 is filled with the extension 5a, but the remaining portion is the empty space 4a. It is also possible to improve heat dissipation using the sealing layer 5-2 also in such a configuration. The stress between the chips 2 can be alleviated by the presence of the empty space 4a. Also, in the configuration of FIGS. 95 to 98 described above, a part of the seam portion 4 may be filled with the extension 5a, and the remaining portion may be the empty space 4a.

### 27. Twenty-Second Embodiment

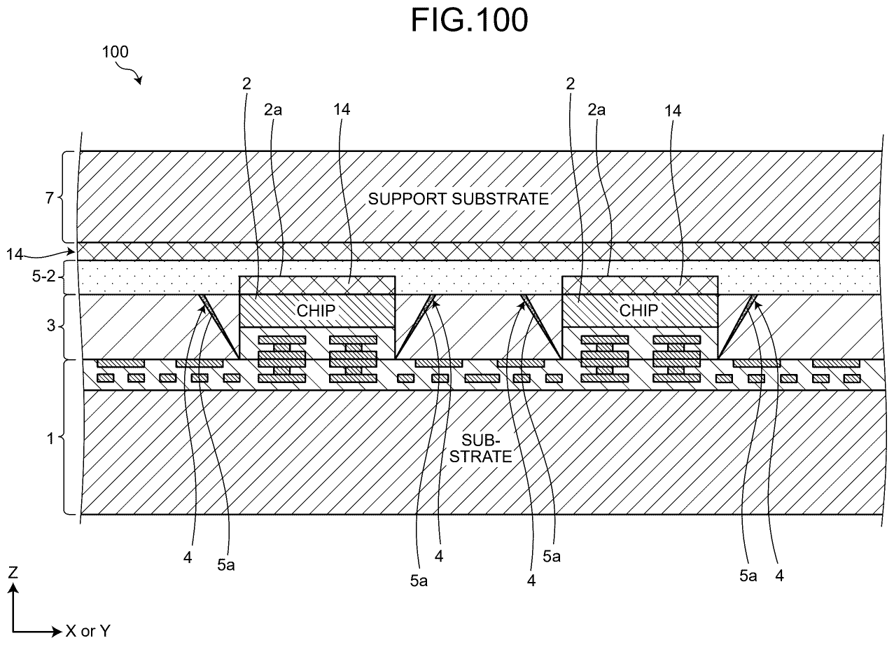

FIG. 100 is a diagram illustrating an example of a schematic configuration of a light detection device according to a twenty-second embodiment. The light detection device 100 is different from the configuration of FIG. 94 described above in including a compound layer 14.

The compound layer 14 is provided between the chip 2 and the sealing layer 5-2, and is also provided on the sealing layer 5-2. The compound layer 14 may be a silicide layer, for example. Examples of the material of the compound layer 14 may include a semiconductor material such as silicon (Si) and a metal material.

Two compound layers 14 are provided. The first compound layer 14 is provided on the front surface 2a of the chip 2. The sealing layer 5-2 is provided so as to cover the buried layer 3, the seam portion 4, and the first compound layer 14. The second compound layer 14 is provided so as to cover the sealing layer 5-2. The support substrate 7 is bonded through the compound layer 14. In this manner, it is also possible to improve heat dissipation using the compound layer 14 including the metal material.

### 28. Twenty-Third Embodiment

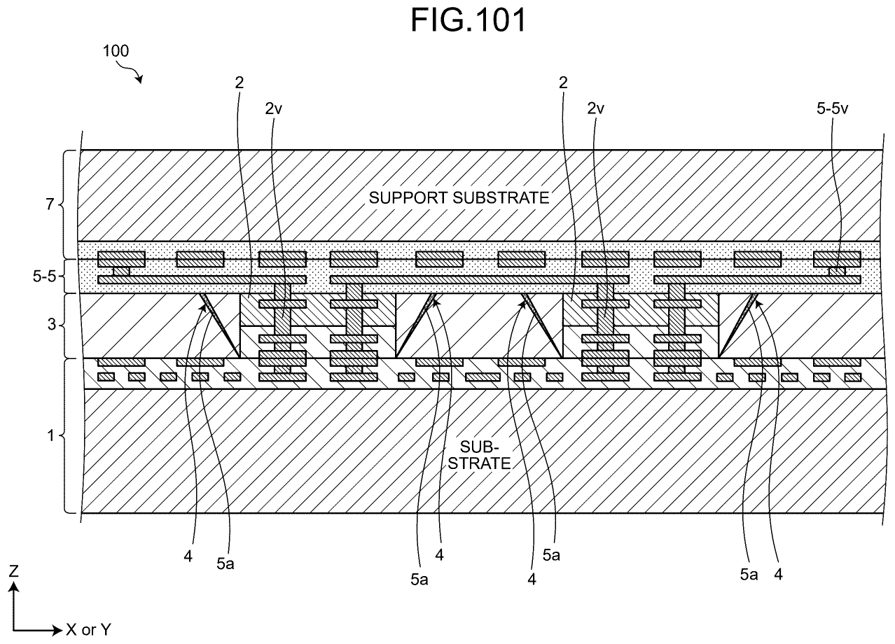

FIG. 101 is a diagram illustrating an example of a schematic configuration of a light detection device according to a twenty-third embodiment. The light detection device 100 is different from the configuration of FIG. 94 described above in including a sealing layer 5-5 instead of including the sealing layer 5-2. The sealing layer 5-5 is a layer having a metal structure such as a wiring line (including a via) provided in an insulator. The metal structure provides a heat dissipation route, and can be used as wiring or a pad. An example of the metal structure is indicated as a via 5-5v with a reference sign. In this manner, it is also possible to improve heat dissipation using the sealing layer 5-5. In addition, a wiring can be formed at a bonding surface between the buried layer 3 and the support substrate 7.

### 29. Example of Application to Imaging Device

An example of application of the light detection device 100 according to the above-described 16 to 23 embodiments is an imaging device. The imaging device has been described above with reference to FIGS. 20 to 23, and thus, a detailed description thereof will not be repeated. For example, in a case where the light detection device 100 according to the sixteenth embodiment is used as an imaging device, it is possible to adopt a configuration including the sealing layer 5-2 in place of the sealing layer 5 and the auxiliary layer 6 in FIGS. 20 to 22.

### 30. Example of Manufacturing Method

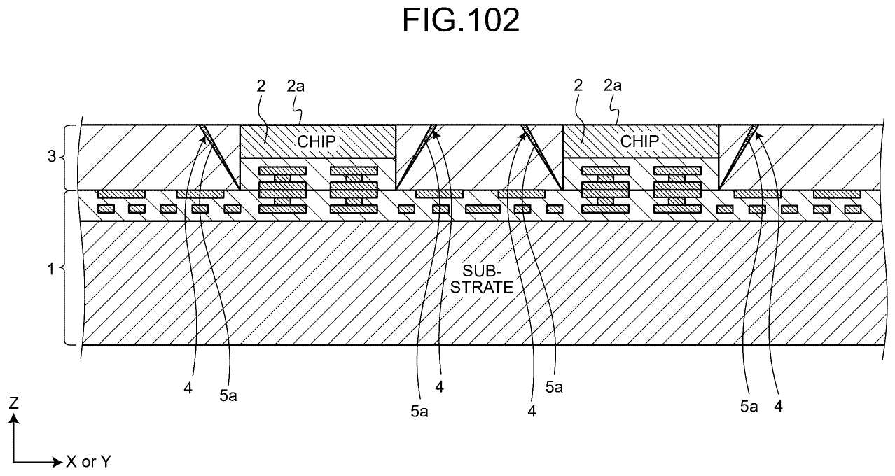

FIGS. 102 to 107 are diagrams illustrating an example of a method of manufacturing the light detection device. FIGS. 102 to 105 illustrate examples of a manufacturing method for obtaining the configuration of FIG. 94 described above. As a premise, it is assumed that a manufacturing process similar to that in FIGS. 9 to 12 described above is completed.

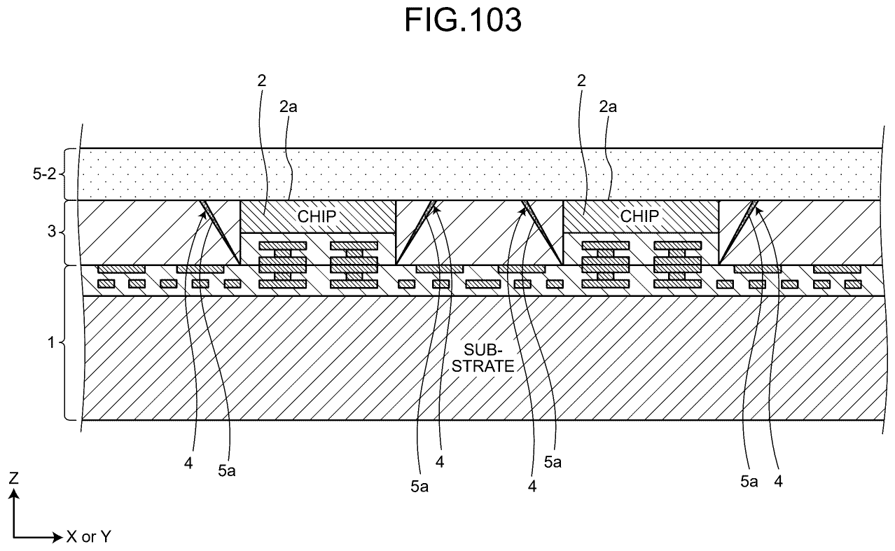

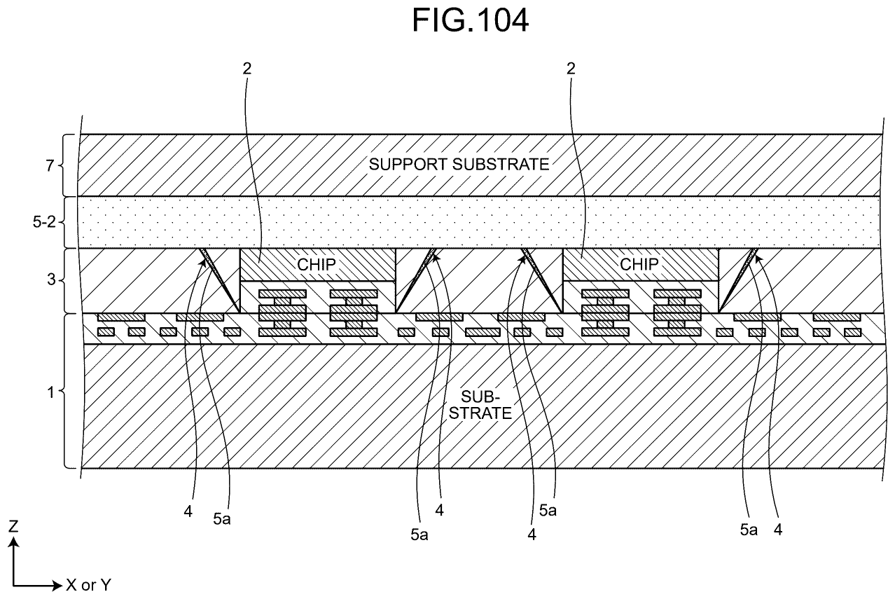

As illustrated in FIG. 102, the sealing layer 5 and the buried layer 3 are polished and cleaned. the front surface 2a of the chip 2 is exposed from the buried layer 3. As illustrated in FIG. 103, a sealing layer 5-2 is provided so as to cover the buried layer 3, the seam portion 4, and the chip 2. As illustrated in FIG. 104, the configuration of FIG. 94 described above is obtained by bonding the support substrate 7 through the sealing layer 5-2.

In the manufacturing process of FIG. 103 described above, when the inside of the seam portion 4 is not completely filled with the sealing layer 5 and the seam portion 4 has the empty space 4a, the configuration of FIG. 99 described above is obtained. In the manufacturing process of FIG. 102 described above, in a case where polishing and cleaning are performed so that the buried layer 3 remains on the chip 2, and then the sealing layer 5 is provided, the configuration of FIG. 95 described above is obtained. In the manufacturing process of FIG. 103, when the sealing layer 5-2 (metal layer) is provided instead of the sealing layer 5-3, the configuration of FIG. 96 described above is obtained.

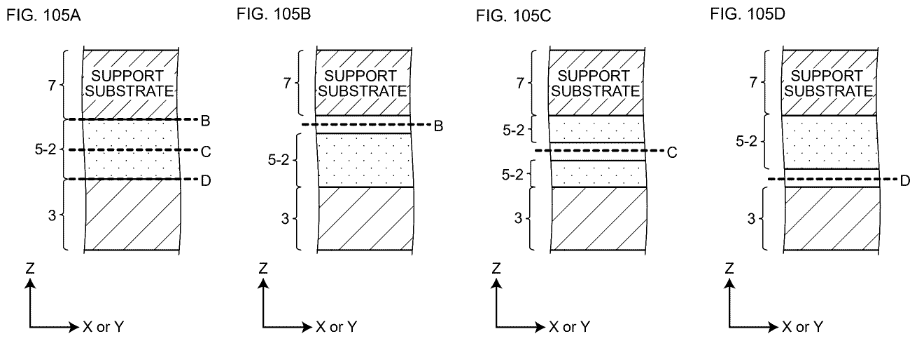

There may be several variations in the position of the bonding surface of the support substrate 7. Specifically, FIG. 105 (A) illustrates three types of bonding surfaces, that is, a bonding surface B, a bonding surface C, and a bonding surface D. The bonding surface B is located between the support substrate 7 and the sealing layer 5-2. The bonding surface C is located in the sealing layer 5-2. The bonding surface D is located between the sealing layer 5-2 and the buried layer 3.

FIGS. (B), (C), and 105 (D) schematically illustrate Z-axis direction exploded views of the support substrate 7, the sealing layer 5-2, and the buried layer 3 respectively in the bonding surface B, the bonding surface C, and the bonding surface D. A compound (silicide) is generated in the bonding process, and in this case, the configuration of FIG. 100 described above is obtained.

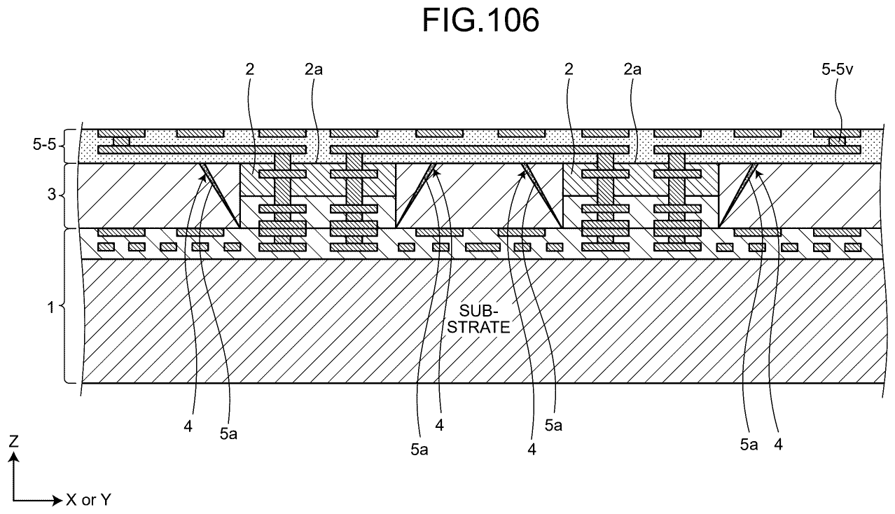

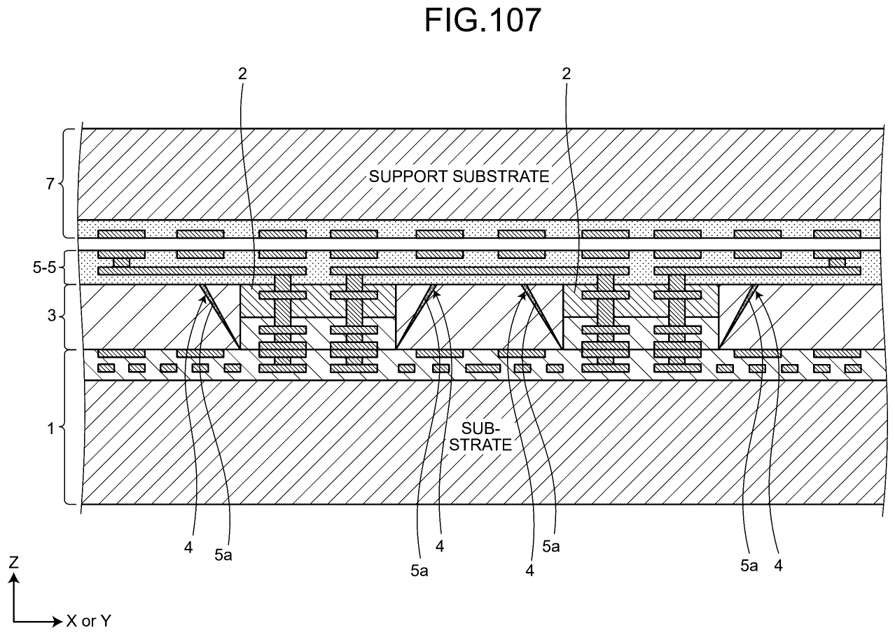

FIGS. 106 and 107 illustrate an example of a manufacturing method for obtaining the configuration of FIG. 101 described above. As a premise, it is assumed that the manufacturing process up to FIG. 102 described above is completed.

As illustrated in FIG. 106, a sealing layer 5-5 is provided so as to cover the buried layer 3, the seam portion 4, and the chip 2. As illustrated in FIG. 107, the configuration of FIG. 101 described above is obtained by bonding the support substrate 7 through the sealing layer 5-5.

### <Section Summary>

The light detection devices 100 according to the sixteenth to twenty-third embodiments described above are specified as follows, for example. As described with reference to FIGS. 94, 99, and the like, at least a part of the seam portion 4 is filled with a material (for example, the extension 5a) different from the material of the buried layer 3, and the sealing layer 5-2 is a layer having thermal conductivity higher than thermal conductivity of silicon (Si). Even with such a configuration, communication of the seam portion 4 to the outside can be suppressed. In addition, heat dissipation can be improved.

As described with reference to FIG. 95 and the like, the light detection device 100 may include the sealing layer 5 (first sealing layer) provided so as to cover the buried layer 3 and the seam portion 4 and the sealing layer 5-2 (second sealing layer) provided so as to cover the sealing layer 5, and the sealing layer 5-2 may have thermal conductivity higher than thermal conductivity of silicon (Si). Heat dissipation can be improved also with such a configuration.

As described with reference to FIG. 96 and the like, the sealing layer 5-3 may be a metal layer. Heat dissipation can be improved also with such a configuration.

As described with reference to FIG. 97 and the like, the sealing layer 5-4 may include: the insulating layer 50 (first portion) covering the buried layer 3 out of the buried layer 3 and the chip 2; and the sealing layer 5-2 (second portion) covering the chip 2 out of the buried layer 3 and the chip 2. The insulating layer 50 may have an insulating property, and the sealing layer 5-2 may have thermal conductivity higher than thermal conductivity of silicon (Si). Heat dissipation can be improved also with such a configuration.

As described with reference to FIG. 98 and the like, the light detection device 100 may include the additional layer 9 provided between the chip 2 and the buried layer 3, and the additional layer 9 may be a metal layer. Heat dissipation can be improved also with such a configuration.

As described with reference to FIG. 100 and the like, the light detection device 100 may include the compound layer 14 provided between the chip 2 and the sealing layer 5-2, and the compound layer 14 may be a silicide layer. Heat dissipation can be improved also with such a configuration.

As described with reference to FIG. 101 and the like, the sealing layer 5-5 may be a layer in which a metal structure (for example, the via 5-5v and the like) is provided in the insulator. Heat dissipation can be improved also with such a configuration. When the support substrate 7 is bonded, a wiring can also be formed on the bonding surface.

### 31. Twenty-Fourth Embodiment

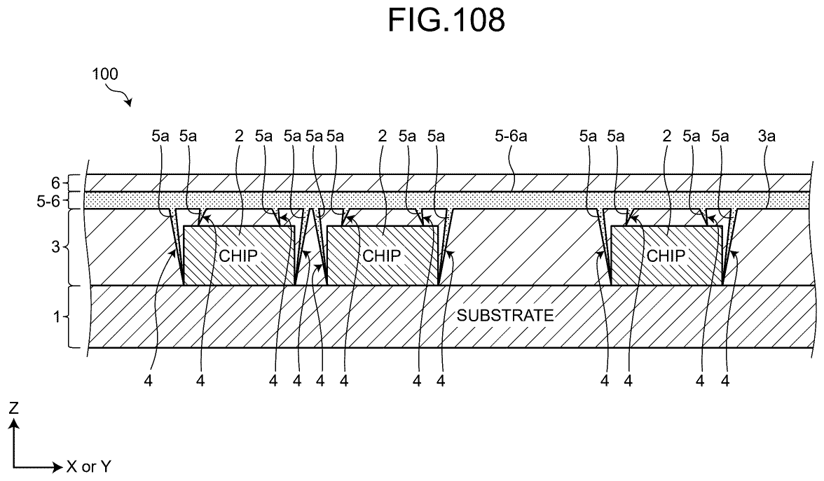

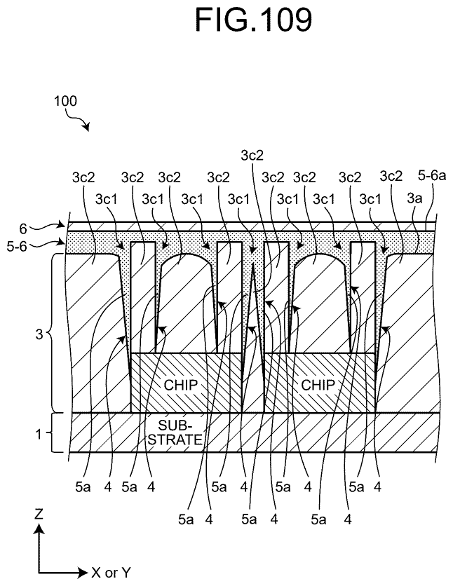

FIGS. 108 and 109 are diagrams illustrating an example of a schematic configuration of a light detection device according to a twenty-fourth embodiment. Note that illustration of the support substrate 7 is omitted, and the similar applies to the subsequent drawings. The light detection device 100 includes a sealing layer 5-6 instead of the sealing layer 5. The sealing layer 5-6 is a resin layer. Among the front surfaces of the sealing layer 5-6, a surface on the Z-axis positive direction side is denoted as a front surface 5-6a in the drawing.

FIG. 109 schematically illustrates an enlarged view of a portion including the chip 2, and the buried layer 3 and the sealing layer 5 located on the chip 2. The buried layer 3 has an uneven shape on the front surface 3a. Specifically, the front surface 3a of the buried layer 3 has a recess 3c1 and a protrusion 3c2. The recess 3c1 has a recessed shape recessed downward (in the Z-axis positive direction). The protrusion 3c2 has a protruding shape protruding upward (in Z-axis positive direction).

The sealing layer 5-6 is a resin layer provided so as to fill the recess 3c1 and cover the recess 3c1 and the protrusion 3c2. The resin layer may be an oxide layer or an organic layer. The oxide layer may be, for example, an oxide-based insulating film or an oxide-based bonding film. The organic layer may have heat resistance temperature of 400 °C or higher, for example. Examples of the material of such an organic layer include polyimide, siloxane, and silicone. Even when exposed to heat of about 400 °C in the subsequent step, the layer can withstand the heat.

The sealing layer 5-6 may be applied, onto the buried layer 3, in the form of a coating liquid at the time of manufacturing. This facilitates filling the recess 3c1 with the sealing layer 5-6, and facilitates extension of the sealing layer 5-6 into the seam portion 4. Since this is not a conformal deposition method, the front surface after application of the coating becomes a surface having a higher planarization than before application. In the example illustrated in FIG. 109, the front surface 5-6a of the sealing layer 5-6 is a planarized surface. That is, the shapes of the recess 3c1 and the protrusion 3c2 on the front surface 3a of the buried layer 3 are smoothed by the sealing layer 5-6, so as to obtain the front surface 5-6a being a planarized surface.

### <Example of Manufacturing Method>

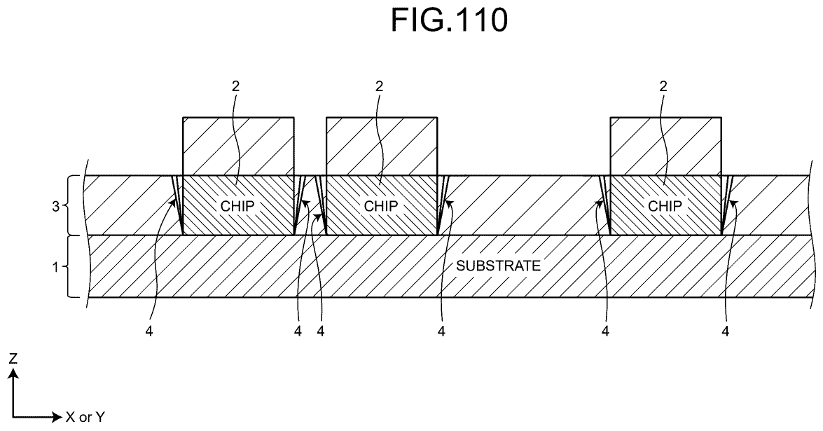

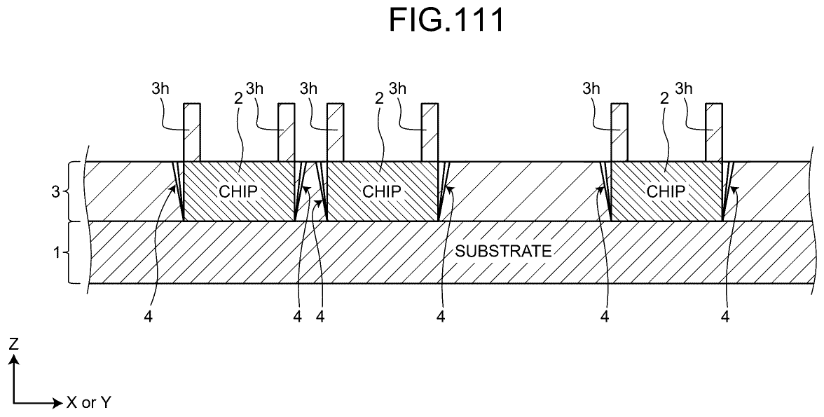

FIGS. 110 to 114 are diagrams illustrating an example of a method of manufacturing the light detection device. As illustrated in FIG. 110, the chip 2 is provided on the substrate 1, and the buried layer 3 is provided so as to cover the chip 2. A seam portion 4 occurs in the buried layer 3. As illustrated in FIG. 111, by a lithography process including dry etching or the like, the buried layer 3 on the chip 2 is removed except for the upper portions of the corners of the chip 2. The buried layer 3 remaining at the upper portion of the corner of the chip 2 is denoted as a corner portion 3h in the drawing. By leaving the corner portion 3h, it is possible to protect the outer portion of the chip 2 and to prevent the buried layer 3 on the outer side of the chip 2 from coming off.

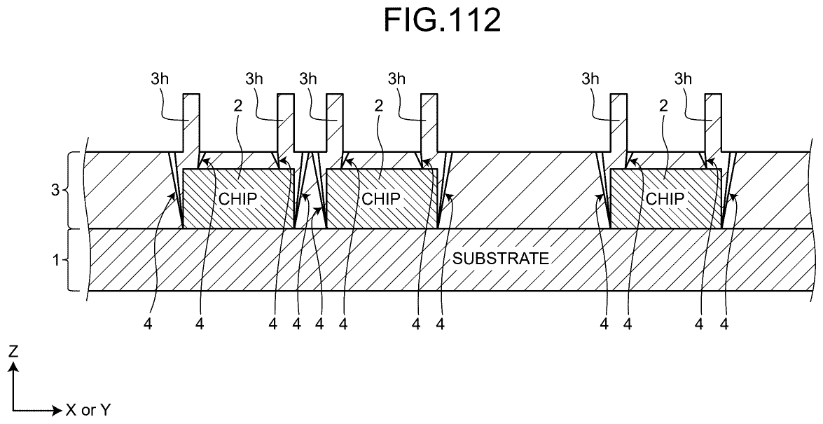

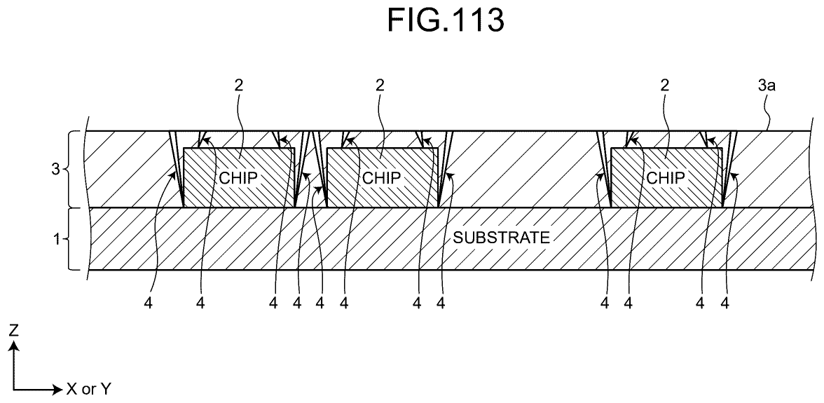

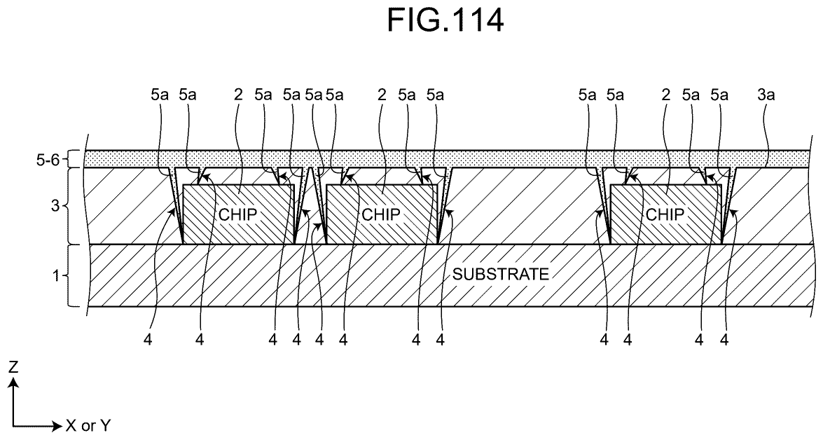

As illustrated in FIG. 112, the buried layer 3 is further provided. In this example, the seam portion 4 also occurs in the buried layer 3 at the upper portion of the chip 2. As illustrated in FIG. 113, the corner portion 3h is removed by CMP. The CMP here is different from normal CMP in the composition and the like of the slurry, and ends when the layer is planarized to some extent (self-stop CMP). As illustrated in FIG. 114, a sealing layer 5-6 is provided so as to cover the buried layer 3 and the seam portion 4. The sealing layer 5-6 is provided by applying the material (resin material). At this time, the material of the sealing layer 5-6 extends into the Seam portion 4, and the extended portion is to be the extension 5a of the sealing layer 5-6. In addition, the recess 3c1 on the front surface 3a of the buried layer 3 described above with reference to FIG. 109 is filled with the sealing layer 5-6. Thereafter, by providing an auxiliary layer 6 so as to cover the sealing layer 5, the configurations of FIGS. 108 and 109 described above can be obtained.

In the above manufacturing method, the lithography and the subsequent process of depositing the buried layer 3 (the processes of FIGS. 111 and 112) may be omitted.

### <Example of Manufacturing Method>

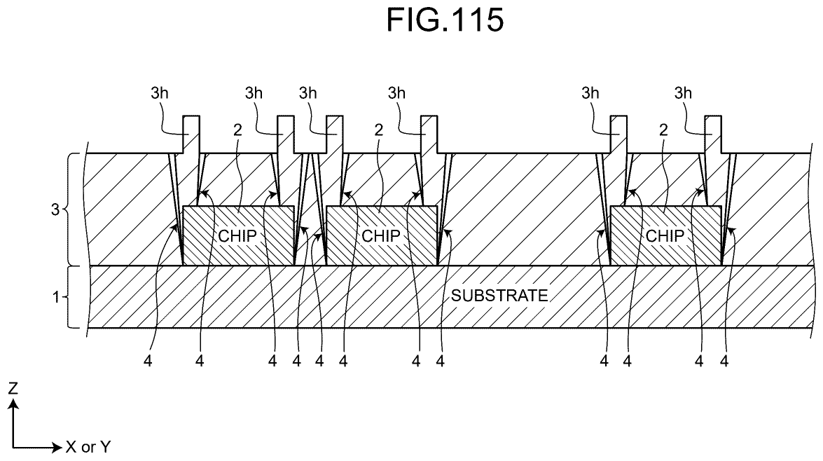

FIGS. 115 to 119 are diagrams illustrating an example of a method of manufacturing the light detection device. Compared to the previously described manufacturing method of FIGS. 110 to 114, a process of CMP is added before providing the sealing layer 5-6. As a premise, it is assumed that the manufacturing process of FIG. 111 described above is completed.

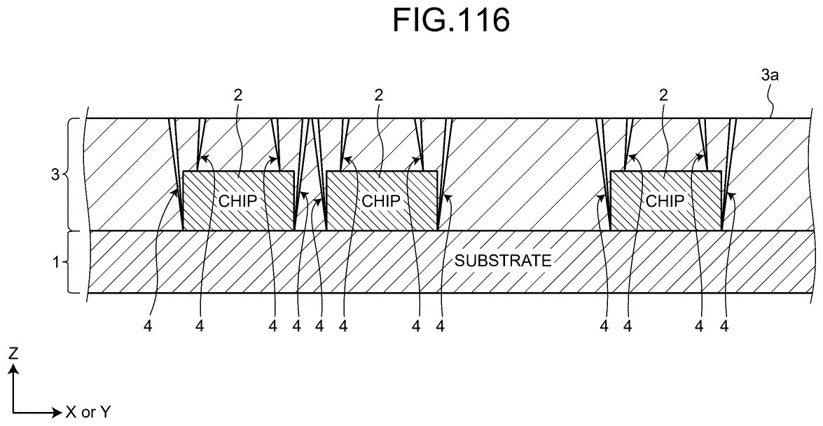

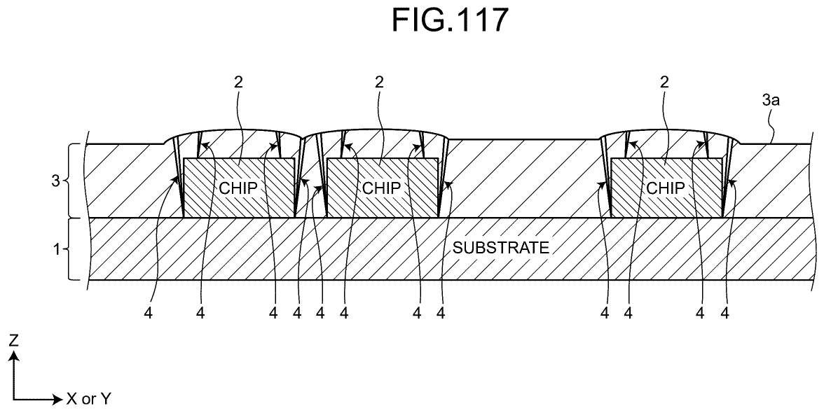

As illustrated in FIG. 115, the buried layer 3 is further provided. The thickness (length in the Z-axis direction) of the buried layer 3 added here may be greater than the thickness of the buried layer 3 in FIG. 112 described above. As illustrated in FIG. 116, the corner portion 3h is removed by self-stop CMP. As illustrated in FIG. 117, the top of the buried layer 3 is polished and cleaned by CMP. In this CMP, the buried layer 3 in a portion corresponding to the corner of the chip 2 has roundness (is rounded).

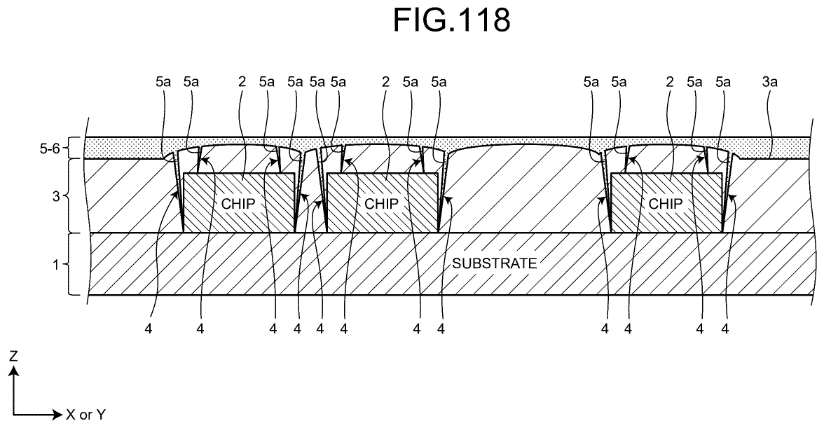

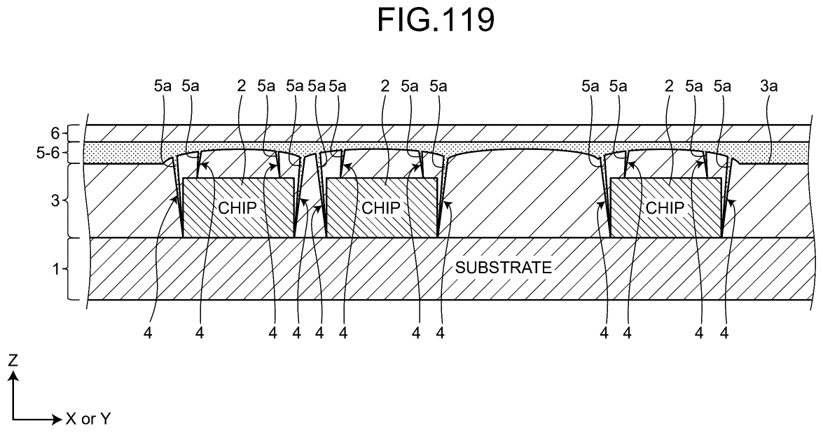

As illustrated in FIG. 118, a sealing layer 5-6 is provided so as to cover the buried layer 3 and the seam portion 4. As illustrated in FIG. 119, the auxiliary layer 6 is provided so as to cover the sealing layer 5. Except that the buried layer 3 at a portion corresponding to the corner of the chip 2 is rounded, the configuration similar to the configurations of FIGS. 108 and 109 described above can be obtained.

In the above manufacturing method, the lithography, the subsequent deposition of the buried layer 3, and the self-stop CMP process (processes of FIGS. 111, 115 and 116) may be omitted.

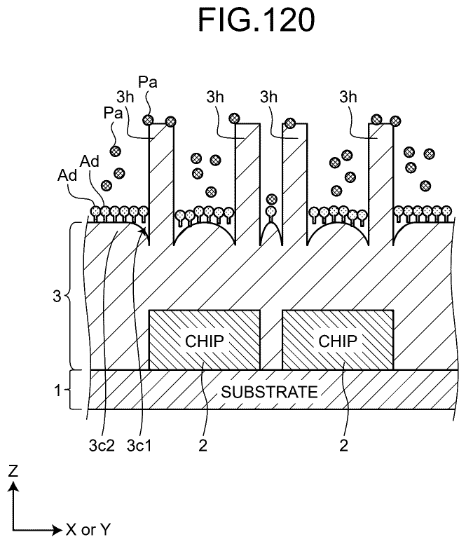

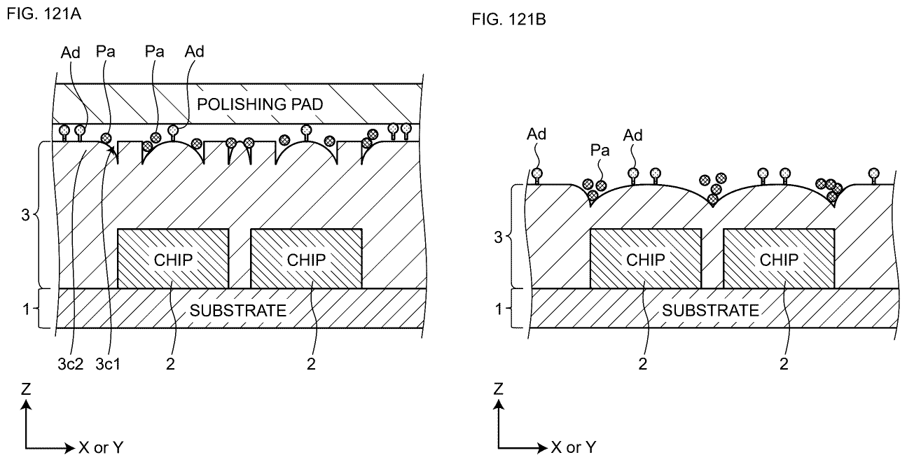

When the top of the buried layer 3 is polished by CMP, the front surface 3a of the buried layer 3 can have a recess 3c1 and a protrusion 3c2. This will be described with reference to FIGS. 120 and 121.

FIGS. 120 and 121 are diagrams illustrating an example of CMP. Illustration of the seam portion 4 is omitted to facilitate understanding.

FIG. 120 schematically illustrates the Self-stop CMP performed in FIGS. 113 and 116 described above. In this example, the upper portion of the buried layer 3 (for example, an oxide film such as SiO2) is polished using the slurry containing ceria abrasives Pa and additive Ad, so as to remove the corner portion 3h. Complete planarization may be difficult, and in this example, the buried layer 3 has the recess 3c1 and the protrusion 3c2. For example, a remaining portion (corner residue) of the corner portion 3h remaining without being scraped, a slit generated between the corner residues, the seam portion 4, and the like can be the recess 3c1 and the protrusion 3c2.

FIG. 121 schematically illustrates CMP performed in FIG. 117 described above. As illustrated in (A) of FIG. 121, the top of the buried layer 3 is polished using a polishing pad. The ceria abrasives Pa are present in liberated states, not adsorbed to the buried layer 3. As illustrated in FIG. 121 (B), slurry accumulation occurs in the recess 3c1 and the protrusion 3c2 of the buried layer 3 located above the corner of the chip 2, increasing local stress and allowing polishing to proceed. Polishing of the flat portion at the tip of the protrusion 3c2 having a relatively wide width (length in the XY plane direction) is hindered by the effect of the additive Ad.

For the reasons described above, for example, the buried layer 3 grows the recess 3c1 and the protrusion 3c2 in the manufacturing process. By providing the sealing layer 5-6 (resin layer) so as to fill the recess 3c1 and cover the recess 3c1 and the protrusion 3c2, the recess 3c1 and the protrusion 3c2 are smoothed to obtain the front surface 5-6a being a planarized surface.

### 32. Twenty-Fifth Embodiment

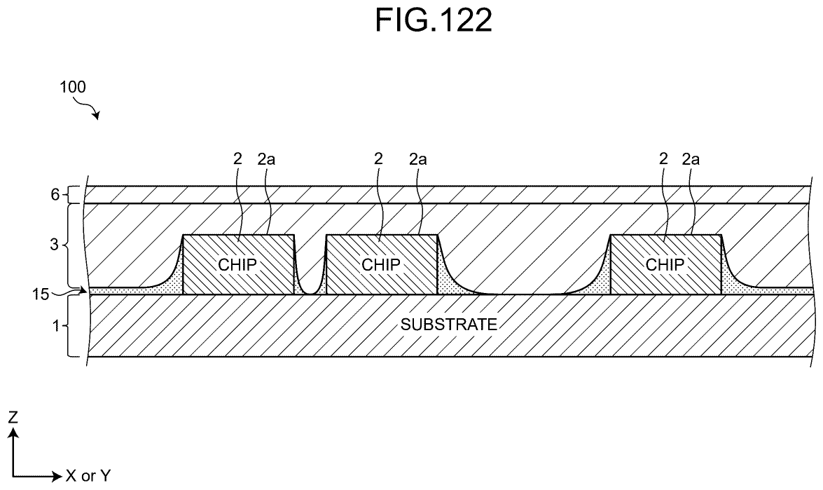

FIG. 122 is a diagram illustrating an example of a schematic configuration of a light detection device according to a twenty-fifth embodiment. The light detection device 100 includes a resin layer 15 instead of the sealing layer 5. Similarly to the sealing layer 5-6 described above, the resin layer 15 is an oxide layer or an organic layer. The material of the resin layer 15 may be the same as the material of the sealing layer 5-6.

The resin layer 15 is provided between the chip 2 and the buried layer 3. In this example, the resin layer 15 is provided so as to cover the substrate 1 and the side surface of the chip 2. However, the resin layer 15 may cover not only the side surface of the chip 2 but also the front surface 2a.

By covering the chip 2 with the resin layer 15, the shape of the portion of the chip 2, for example, the shape of the stepped portion formed with the substrate 1 becomes gentle. Accordingly, the seam portion 4 is less likely to occur. Even if the seam portion 4 occurs, the auxiliary layer 6 functions as a sealing layer covering the buried layer 3 and the seam portion 4, making it possible to suppress communication of the seam portion 4 to the outside as described above.

### <Example of Manufacturing Method>

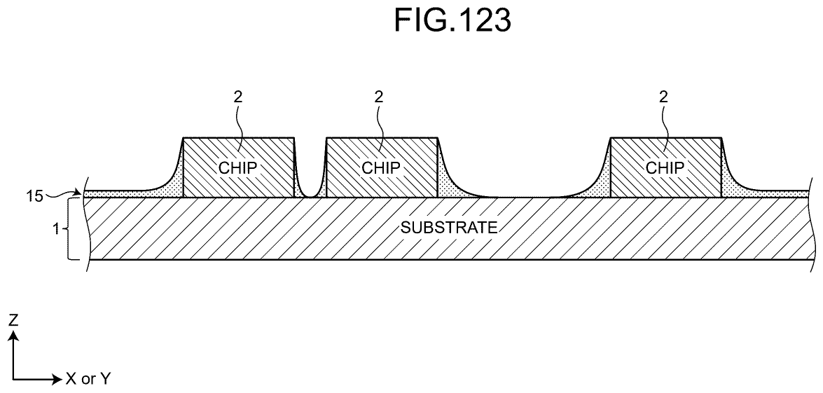

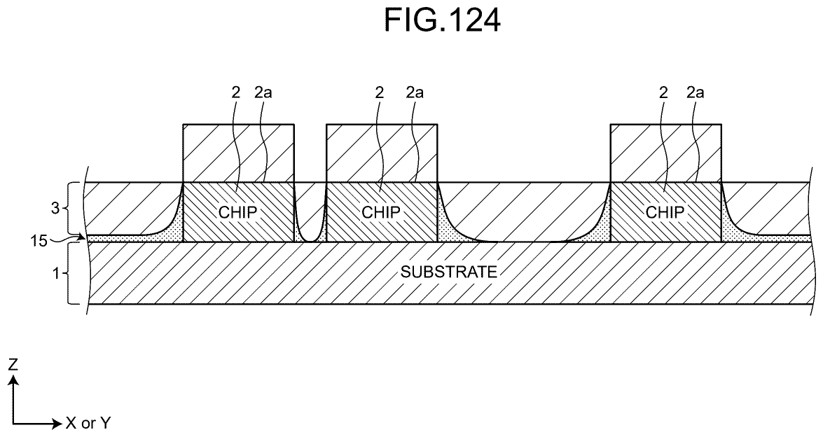

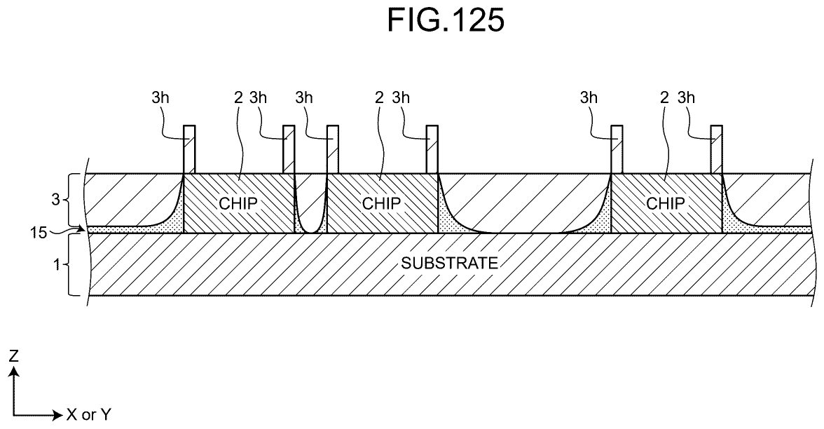

FIGS. 123 to 128 are diagrams illustrating an example of a method of manufacturing the light detection device. As illustrated in FIG. 123, the chip 2 is provided on the substrate 1, and the resin layer 15 is provided so as to cover the chip 2. As illustrated in FIG. 124, the buried layer 3 is provided so as to cover the resin layer 15 (also the front surface 2a of the chip 2 in this example). In this example, no seam portion 4 occurs in the buried layer 3. As illustrated in FIG. 125, the buried layer 3 is removed so as to leave the corner portion 3h by a lithography process including dry etching or the like.

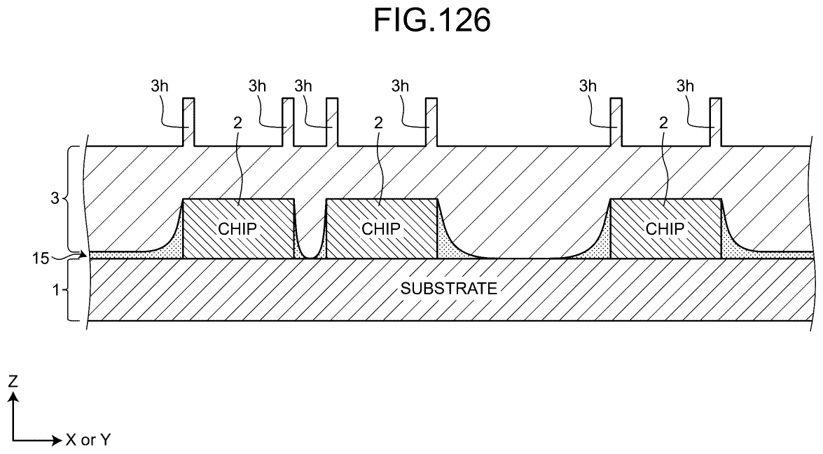

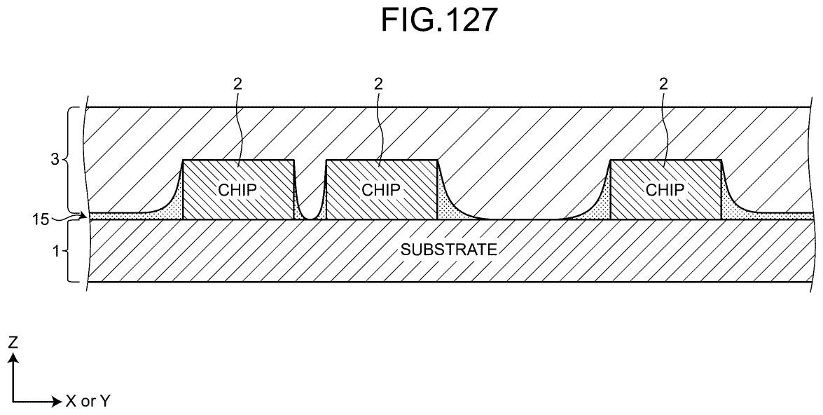

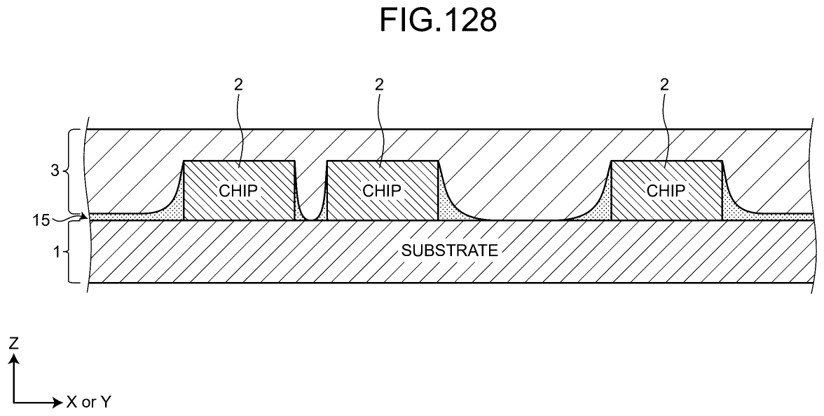

As illustrated in FIG. 126, a buried layer 3 is further provided. As illustrated in FIG. 127, the corner portion 3h is removed by CMP (self-stop CMP). As illustrated in FIG. 128, the top of the buried layer 3 is polished and cleaned by CMP. Thereafter, by providing the auxiliary layer 6 so as to cover the buried layer 3, the configuration of FIG. 122 described above is obtained.

In the above manufacturing method, the lithography, the subsequent deposition of the buried layer 3, and the self-stop CMP process (processes of FIGS. 125 to 127) may be omitted.

### <Section Summary>

The light detection devices 100 according to the twenty-fourth embodiment and the twenty-fifth embodiment described above are specified as follows, for example. As described with reference to FIGS. 108 and 109 and the like, the sealing layer 5-6 may be a resin layer (for example, an oxide layer or an organic layer). The front surface 3a of the buried layer 3 may have the recess 3c1, and the sealing layer 5-6 may be provided so as to fill the recess 3c1. The front surface 5-6a of the sealing layer 5-6 may be a planarized surface. This makes it possible to smooth the recess 3c1 of the front surface 3a of the buried layer 3, so as to be able to obtain a planarized surface (front surface 5-6a).

The sealing layer 5-6 which is an organic layer may have heat resistance temperature of 400 °C or higher. The material of the organic layer may contain at least one of polyimide, siloxane, and silicone. This makes it possible to withstand heat even when exposed to heat of about 400 °C in a subsequent step, for example.

As described with reference to FIG. 122 and the like, the light detection device 100 may include the resin layer 15 (for example, an oxide layer or an organic layer) provided between the chip 2 and the buried layer 3. This makes it possible to suppress the occurrence of the seam portion 4.

The resin layer 15 may have characteristics similar to the characteristics of the sealing layer 5-6 described above. For example, the resin layer 15 as an organic layer may have heat resistance temperature of 400 °C or higher. The material of the organic layer may contain at least one of polyimide, siloxane, and silicone. This makes it possible to withstand heat even when exposed to heat of about 400 °C in a subsequent step, for example.

The embodiments of the present disclosure have been described above. However, the technical scope of the present disclosure is not limited to the above-described embodiments, and various modifications can be made without departing from the scope of the present disclosure. Moreover, it is allowable to combine the components across different embodiments and modifications as appropriate.

Note that the present technology can also have the following configurations.
(1) A light detection device comprising:
a substrate including a light detection element;
a chip provided for the substrate;
a buried layer provided to cover the chip;
a seam portion occurring in the buried layer and extending to a front surface of the buried layer; and
a sealing layer provided to cover the buried layer and the seam portion.
(2) The light detection device according to (1), further comprising
a support substrate located on a side opposite to the substrate across the sealing layer and configured to directly or indirectly support the sealing layer.
(3) The light detection device according to (1) or (2),
wherein at least a part of the seam portion is an empty space.
(4) The light detection device according to any one of (1) to (3),
wherein the sealing layer includes an extension extending into the seam portion so as to fill at least a part of the seam portion.
(5) The light detection device according to any one of (1) to (4),
wherein a material of the sealing layer includes a low-permeability material.
(6) The light detection device according to any one of (1) to (5),
wherein a material of the sealing layer includes a low Young's modulus material.
(7) The light detection device according to any one of (1) to (6), further comprising
a side wall provided to cover a side surface of the chip.
(8) The light detection device according to any one of (1) to (7),
wherein the chip includes a first chip and a second chip provided separated from each other,
the seam portion includes a first seam portion occurring due to the first chip and a second seam portion occurring due to the second chip, and
the first seam portion and the second seam portion are connected to each other.
(9) The light detection device according to any one of (1) to (8), further comprising
an additional layer provided between the chip and the buried layer.
(10) The light detection device according to any one of (1) to (9), further comprising
an auxiliary layer provided so as to cover the sealing layer.
(11) The light detection device according to (10),
wherein the auxiliary layer has a stacked structure.
(12) The light detection device according to any one of (1) to (11),
wherein the chip includes at least one of a logic chip, a memory chip, and an artificial intelligence (AI) chip.
(13) The light detection device according to any one of (1) to (12),
wherein the light detection device is an imaging device configured to include a plurality of pixels.
(14) The light detection device according to (13), further comprising:
a filter layer provided on a side opposite to the chip and the buried layer across the substrate; and
a lens layer provided on a side opposite to the substrate across the filter layer.
(15) The light detection device according to any one of (1) to (14), further comprising
an additional substrate provided between the substrate and the buried layer.
(16) The light detection device according to any one of (1) to (15),
wherein the chip includes two chips disposed adjacent to each other at an interval, and
the buried layer includes a wiring line provided between the two chips.
(17) The light detection device according to any one of (1) to (16), further comprising:
a support substrate located on a side opposite to the substrate across the sealing layer and configured to directly or indirectly support the sealing layer; and
a penetrating via configured to penetrate the buried layer, the sealing layer, and the support substrate.
(18) The light detection device according to any one of (1) to (17),
wherein the chip includes:
a first chip; and
a second chip having a thickness greater than a thickness of the first chip,
the seam portion includes:
a first seam portion extending from the first chip toward a front surface of the buried layer; and
a second seam portion extending from the second chip toward the front surface of the buried layer, and
the second seam portion extends closer to the front surface of the buried layer, compared with the first seam portion.
(19) The light detection device according to any one of (1) to (18),
wherein the chip includes:
a first chip; and
a second chip and a third chip stacked in order,
the second chip and the third chip have, as a whole, a thickness greater than a thickness of the first chip,
the seam portion includes:
a first seam portion extending from the first chip toward a front surface of the buried layer; and
a second seam portion extending from the second chip toward the front surface of the buried layer, and
the second seam portion extends closer to the front surface of the buried layer, compared with the first seam portion.
(20) The light detection device according to (18) or (19),
wherein the sealing layer includes an extension extending into the second seam portion so as to fill at least a part of the second seam portion.
(21) The light detection device according to any one of (18) to (20),
wherein the first seam portion does not reach the front surface of the buried layer, and
the second seam portion reaches the front surface of the buried layer.
(22) The light detection device according to any one of (1) to (21),
wherein the chip includes a lower chip and an upper chip located to be aligned in a height direction,
the light detection device further comprises a bonding layer provided between the lower chip and the upper chip,
the buried layer includes:
a lower buried layer provided so as to cover a side surface of the lower chip; and
an upper buried layer provided so as to cover the upper chip and the bonding layer,
the seam portion includes:
a lower seam portion occurring in the lower buried layer and extending to a front surface of the lower buried layer; and
an upper seam portion occurring in the upper buried layer and extending to a front surface of the upper buried layer,
the bonding layer is provided so as to cover the lower buried layer and the lower seam portion, and
the sealing layer is provided so as to cover the upper buried layer and the upper seam portion.
(23) The light detection device according to (22),
wherein the chip further includes a lower chip and a dummy chip provided on opposite sides to each other across the bonding layer, and
the upper buried layer is provided so as to cover the upper chip, the dummy chip, and the bonding layer.
(24) The light detection device according to any one of (1) to (23),
wherein the sealing layer includes:
a first portion covering the seam portion; and
a second portion not covering the seam portion, and
a back surface of the first portion is located below a back surface of the second portion.
(25) The light detection device according to (24),
wherein a front surface of the first portion is located at a same height as a front surface of the second portion.
(26) The light detection device according to (24), further comprising
an auxiliary layer provided so as to cover the sealing layer,
wherein a front surface of the second portion is located above a front surface of the first portion, and
a front surface of the auxiliary layer is a planarized surface.
(27) The light detection device according to any one of (1) to (26),
wherein the sealing layer has a stacked structure including a stack of a plurality of layers.
(28) The light detection device according to (27),
wherein the plurality of layers of the sealing layer includes an inorganic layer and an organic layer.
(29) The light detection device according to any one of (1) to (28), further comprising
a dummy chip disposed to be adjacent to the chip at an interval,
wherein the buried layer is provided so as to cover the chip and the dummy chip, and
the seam portion extends to the front surface of the buried layer at a portion between the chip and the dummy chip.
(30) The light detection device according to (29),
wherein the seam portion extends in a height direction of the chip and the dummy chip.
(31) The light detection device according to (29) or (30),
wherein the chip includes two chips provided separated from each other, and
the dummy chip is provided between the two chips.
(32) The light detection device according to any one of (1) to (31),
wherein the chip has a shape having a width decreasing toward a front surface of the chip.
(33) The light detection device according to (32),
wherein an edge portion of the chip has a tapered shape or a round shape on the front surface of the chip.
(34) The light detection device according to (32) or (33),
wherein the seam portion extends in a height direction of the chip.
(35) The light detection device according to any one of (1) to (34),
wherein the seam portion has a shape having a width changing with a growth of the seam portion in an extending direction.
(36) The light detection device according to (35),
wherein the seam portion includes:
a central portion located at a center in the extending direction of the seam portion; and
an end portion located at an end in the extending direction of the seam portion, and
the central portion has a width greater than a width of the end portion.
(37) The light detection device according to any one of (29) to (36),
wherein the dummy chip extends so as to face a side surface of the chip in plan view, and the dummy chip has a length of a half or more of a length of the side surface of the chip facing the dummy chip in an extending direction of the dummy chip.
(38) The light detection device according to any one of (29) to (37),
wherein the dummy chip is disposed so as to sandwich the chip in plan view.
(39) The light detection device according to any one of (29) to (38),
wherein the dummy chip includes two or more dummy chips.
(40) The light detection device according to any one of (29) to (39),
wherein a material of the dummy chip includes a same material as a material of the chip.
(41) The light detection device according to any one of (29) to (40),
wherein the dummy chip has a height equal to a height of the chip.
(42) The light detection device according to any one of (29) to (41),
wherein the chip includes two or more chips.
(43) The light detection device according to any one of (29) to (42),
wherein the dummy chip continuously extends so as to surround the chip in plan view.
(44) The light detection device according to any one of (29) to (43),
wherein the dummy chip has a side surface exposed from the buried layer when the light detection device is viewed from a side.
(45) The light detection device according to any one of (1) to (44),
wherein at least a part of the seam portion is filled with a material different from a material of the buried layer, and
the sealing layer is a layer having thermal conductivity higher than thermal conductivity of silicon.
(46) The light detection device according to (45), further comprising:
a first sealing layer provided so as to cover the buried layer and the seam portion; and
a second sealing layer provided so as to cover the first sealing layer,
wherein the second sealing layer has thermal conductivity higher than thermal conductivity of silicon.
(47) The light detection device according to (45) or (46),
wherein the sealing layer is a metal layer.
(48) The light detection device according to any one of (45) to (47),
wherein the sealing layer includes:
a first portion covering the buried layer, out of the buried layer and the chip; and
a second portion covering the chip, out of the buried layer and the chip,
the first portion has an insulating property, and
the second portion has thermal conductivity higher than thermal conductivity of silicon.
(49) The light detection device according to any one of (45) to (48), further comprising
an additional layer provided between the chip and the buried layer,
wherein the additional layer is a metal layer.
(50) The light detection device according to any one of (45) to (49), further comprising
a compound layer provided between the chip and the sealing layer,
wherein the compound layer is a silicide layer.
(51) The light detection device according to any one of (45) to (50),
wherein the sealing layer is a layer having a metal structure provided in an insulator.
(52) The light detection device according to any one of (1) to (51),
wherein the sealing layer is a resin layer.
(53) The light detection device according to (52),
wherein a front surface of the buried layer has a recess, and
the sealing layer is provided so as to fill the recess.
(54) The light detection device according to (52) or (53),
wherein a front surface of the sealing layer is a planarized surface.
(55) The light detection device according to any one of (52) to (54),
wherein the resin layer is an oxide layer or an organic layer.
(56) The light detection device according to (55),
wherein the organic layer has heat resistance temperature of 400 °C or higher.
(57) The light detection device according to (56),
wherein a material of the organic layer includes at least one of polyimide, siloxane, and silicone.
(58) The light detection device according to any one of (1) to (57), further comprising
a resin layer provided between the chip and the buried layer.
(59) The light detection device according to (58),
wherein the resin layer is an oxide layer or an organic layer.
(60) The light detection device according to (59),
wherein the organic layer has heat resistance temperature of 400 °C or higher.
(61) The light detection device according to (60),
wherein a material of the organic layer includes at least one of polyimide, siloxane, and silicone.

### REFERENCE SIGNS LIST

100 LIGHT DETECTION DEVICE
1 SUBSTRATE
1a FRONT SURFACE
1b BACK SURFACE
1p LIGHT DETECTION ELEMENT
2 CHIP
2a FRONT SURFACE
2b MOUNTING SURFACE
2c SIDE SURFACE
2d SIDE SURFACE
2e SIDE SURFACE
2f SIDE SURFACE
2v PENETRATING VIA
21 CENTRAL PORTION
22 EDGE PORTION
2D DUMMY CHIP
3 BURIED LAYER
3a FRONT SURFACE
3b BACK SURFACE
3h CORNER PORTION
3v PENETRATING VIA
3c1 RECESS
3c2 PROTRUSION
4 SEAM PORTION
41 END PORTION
42 CENTRAL PORTION
43 END PORTION
4a EMPTY SPACE
5 SEALING LAYER
5a EXTENSION
51 FIRST PORTION
51a FRONT SURFACE
51b BACK SURFACE
52 SECOND PORTION
52a FRONT SURFACE
52b BACK SURFACE
53 INORGANIC LAYER
54 ORGANIC LAYER
5-2 SEALING LAYER
5-3 SEALING LAYER
5-4 SEALING LAYER
5-5 SEALING LAYER
5-5v VIA
5-6 SEALING LAYER
6 AUXILIARY LAYER
61 LAYER
62 LAYER
63 LAYER
6a FRONT SURFACE
7 SUPPORT SUBSTRATE
7a FRONT SURFACE
7b BACK SURFACE
8 SIDE WALL
9 ADDITIONAL LAYER
L WIRING LINE
10 FILTER LAYER
11 LENS LAYER
11a LENS
12 ADDITIONAL SUBSTRATE
12a FRONT SURFACE
12b BACK SURFACE
12v PENETRATING VIA
V PENETRATING VIA
13 BONDING LAYER
14 COMPOUND LAYER
15 RESIN LAYER
200 WAFER
Ad ADDITIVE
Pa CERIA ABRASIVE
SL SCRIBE LINE

1. A light detection device comprising:
a substrate including a light detection element;
a chip provided for the substrate;
a buried layer provided to cover the chip;
a seam portion occurring in the buried layer and extending to a front surface of the buried layer; and
a sealing layer provided to cover the buried layer and the seam portion.

2. The light detection device according to claim 1, further comprising
a support substrate located on a side opposite to the substrate across the sealing layer and configured to directly or indirectly support the sealing layer.

3. The light detection device according to claim 1,
wherein at least a part of the seam portion is an empty space.

4. The light detection device according to claim 1,
wherein the sealing layer includes an extension extending into the seam portion so as to fill at least a part of the seam portion.

5. The light detection device according to claim 1,
wherein a material of the sealing layer includes a low-permeability material.

6. The light detection device according to claim 1,
wherein a material of the sealing layer includes a low Young's modulus material.

7. The light detection device according to claim 1, further comprising
a side wall provided to cover a side surface of the chip.

8. The light detection device according to claim 1,
wherein the chip includes a first chip and a second chip provided separated from each other,
the seam portion includes a first seam portion occurring due to the first chip and a second seam portion occurring due to the second chip, and
the first seam portion and the second seam portion are connected to each other.

9. The light detection device according to claim 1, further comprising
an additional layer provided between the chip and the buried layer.

10. The light detection device according to claim 1, further comprising
an auxiliary layer provided so as to cover the sealing layer.

11. The light detection device according to claim 10,
wherein the auxiliary layer has a stacked structure.

12. The light detection device according to claim 1,
wherein the chip includes at least one of a logic chip, a memory chip, and an artificial intelligence (AI) chip.

13. The light detection device according to claim 1,
wherein the light detection device is an imaging device configured to include a plurality of pixels.

14. The light detection device according to claim 13, further comprising:
a filter layer provided on a side opposite to the chip and the buried layer across the substrate; and
a lens layer provided on a side opposite to the substrate across the filter layer.

15. The light detection device according to claim 1, further comprising
an additional substrate provided between the substrate and the buried layer.

16. The light detection device according to claim 1,
wherein the chip includes two chips disposed adjacent to each other at an interval, and
the buried layer includes a wiring line provided between the two chips.

17. The light detection device according to claim 1, further comprising:
a support substrate located on a side opposite to the substrate across the sealing layer and configured to directly or indirectly support the sealing layer; and
a penetrating via configured to penetrate the buried layer, the sealing layer, and the support substrate.

18. The light detection device according to claim 1,
wherein the chip includes:
a first chip; and
a second chip having a thickness greater than a thickness of the first chip,
the seam portion includes:
a first seam portion extending from the first chip toward a front surface of the buried layer; and
a second seam portion extending from the second chip toward the front surface of the buried layer, and
the second seam portion extends closer to the front surface of the buried layer, compared with the first seam portion.

19. The light detection device according to claim 1,
wherein the chip includes:
a first chip; and
a second chip and a third chip stacked in order,
the second chip and the third chip have, as a whole, a thickness greater than a thickness of the first chip,
the seam portion includes:
a first seam portion extending from the first chip toward a front surface of the buried layer; and
a second seam portion extending from the second chip toward the front surface of the buried layer, and
the second seam portion extends closer to the front surface of the buried layer, compared with the first seam portion.

20. The light detection device according to claim 18,
wherein the sealing layer includes an extension extending into the second seam portion so as to fill at least a part of the second seam portion.

21. The light detection device according to claim 18,
wherein the first seam portion does not reach the front surface of the buried layer, and
the second seam portion reaches the front surface of the buried layer.

22. The light detection device according to claim 1,
wherein the chip includes a lower chip and an upper chip located to be aligned in a height direction,
the light detection device further comprises a bonding layer provided between the lower chip and the upper chip,
the buried layer includes:
a lower buried layer provided so as to cover a side surface of the lower chip; and
an upper buried layer provided so as to cover the upper chip and the bonding layer,
the seam portion includes:
a lower seam portion occurring in the lower buried layer and extending to a front surface of the lower buried layer; and
an upper seam portion occurring in the upper buried layer and extending to a front surface of the upper buried layer,
the bonding layer is provided so as to cover the lower buried layer and the lower seam portion, and
the sealing layer is provided so as to cover the upper buried layer and the upper seam portion.

23. The light detection device according to claim 22,
wherein the chip further includes a lower chip and a dummy chip provided on opposite sides to each other across the bonding layer, and
the upper buried layer is provided so as to cover the upper chip, the dummy chip, and the bonding layer.

24. The light detection device according to claim 1,
wherein the sealing layer includes:
a first portion covering the seam portion; and
a second portion not covering the seam portion, and
a back surface of the first portion is located below a back surface of the second portion.

25. The light detection device according to claim 24,
wherein a front surface of the first portion is located at a same height as a front surface of the second portion.

26. The light detection device according to claim 24, further comprising
an auxiliary layer provided so as to cover the sealing layer,
wherein a front surface of the second portion is located above a front surface of the first portion, and
a front surface of the auxiliary layer is a planarized surface.

27. The light detection device according to claim 1,
wherein the sealing layer has a stacked structure including a stack of a plurality of layers.

28. The light detection device according to claim 27,
wherein the plurality of layers of the sealing layer includes an inorganic layer and an organic layer.

29. The light detection device according to claim 1, further comprising
a dummy chip disposed to be adjacent to the chip at an interval,
wherein the buried layer is provided so as to cover the chip and the dummy chip, and
the seam portion extends to the front surface of the buried layer at a portion between the chip and the dummy chip.

30. The light detection device according to claim 29,
wherein the seam portion extends in a height direction of the chip and the dummy chip.

31. The light detection device according to claim 29,
wherein the chip includes two chips provided separated from each other, and
the dummy chip is provided between the two chips.

32. The light detection device according to claim 1,
wherein the chip has a shape having a width decreasing toward a front surface of the chip.

33. The light detection device according to claim 32,
wherein an edge portion of the chip has a tapered shape or a round shape on the front surface of the chip.

34. The light detection device according to claim 32,
wherein the seam portion extends in a height direction of the chip.

35. The light detection device according to claim 1,
wherein the seam portion has a shape having a width changing with a growth of the seam portion in an extending direction.

36. The light detection device according to claim 35,
wherein the seam portion includes:
a central portion located at a center in the extending direction of the seam portion; and
an end portion located at an end in the extending direction of the seam portion, and
the central portion has a width greater than a width of the end portion.

37. The light detection device according to claim 29,
wherein the dummy chip extends so as to face a side surface of the chip in plan view, and the dummy chip has a length of a half or more of a length of the side surface of the chip facing the dummy chip in an extending direction of the dummy chip.

38. The light detection device according to claim 29,
wherein the dummy chip is disposed so as to sandwich the chip in plan view.

39. The light detection device according to claim 29,
wherein the dummy chip includes two or more dummy chips.

40. The light detection device according to claim 29,
wherein a material of the dummy chip includes a same material as a material of the chip.

41. The light detection device according to claim 29,
wherein the dummy chip has a height equal to a height of the chip.

42. The light detection device according to claim 29,
wherein the chip includes two or more chips.

43. The light detection device according to claim 29,
wherein the dummy chip continuously extends so as to surround the chip in plan view.

44. The light detection device according to claim 29,
wherein the dummy chip has a side surface exposed from the buried layer when the light detection device is viewed from a side.

45. The light detection device according to claim 1,
wherein at least a part of the seam portion is filled with a material different from a material of the buried layer, and
the sealing layer is a layer having thermal conductivity higher than thermal conductivity of silicon.

46. The light detection device according to claim 45, further comprising:
a first sealing layer provided so as to cover the buried layer and the seam portion; and
a second sealing layer provided so as to cover the first sealing layer,
wherein the second sealing layer has thermal conductivity higher than thermal conductivity of silicon.

47. The light detection device according to claim 45,
wherein the sealing layer is a metal layer.

48. The light detection device according to claim 45,
wherein the sealing layer includes:
a first portion covering the buried layer, out of the buried layer and the chip; and
a second portion covering the chip, out of the buried layer and the chip,
the first portion has an insulating property, and
the second portion has thermal conductivity higher than thermal conductivity of silicon.

49. The light detection device according to claim 45, further comprising
an additional layer provided between the chip and the buried layer,
wherein the additional layer is a metal layer.

50. The light detection device according to claim 45, further comprising
a compound layer provided between the chip and the sealing layer,
wherein the compound layer is a silicide layer.

51. The light detection device according to claim 45,
wherein the sealing layer is a layer having a metal Structure provided in an insulator.

52. The light detection device according to claim 1,
wherein the sealing layer is a resin layer.

53. The light detection device according to claim 52,
wherein a front surface of the buried layer has a recess, and
the sealing layer is provided so as to fill the recess.

54. The light detection device according to claim 52,
wherein a front surface of the sealing layer is a planarized surface.

55. The light detection device according to claim 52,
wherein the resin layer is an oxide layer or an organic layer.

56. The light detection device according to claim 55,
wherein the organic layer has heat resistance temperature of 400 °C or higher.

57. The light detection device according to claim 56,
wherein a material of the organic layer includes at least one of polyimide, siloxane, and silicone.

58. The light detection device according to claim 1, further comprising
a resin layer provided between the chip and the buried layer.

59. The light detection device according to claim 58,
wherein the resin layer is an oxide layer or an organic layer.

60. The light detection device according to claim 59,
wherein the organic layer has heat resistance temperature of 400 °C or higher.

61. The light detection device according to claim 60,
wherein a material of the organic layer includes at least one of polyimide, siloxane, and silicone.
